(19) United States
(12) Patent Application Publication
(10) Pub. No.: US 2026/0239871 A1
(43) Pub. Date: Aug. 13, 2026

(54) QUANTUM DOT COMPOSITION, LIGHT-EMITTING DEVICE, ELECTRONIC APPARATUS, AND ELECTRONIC EQUIPMENT

(71) Applicant: Samsung Display Co., Ltd., Yongin-si (KR)

(72) Inventors: Yunku Jung, Yongin-si (KR); Chulsoon Park, Yongin-si (KR); Seonhui Baek, Yongin-si (KR)

(21) Appl. No.: 19/443,951

(22) Filed: Jan. 8, 2026

(30) Foreign Application Priority Data
Feb. 11, 2025 (KR) 10-2025-0017228

(51) Int. Cl. H10K 85/30; B82Y 20/00; B82Y 40/00; C09D 5/22; C09D 7/62; C09K 11/02; C09K 11/88; H10K 50/115; H10K 59/12

(52) U.S. Cl. CPC H10K 85/381; C09D 5/22; C09D 7/62; C09K 11/025; C09K 11/883; B82Y 20/00; B82Y 40/00; H10K 50/115; H10K 59/12

(57) ABSTRACT

A quantum dot composition, a light-emitting device, an electronic apparatus including the light-emitting device, and an electronic equipment including the light-emitting device are disclosed. The quantum dot composition may include a quantum dot, a Zn complex compound represented by Formula 1, and a solvent:

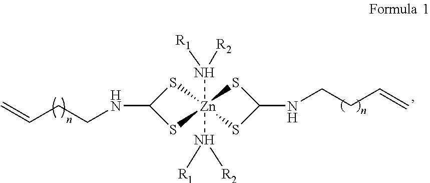

wherein, in Formula 1, R₁ and R₂ may each independently be hydrogen, a C₈-C₂₀ alkyl group, a C₈-C₂₀ alkenyl group, or a C₈-C₂₀ alkyloxiranyl group, at least one selected from R₁ and R₂ may be a C₈-C₂₀ alkyl group, a C₈-C₂₀ alkenyl group, or a C₈-C₂₀ alkyloxiranyl group, n may be an integer of 1 to 10, and a dotted line indicates a coordinate bond.

### CROSS-REFERENCE TO RELATED APPLICATION

The present application claims priority to and the benefit of Korean Patent Application No. 10-2025-0017228, filed on Feb. 11, 2025, in the Korean Intellectual Property Office, the entire disclosure of which is incorporated herein by reference.

### BACKGROUND

### 1. Field

One or more embodiments of the present disclosure relate to a quantum dot composition, and an electronic device, an electronic apparatus, and an electronic equipment, each manufactured from the quantum dot composition.

### 2. Description of the Related Art

Light-emitting devices are devices that convert electrical energy into light energy. In such devices, holes provided from an anode may move toward an emission layer through (via) a hole transport region, and electrons provided from a cathode may move toward the emission layer through (via) an electron transport region. These charge carriers, the holes and electrons, recombine in the emission layer to produce (form) excitons. The excitons may subsequently transition from an excited state to a ground state, thereby generating (emitting) light. The emission layer of the light-emitting device may include quantum dots.

Quantum dots, which are nanocrystals of semiconductor materials, exhibit quantum confinement effects. By controlling the size of the quantum dots, it is possible to tune the emission wavelength, thereby achieving desirable color purity and high luminescence efficiency. The emission layer of a light-emitting device may be formed utilizing a quantum dot composition.

### SUMMARY

One or more aspects of embodiments of the present disclosure are directed toward a quantum dot composition to form or manufacture an emission layer having improved or enhanced current efficiency and lifespan, an electronic device including the emission layer formed or manufactured from the quantum dot composition, and an electronic apparatus and an electronic equipment each including the electronic device.

Additional aspects of embodiments will be set forth in part in the description which follows and, in part, will be apparent from the description or may be learned by practice of the presented embodiments of the disclosure.

According to one or more embodiments, a quantum dot composition includes a quantum dot, a Zn complex compound represented by Formula 1, and a solvent:

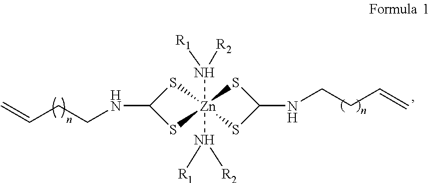

wherein, in Formula 1,
R₁ and R₂ may each independently be hydrogen, a C₈-C₂₀ alkyl group, a C₈-C₂₀ alkenyl group, or a C₈-C₂₀ alkyloxiranyl group, and at least one selected from R₁ and R₂ may be a C₈-C₂₀ alkyl group, a C₈-C₂₀ alkenyl group, or a C₈-C₂₀ alkyloxiranyl group,
n may be an integer of 1 to 10, and
a dotted line indicates a coordinate bond.

According to one or more embodiments, a light-emitting device includes a first electrode, a second electrode opposite to (e.g., facing) the first electrode, an interlayer arranged between the first electrode and the second electrode and including an emission layer, and the emission layer may be formed or manufactured from the quantum dot composition and may include the quantum dot, ZnS generated from decomposition of the Zn complex compound represented by Formula 1, ZnS to which a ligand is bonded (e.g., ZnS to which a ligand is bonded and/or which is generated from decomposition of the Zn complex compound represented by Formula 1), and a thiourea derivative.

According to one or more embodiments, an electronic apparatus includes the light-emitting device.

According to one or more embodiments, an electronic equipment includes the light-emitting device.

For example, the quantum dot composition as described herein should enable the formation of an emission layer with enhanced charge balance and exciton confinement, contributing to improved or enhanced current efficiency and operational stability of the light-emitting device. The inclusion of the Zn complex compound facilitates in-situ formation of ZnS, which acts as a passivation layer and improves or enhances the interface properties between the quantum dots and surrounding matrix. These improvements are to achieve high-performance light-emitting devices, which may be integrated into a wide range of electronic apparatuses, such as displays, lighting systems, and/or wearable electronics.

### BRIEF DESCRIPTION OF THE DRAWINGS

The above and other aspects and features of certain embodiments of the present disclosure will be more apparent from the following description taken in conjunction with the accompanying drawings, in which:

FIG. 1 is a schematic cross-sectional view of a structure of a light-emitting device according to one or more embodiments;

FIG. 2 is a schematic view of a structure of an electronic apparatus according to one or more embodiments;

FIG. 3 is a cross-sectional view of a light-emitting apparatus according to one or more embodiments;

FIG. 4 is a cross-sectional view of a light-emitting apparatus according to one or more embodiments.

FIG. 5 is a block diagram of an electronic equipment according to one or

more embodiments;

FIG. 6 is a schematic view of an electronic equipment according to one or more embodiments;

FIG. 7 is a diagram schematically illustrating the exterior of a vehicle as an electronic equipment including a light-emitting device according to one or more embodiments;

FIG. 8 is a diagram schematically illustrating the exterior of a vehicle as an electronic equipment including a light-emitting device according to one or more embodiments;

FIGS. 9A-9C are each a diagram schematically illustrating the interior of a vehicle according to one or more embodiments;

FIG. 10 is a graph of a UV-VIS absorption spectrum of a quantum dot thin film of Test Example 1;

FIG. 11 is a graph of a UV-VIS absorption spectrum measured after cleaning of the quantum dot thin film of Test Example 1; and

FIG. 12 is a photomicrograph of an upper surface of a quantum dot thin film of each of Test Example 5 and Comparative Test Example 3.

### DETAILED DESCRIPTION

Reference will be made in more detail to one or more embodiments, examples of which are illustrated in the accompanying drawings, wherein like reference numerals refer to like elements throughout the attached drawings and the written description, and duplicative descriptions thereof may not be provided in the specification. In this regard, the subject matter of the present disclosure may be embodied in different forms and should not be construed as being limited to one or more embodiments set forth herein. Rather, these embodiments are provided as examples, by referring to the drawings, to explain the aspects and features of the present description to those skilled in the art.

The utilization of “may” if (e.g., when) describing embodiments of the present disclosure refers to “one or more embodiments of the present disclosure.”

As used herein, the singular forms “a,” “an,” and “the” are intended to include the plural forms as well, unless the context clearly indicates otherwise. The singular expression includes the plural expression unless the context clearly dictates otherwise.

As used herein, the term “and/or” includes any and all combinations of one or more of the associated listed items.

As used herein, the term “and/or” or “or” includes any and all combinations of one or more of the associated listed items. Throughout the present disclosure, the expressions, such as “at least one of,” “one of,” and “selected from,” if (e.g., when) preceding a list of elements, modify the entire list of elements and do not modify the individual elements of the list. For example, “at least one of a, b, or c,” “at least one selected from among a, b, and c,” or “at least one selected from among a to c,” and/or the like indicates only a, only b, only c, both (e.g., simultaneously) a and b, both (e.g., simultaneously) a and c, both (e.g., simultaneously) b and c, all of a, b, and c, or variations thereof.

Because the disclosure may have diverse modified embodiments, embodiments of the present disclosure are illustrated in the drawings and are described in the detailed description. Aspects, features, and characteristics of embodiments of the present disclosure, and methods of accomplishing thereof will be more apparent if (e.g., when) referring to one or more embodiments described with reference to the drawings. The disclosure may, however, be embodied in one or more different forms and should not be construed as limited to the embodiments set forth herein.

It will be understood that although the terms “first,” “second,” and/or the like used herein may be used herein to describe one or more suitable components, these components should not be limited by these terms. These components are only used to distinguish one component from another.

An expression used in the singular encompasses the expression of the plural, unless it has a clearly different meaning in the context.

In the specification, it is to be understood that the terms, such as “have,” “include,” “having,” and “including,” are intended to indicate the existence of the features or components disclosed in the specification and are not intended to preclude the possibility that one or more other features or components may exist or may be added. For example, unless otherwise limited, terms, such as “have,” “include,” “having,” or “including,” may refer to either consisting of features or components described in the specification only or further including other components. For example, it should be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having,” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

In the context of the present application and unless otherwise defined, the terms “use,” “using,” and “used” may be considered synonymous with the terms “utilize,” “utilizing,” and “utilized,” respectively.

In the drawings, the thickness of layers, films, panels, regions, and/or the like may be exaggerated for clarity.

It will be understood that if (e.g., when) an element, such as a layer, a film, a region, or a substrate, is referred to as being “on” or “above” another element, it may be directly on or directly above the other element or intervening elements may also be present therebetween. In contrast, if (e.g., when) an element is referred to as being “directly on” or “directly above” another element, there are no intervening elements present therebetween.

As utilized herein, the terms “substantially,” “about,” or similar terms are used as terms of approximation and not as terms of degree and are intended to account for the inherent deviations in measured or calculated values that would be recognized by those of ordinary skill in the art. “About” as used herein is inclusive of the stated value and refers to as being within an acceptable range of deviation for the particular value as determined by one of ordinary skill in the art, considering the measurement in question and the error associated with measurement of the particular quantity (e.g., the limitations of the measurement system). For example, “about” may refer to as being within one or more standard deviations or within ±30%, ±20%, ±10%, or ±5% of the stated value. Also, it should be understood that, even if (e.g., when) the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend the disclosure, including the claims, to expressly recite any sub-range subsumed within the ranges expressly recited herein.

The term “Group II” used herein may include a Group IIA element and a Group IIB element on the IUPAC periodic table, and the Group II element includes, for example, magnesium (Mg), calcium (Ca), zinc (Zn), cadmium (Cd), and/or mercury (Hg).

The term “Group III” used herein may include a Group IIIA element and a Group IIIB element on the IUPAC periodic table, and the Group III element may include, for example, aluminum (AI), gallium (Ga), indium (In), and/or thallium (Tl).

The term “Group V” used herein may include a Group VA element and a Group VB element on the IUPAC periodic table, and the Group V element may include, for example, nitrogen (N), phosphorus (P), arsenic (As), and/or antimony (Sb).

The term “Group VI” used herein may include a Group VIA element and a Group VIB element on the IUPAC periodic table, and the Group VI element may include, for example, sulfur(S), selenium (Se), and/or tellurium (Te).

### Quantum Dot Composition

According to one or more embodiments, a quantum dot composition may include: a quantum dot; a Zn complex compound; and a solvent.

In one or more embodiments, the quantum dot may include a semiconductor compound.

In one or more embodiments, the quantum dot may include: a Group II-VI semiconductor compound; a Group III-V semiconductor compound; a Group III-VI semiconductor compound; a Group I-III-VI semiconductor compound; a Group IV-VI semiconductor compound; or a combination thereof.

### Zn Complex Compound

In one or more embodiments, the Zn complex compound may be a compound represented by Formula 1 or 2:

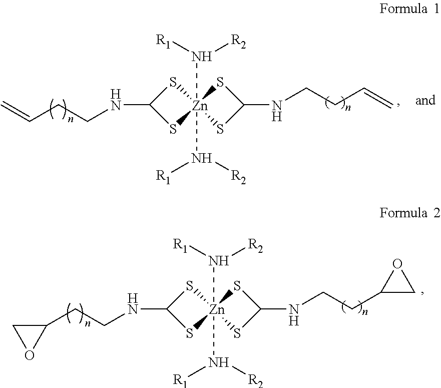

wherein, in Formulae 1 and 2,
R₁ and R₂ may each independently be hydrogen, a C₈-C₂₀ alkyl group, a C₈-C₂₀ alkenyl group, or a C₈-C₂₀ alkyloxiranyl group, and at least one selected from R₁ and R₂ may be a C₈-C₂₀ alkyl group, a C₈-C₂₀ alkenyl group, or a C₈-C₂₀ alkyloxiranyl group.

In one or more embodiments, a C₈-C₂₀ alkyl group may be a linear alkyl group.

In one or more embodiments, a C₈-C₂₀ alkenyl group may be a group having an ethylene group at the terminus of a C₆-C₁₈ alkyl chain (e.g., a linear C₆-C₁₈ alkyl group).

In one or more embodiments, a C₈-C₂₀ alkyloxiranyl group may be a group having an epoxy group at the terminus of a C₆-C₁₈ alkyl chain (e.g., a linear C₆-C₁₈ alkyl group).

n may be an integer of 1 to 10, an integer of 1 to 5, or an integer of 1 to 3.

A dotted line indicates a coordinate bond.

An amine group coordinate-bonded to Zn in a compound of Formula 1 or 2 may be primary amine group or secondary amine group. In one or more embodiments, the amine group may be a primary amine group. For example, one selected from R₁ and R₂ may be hydrogen, and the other one selected from R₁ and R₂ may a C₈-C₂₀ alkyl group, a C₈-C₂₀ alkenyl group, or a C₈-C₂₀ alkyloxiranyl group.

In one or more embodiments, one selected from R₁ and R₂ may be hydrogen, and the other one selected from R₁ and R₂ may be an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, an n-notadecyl group, or an n-eicosyl group.

In one or more embodiments, one selected from R₁ and R₂ may be hydrogen, and the other one selected from R₁ and R₂ may be an n-octenyl group, an n-nonenyl group, an n-decenyl group, an n-undecenyl group, an n-dodecenyl group, an n-tridecenyl group, an n-tetradecenyl group, an n-pentadecenyl group, an n-hexadecenyl group, an n-heptadecenyl group, an n-octadecenyl group, an n-nonadecenyl group, or an n-eicocenyl group.

In one or more embodiments, one selected from R₁ and R₂ may be hydrogen, and the other one selected from R₁ and R₂ may be an n-hexyloxiranyl group, an n-heptyloxiranyl group, an n-octyloxiranyl group, an n-nonyloxiranyl group, an n-decyloxiranyl group, an n-undecyloxiranyl group, an n-dodecyloxiranyl group, an n-tridecyloxiranyl group, an n-tetradecyloxiranyl group, an n-pentadecyloxiranyl group, an n-hexadecyloxiranyl group, an n-heptadecyloxiranyl group, or an n-octadecyloxiranyl group.

In one or more embodiments, the Zn complex compound may include a compound in Group I (e.g., may be any compound selected from among the compounds in Group 1):

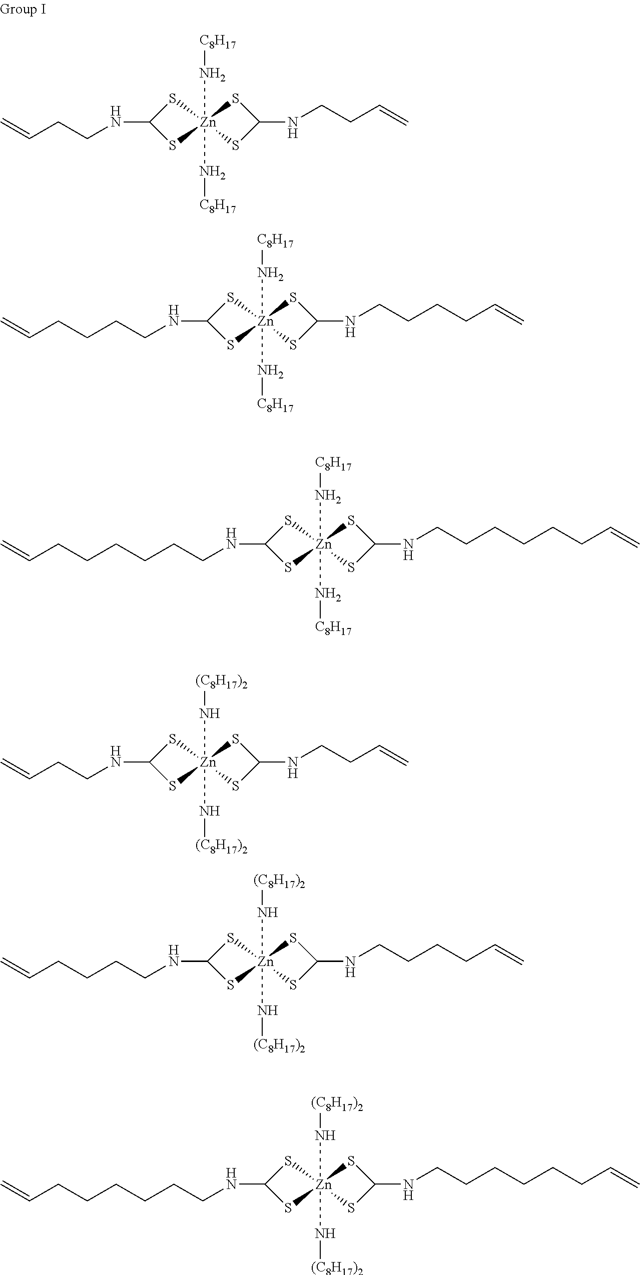

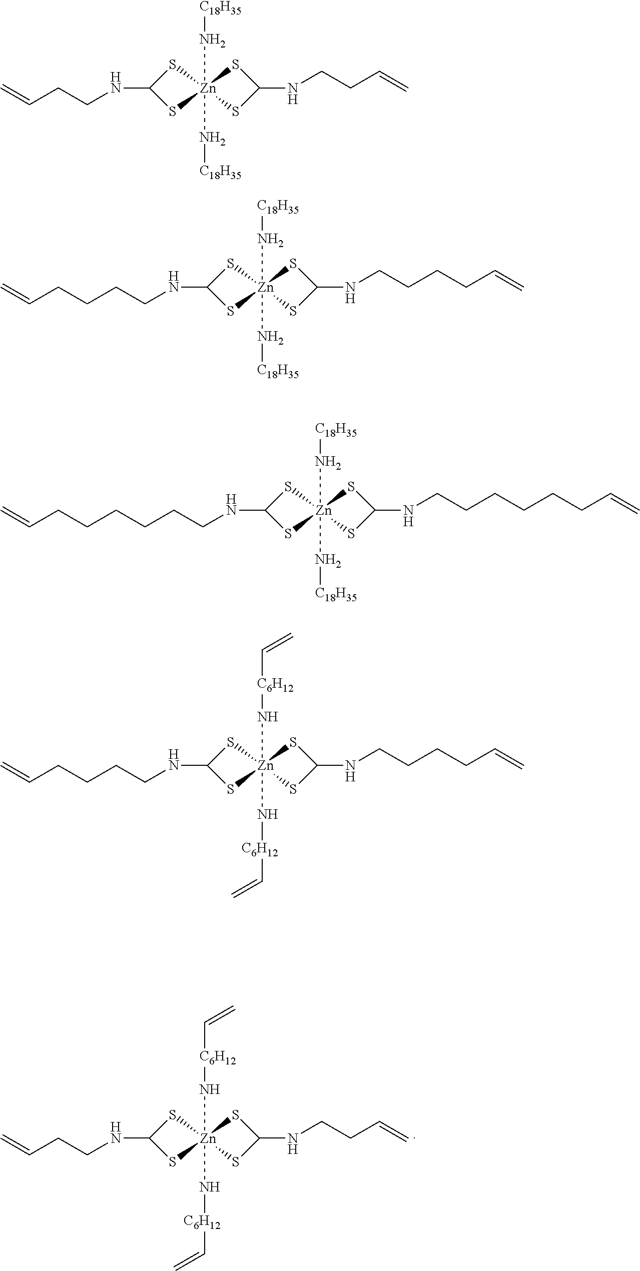

In one or more embodiments, the amount of the Zn complex compound per a total weight (e.g., based on 100 wt %) of the quantum dot may be about 0.5 wt % to about 5 wt %, about 1 wt % to about 4 wt %, or about 2 wt % to about 3 wt %.

If (e.g., when) forming or manufacturing the quantum dot thin film from the quantum dot composition, the Zn complex compound may be decomposed during a baking process and may generate ZnS and/or ZnS to which a ligand is bonded and a thiourea derivative. The baking temperature may be, for example, about 100° C. to about 200° C. or about 140° C. to about 180° C.

In one or more embodiments, ZnS to which a ligand is bonded and/or which is generated from decomposition of the Zn complex compound of Formula 1 may be represented by Formula 1A:

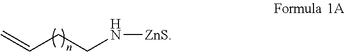

In one or more embodiments, ZnS to which a ligand is bonded and/or which is generated from decomposition of the Zn complex compound of Formula 2 may be represented by Formula 2A:

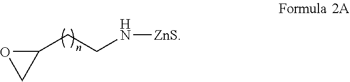

In one or more embodiments, the thiourea derivative may be represented by Formula 3:

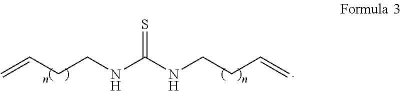

n in Formulae 1A, 2A, and 3 may be the same as defined in one or more embodiments.

ZnS generated from the Zn complex compound may be distributed like a matrix between the quantum dots in the quantum dot thin film. ZnS distributed between the quantum dots may prevent non-emitting electron transfer (or reduce a degree or occurrence of non-emitting electron transfer) between the quantum dots. This may be because of somewhat or substantially wide bandgap energy of 3.6 eV that ZnS has. If (e.g., when) the electron transfer layer of metal oxide nanoparticles is present on the quantum dot emission layer, the metal oxide nanoparticles may penetrate into a space between the quantum dots of the quantum dot emission layer, and in this case, a leakage current may be generated in the quantum dots. As ZnS fills the space between the quantum dots in the present disclosure, the penetration of metal oxide nanoparticles may be prevented (or a degree or occurrence of the penetration of metal oxide nanoparticles may be reduced), thereby avoiding the generation of leakage current. In one or more embodiments, as ZnS fills the space between the quantum dots, aggregation of the quantum dots may be prevented (or a degree or occurrence of aggregation of the quantum dots may be reduced), which may facilitate substantially uniform formation of the quantum dot thin film.

Moreover, as an ethylene group or an epoxy group at the terminus of ZnS to which a ligand is bonded and which is generated from the Zn complex compound is cross-linked, damage that may be caused by the solvent of the upper layer to the quantum dot thin film may be prevented (or a degree or occurrence of damage that may be caused by the solvent of the upper layer to the quantum dot thin film may be reduced).

### Quantum Dot

The quantum dot may include: a Group II-VI semiconductor compound; a Group III-V semiconductor compound; a Group III-VI semiconductor compound; a Group I-III-VI semiconductor compound; a Group IV-VI semiconductor compound; or a combination thereof.

Examples of the Group II-VI semiconductor compound may include: a binary compound, such as CdS, CdSe, CdTe, ZnS, ZnSe, ZnTe, ZnO, HgS, HgSe, HgTe, MgSe, and/or MgS; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, and/or MgZnS; a quaternary compound, such as CdZnSeS, CdZnSeTe, CdZnSTe, CdHgSeS, CdHgSeTe, CdHgSTe, HgZnSeS, HgZnSeTe, and/or HgZnSTe; or a combination thereof.

Examples of the Group III-V semiconductor compound may include: a binary compound, such as GaN, GaP, GaAs, GaSb, AlN, AlP, AlAs, AlSb, InN, InP, InAs, InSb, and/or the like; a ternary compound, such as GaNP, GaNAs, GaNSb, GaPAs, GaPSb, AlNP, AlNAs, AlNSb, AlPAS, AlPSb, InGaP, InNP, InAlP, InNAs, InNSb, InPAs, InPSb, and/or the like; a quaternary compound, such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and/or the like; or a (e.g., any suitable) combination thereof. In one or more embodiments, the Group III-V semiconductor compound may further include a Group II element. Examples of the Group III-V semiconductor compound further including a Group II element may include InZnP, InGaZnP, InAlZnP, and/or the like.

Examples of the Group III-VI semiconductor compound may include: a binary compound, such as GaS, GaSe, Ga₂Se₃, GaTe, InS, InSe, In₂S₃, In₂Se₃, and/or InTe; a ternary compound, such as InGaS₃ and/or InGaSe₃; or a (e.g., any suitable) combination thereof.

Examples of the Group I-III-VI semiconductor compound may include: a ternary compound, such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, AgAlO₂, and/or the like; a quaternary compound, such as CuInGaS₂, AgInGaS₂, AgInGaSe₂, and/or the like; or a (e.g., any suitable) combination thereof.

Examples of the Group IV-VI semiconductor compound may include: a binary compound, such as SnS, SnSe, SnTe, PbS, PbSe, and/or PbTe; a ternary compound, such as SnSeS, SnSeTe, SnSTe, PbSeS, PbSeTe, PbSTe, SnPbS, SnPbSe, and/or SnPbTe; a quaternary compound, such as SnPbSSe, SnPbSeTe, and/or SnPbSTe; or a (e.g., any suitable) combination thereof.

Examples of the Group IV element or compound may include: a single element, such as Si, Ge, and/or the like; a binary compound, such as SiC, SiGe, and/or the like; or a (e.g., any suitable) combination thereof.

Each element included in a multi-element compound, such as the binary compound, the ternary compound, and/or the quaternary compound, may be present at a substantially uniform concentration or non-uniform concentration in a particle. The foregoing formulae refer to the types (kinds) of elements included in each compound, and the element ratios in these compounds may be different from each other. For example, AgInGaS₂ may indicate AgInₓGa₁₋ₓS₂ (where x is a real number satisfying 0<x<1).

The quantum dot may have a single structure in which the concentration of each element in the quantum dot is substantially uniform, or a core-shell dual structure. The shell may be around (e.g., surround) at least a part of the core. For example, the material included in the core and the material included in the shell may be different from each other.

The shell of the quantum dot may act as a protective layer that prevents chemical degeneration (or reduces a degree or occurrence of chemical degeneration) of the core to maintain semiconductor characteristics and/or as a charging layer that imparts or enhances electrophoretic characteristics to the quantum dot. The shell may be a single layer or a multi-layer. The interface between the core and the shell may have a concentration gradient in which the concentration of an element existing in the shell decreases toward the center of the core.

Examples of the shell of the quantum dot may be an oxide of metal, metalloid, or non-metal, a semiconductor compound, and a combination thereof. Examples of the oxide of metal, metalloid, or non-metal may include: a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, and/or the like; a ternary compound, such as MgAl₂O₄, CoFe₂O₄, NiFe₂O₄, CoMn₂O₄, and/or the like; or a (e.g., any suitable) combination thereof. Examples of the semiconductor compound may include, as described herein, a Group II-VI semiconductor compound; a Group III-V semiconductor compound; a Group III-VI semiconductor compound; a Group I-III-VI semiconductor compound; a Group IV-VI semiconductor compound; or a combination thereof. For example, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or a combination thereof.

Each element included in a multi-element compound, such as the binary compound and the ternary compound, may be present at a substantially uniform concentration or non-uniform concentration in a particle. The foregoing formulae refer to the types (kinds) of elements included in each compound, and the element ratios in these compounds may be different from each other.

The amount of the quantum dots per a total weight (e.g., based on 100 wt %) of the quantum dot composition may be in a range from about 1 wt % to about 10 wt %, from about 1 wt % to about 20 wt %, from about 2 wt % to about 10 wt %, or from about 3 wt % to about 5 wt %.

A full width at half maximum (FWHM) of an emission wavelength spectrum of the quantum dots may be about 60 nm or less, about 45 nm or less, for example, about 40 nm or less, and for example, about 30 nm or less, and within the foregoing ranges, color purity and/or color reproducibility of the quantum dots may be improved or enhanced. In one or more embodiments, because the light emitted through the quantum dot is emitted in all directions, the wide viewing angle may be improved or enhanced.

In one or more embodiments, the quantum dot may be in the form of a spherical particle (e.g., a substantially spherical particle), a pyramidal particle (e.g., a substantially pyramidal particle), a multi-arm particle (e.g., a substantially multi-arm particle), a cubic nanoparticle (e.g., a substantially cubic nanoparticle), a nanotube particle (e.g., a substantially nanotube particle), a nanowire particle (e.g., a substantially nanowire particle), a nanofiber particle (e.g., a substantially nanofiber particle), or a nanoplate particle (e.g., a substantially nanoplate particle).

Because an energy band gap may be adjusted or optimized by controlling or selecting the size of the quantum dot, light having one or more suitable wavelength bands may be obtained from the quantum dot emission layer. Accordingly, by utilizing quantum dots of different sizes, a light-emitting device that emits light of one or more suitable wavelengths may be implemented. In one or more embodiments, the size of the quantum dots or the ratio of elements in the quantum dot compound may be selected so that (e.g., such that) red light, green light, and/or blue light may be emitted. In one or more embodiments, the quantum dots may be configured or arranged to emit white light by combination of light of one or more suitable colors.

### Solvent

Any suitable solvent which may disperse the quantum dots may be selected as the solvent.

For example, the solvent may include an alcohol-based solvent, a chlorine-based solvent, an ether-based solvent, an ester-based solvent, a ketone-based solvent, an aliphatic hydrocarbon-based solvent, an aromatic hydrocarbon-based solvent, or a (e.g., any suitable) combination thereof, but embodiments of the present disclosure are not limited thereto.

In one or more embodiments, the solvent may include methanol, ethanol, propanol, butanol, pentanol, hexanol, heptanol, octanol, nonaol, decanol, dichloromethane, 1,2-dichloroethane, 1,1,2-trichloroethane, chlorobenzene, o-dichlorobenzene, tetrahydrofuran, dioxane, anisole, 4-methylanisole, butyl phenyl ether, toluene, xylene, mesitylene, ethylbenzene, n-hexylbenzene, cyclohexylbenzene, trimethylbenzene, tetrahydronaphthalene, cyclohexane, methylcyclohexane, n-pentane, n-hexane, n-heptane, n-octane, n-nonane, n-decane, dodecane, hexadecane, oxadecane, acetone, methylethylketone, cyclohexanone, acetophenone, ethyl acetate, butyl acetate, methyl solve acetate, ethyl solve acetate, methyl benzoate, ethyl benzoate, butyl benzoate, 3-phenoxy benzoate, or a (e.g., any suitable) combination thereof, but embodiments of the present disclosure are not limited thereto.

In one or more embodiments, the boiling point of the organic solvent may be 200° C. or higher. As the quantum dot is mixed with the organic solvent having a high boiling point, the cation exchange may be suppressed or reduced, and accordingly, the high efficiency and long lifespan characteristics may be maintained and improved or enhanced. In one or more embodiments, by utilizing the organic solvent having a high boiling point, the dispersibility of the quantum dots in the organic solvent may be improved or enhanced, and an inkjet process for ink ejection may be facilitated without an issue of nozzle clogging and/or the like. For example, the boiling point of the organic solvent may be about 200° C. to about 400° C., about 200° C. to about 350° C., about 200° C. to about 300° C., or about 200° C. to about 250° C. The solvent may be a single solvent or a mixed solvent obtained by mixing two or more solvents. If (e.g., when) three or more types (kinds) of organic solvents are employed, the three types (kinds) of solvents may be mixed at one or more suitable ratios, such as 1:1:1, 3:2:1, 4:3:1, 4:3:2, 5:3:1, or 6:3:1.

In one or more embodiments, the organic solvent may include cyclopentylbenzene, cyclohexylbenzene, dodecane, tridecane, tetradecane, pentadecane, hexadecane, heptadecane, octadecane, nonadecane, icosane, hexylbenzene, heptylbenzene, octylbenzene, nonylbenzene, decylbenzene, or a (e.g., any suitable) combination thereof; however, embodiments of the present disclosure are not limited thereto, and the organic solvent may be any suitable organic solvent having a boiling point of 200° C. or higher. For example, the solvent may not include (e.g., may exclude) an organic solvent (e.g., octane (boiling point: 125° C.)) having a boiling point lower than 200° C.

In one or more embodiments, the quantum dot composition may further include an additive, such as a cross-linking agent, a dispersant, and/or the like.

In one or more embodiments, the amount of the solvent may be about 80 parts by weight to about 99.9 parts by weight or about 90 parts by weight to about 99.8 parts by weight based on 100 parts by weight of the quantum dot composition, but embodiments of the present disclosure are not limited thereto.

In one or more embodiments, the viscosity of the quantum dot composition (at 25° C.) may be about 1 cP to about 10 cP. If (e.g., when) the viscosity of the quantum dot composition is within the foregoing range, the quantum dot composition may be suitable for a solution process (for example, inkjet). In one or more embodiments, the surface tension of the quantum dot composition may be about 20 dyne/cm to about 40 dyne/cm. In one or more embodiments, the vapor pressure of the quantum dot composition (at 25° C.) may be 10⁻² mmHg.

### Method of Manufacturing Quantum Dot Thin Film

The quantum dot thin film may be manufactured by applying the quantum dot composition on a substrate by utilizing a method of spin-coating, inkjet-printing, and/or the like and then heat-treating the quantum dot composition applied. As described in one or more embodiments, as a result of the decomposition of the Zn complex compound by the heat-treatment, the quantum dot thin film may include, along with the quantum dots, ZnS, ZnS to which a ligand is bonded, and a thiourea derivative.

As ZnS fills the space between the quantum dots as described in one or more embodiments, the penetration of the metal oxide nanoparticles and generation of leakage current may be prevented (or a degree or occurrence of the penetration of the metal oxide nanoparticles and generation of leakage current may be reduced), and aggregation of the quantum dots may be prevented (or a degree or occurrence of aggregation of the quantum dots may be reduced) to facilitate substantially uniform formation of the quantum dot thin film. Moreover, as an ethylene group or an epoxy group at the terminus of ZnS to which a ligand is bonded and/or which is generated from the Zn complex compound is cross-linked, damage that may be caused by the solvent of the upper layer to the quantum dot thin film may be prevented (or a degree or occurrence of damage that may be caused by the solvent of the upper layer to the quantum dot thin film may be reduced).

### Light-Emitting Device

The thin film formed or manufactured from the quantum dot composition as described in one or more embodiments may be utilized as an emission layer of a light-emitting device. In one or more embodiments, a light-emitting device may include: a first electrode; a second electrode opposite to (e.g., facing) the first electrode; and an emission layer including a thin film formed or manufactured from the quantum dot composition and arranged between the first electrode and the second electrode. The light-emitting device may further include a hole transport region between the first electrode and the emission layer, an electron transport region between the emission layer and the second electrode, or a combination thereof.

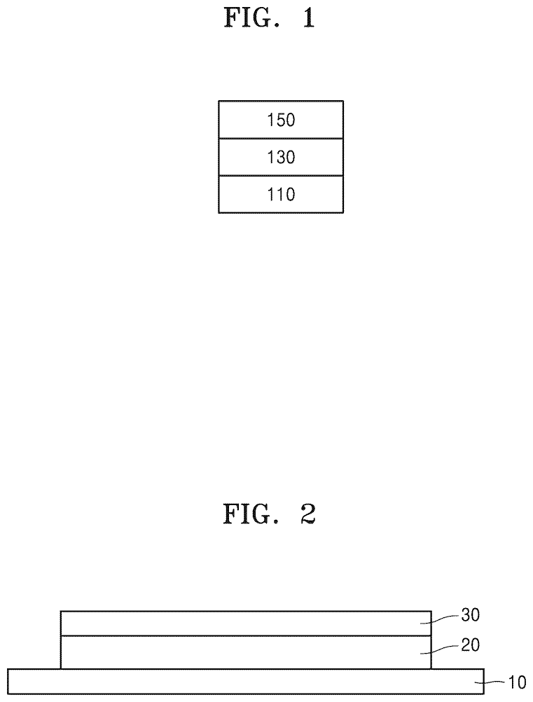

### Description of FIG. 1

FIG. 1 is a schematic cross-sectional view of a structure of a light-emitting device 10 according to one or more embodiments.

The light-emitting device 10 may include: a first electrode 110; a second electrode 150 opposite to (e.g., facing) the first electrode 110; and interlayer 130 arranged between the first electrode 110 and second electrode 150 and including an emission layer. The emission layer may be formed or manufactured from the quantum dot composition according to one or more embodiments. Hereinafter, the layers of the light-emitting device 10 will be described in more detail.

### First Electrode 110

In FIG. 1, a substrate may be additionally arranged under the first electrode 110 or on the second electrode 150. The substrate may be a glass substrate and/or a plastic substrate, each having excellent or suitable mechanical strength, thermal stability, transparency, surface smoothness, ease of handling, and water resistance.

For example, if (e.g., when) the light-emitting device 10 is a top-emission type (kind) in which light is emitted in the opposite direction of the substrate, the substrate may not be essentially or substantially transparent and may be opaque or semi-transparent. In this case, the substrate may be formed or composed of metal. If (e.g., when) the substrate is formed or composed of metal, the substrate may include carbon, iron, chromium, manganese, nickel, titanium, molybdenum, stainless steel (SUS), an Invar alloy, an Inconel alloy, a Kovar alloy, or a (e.g., any suitable) combination thereof.

In one or more embodiments, a buffer layer, a thin-film transistor, an organic insulating (e.g., electrically insulating) layer, and/or the like may be further included between the substrate and the first electrode 110.

The first electrode 110 may be formed or arranged by, for example, depositing and/or sputtering a material on the substrate. The first electrode 110 may be a reflective electrode, a transflective electrode, or a transmissive electrode. To form or arrange the first electrode 110 which is a transmission-type (kind) electrode, the material for the first electrode may include indium tin oxide (ITO), indium zinc oxide (IZO), tin oxide (e.g., SnOₖ, wherein 0<k≤2; e.g., SnO₂), zinc oxide (e.g., ZnOₓ, wherein 0<x≤2; e.g., ZnO), gallium zinc oxide (GZO), aluminum zinc oxide (AZO), InZnSnOₓ (IZSO), ZnSnOₓ (ZSO), graphene, PEDOT:PSS, carbon nanotubes, silver (Ag) nanowire, gold (Au) nanowire, metal mesh, or a (e.g., any suitable) combination thereof. In one or more embodiments, if (e.g., when) the first electrode 110 is a semi-transmissive electrode or a reflective electrode, a material to form or arrange a first electrode may include magnesium (Mg), silver (Ag), aluminum (Al), aluminum-lithium (Al—Li), calcium (Ca), magnesium-indium (Mg—In), magnesium-silver (Mg—Ag), or a (e.g., any suitable) combinations thereof.

The first electrode 110 may have a single-layered structure or a multi-layered structure including two or more layers. In one or more embodiments, the first electrode 110 may have a three-layer structure of ITO/Ag/ITO.

### Interlayer 130

The interlayer 130 may be arranged above the first electrode 110. The interlayer 130 may include the emission layer.

The interlayer 130 may further include a hole transport region arranged between the first electrode 110 and the emission layer, and an electron transport region arranged between the emission layer and the second electrode 150.

The interlayer 130 may further include, in addition to one or more suitable organic materials, a metal-containing compound, such as an organometallic compound, an inorganic material, such as quantum dots, and/or the like.

In one or more embodiments, the interlayer 130 may include, i) two or more emitting units sequentially stacked between the first electrode 110 and the second electrode 150, and ii) a charge generation layer between adjacent emitting units among the two or more emitting units. If (e.g., when) the interlayer 130 includes emitting units and a charge generation layer as described in one or more embodiments, the light-emitting device 10 may be a tandem light-emitting device.

### Hole Transport Region in Interlayer 130

The hole transport region may have: i) a single-layer structure consisting of (e.g., including) a single layer consisting of (e.g., including) a single material, ii) a single-layer structure consisting of (e.g., including) a single layer consisting of (e.g., including) a plurality of materials that are different from each other, or iii) a multilayer structure including a plurality of layers including a plurality of materials that are different from each other.

The hole transport region may include a hole injection layer, a hole transport layer, an emission auxiliary layer, an electron-blocking layer, or a (e.g., any suitable) combination thereof.

For example, the hole transport region may have a single-layered structure including a single layer including a plurality of different materials or a multi-layered structure having a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron-blocking layer structure, wherein for each structure, constituting layers are sequentially stacked from the first electrode 110 in this stated order.

The hole transport region may include an amorphous (e.g., non-crystalline) inorganic material and/or an organic material. The inorganic material may include NiO, MoO₃, Cr₂O₃, and/or Bi₂O₃. The inorganic material may include a p-type (kind) inorganic semiconductor, for example, a p-type (kind) inorganic semiconductor in which an iodide, bromide, or chloride of Cu, Ag, or Au is doped with non-metal, such as O, S, Se, or Te; a p-type (kind) inorganic semiconductor in which a Zn-containing compound is doped with metal, such as Cu, Ag, or Au, and non-metal, such as N, P, As, Sb, or Bi; or a spontaneous p-type (kind) inorganic semiconductor, such as ZnTe.

The organic material may include a compound represented by Formula 201, a compound represented by Formula 202, or a (e.g., any suitable) combination thereof:

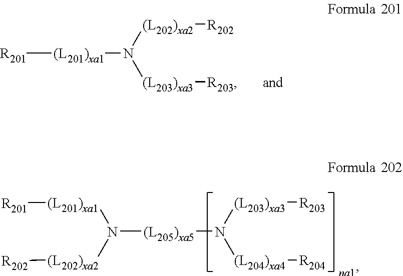

wherein, in Formulae 201 and 202,
L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
L₂₀₅ may be *—O—*′, *—S—*′, *—N(Q₂₀₁)-*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
xa1 to xa4 may each independently be an integer of 0 to 5,
xa5 may be an integer of 1 to 10,
R₂₀₁ to R₂₀₄ and Q₂₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
R₂₀₁ and R₂₀₂ may optionally be linked to each other via a single bond (e.g., a single covalent bond), a C₁-C₅ alkylene group that is unsubstituted or substituted with at least one R₁₀ₐ, or a C₂-C₅ alkenylene group that is unsubstituted or substituted with at least one R₁₀ₐ to form a C₈-C₆₀ polycyclic group (for example, a carbazole group) that is unsubstituted or substituted with at least one R₁₀ₐ (for example, Compound HT16),
R₂₀₃ and R₂₀₄ may optionally be linked to each other via a single bond (e.g., a single covalent bond), a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ, and
na1 may be an integer of 1 to 4.

In one or more embodiments, each of Formulae 201 and 202 may include at least one selected from among the groups represented by Formulae CY201 to CY217:

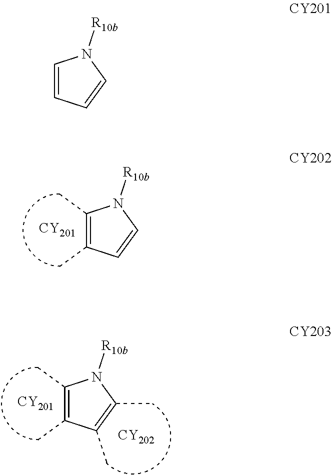

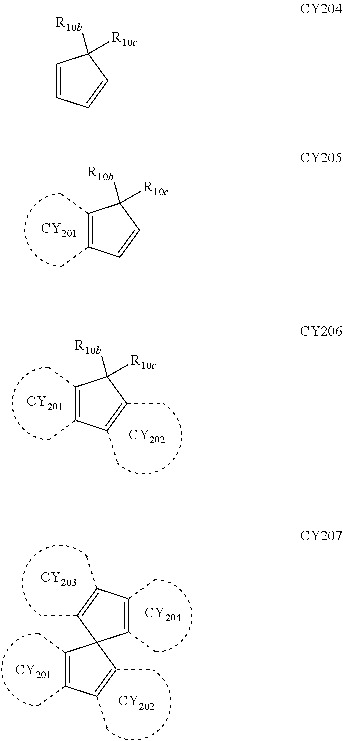

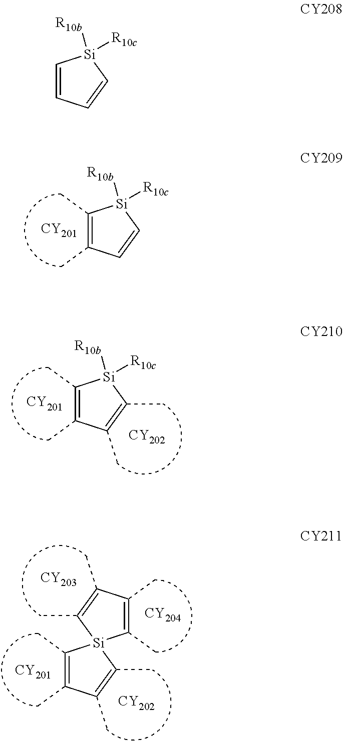

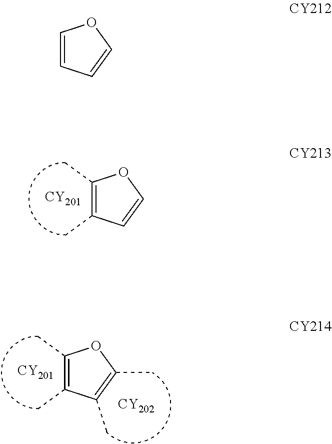

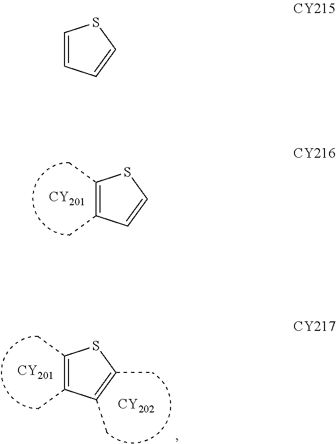

wherein, in Formulae CY201 to CY217, R_{10b} and R_{10c} may each be the same as defined with respect to R₁₀ₐ, ring CY201 to ring CY204 may each independently be a C₃-C₂₀ carbocyclic group or a C₁-C₂₀ heterocyclic group, and at least one hydrogen in Formulae CY201 to CY217 may be unsubstituted or substituted with R₁₀ₐ.

In one or more embodiments, in Formulae CY201 to CY217, ring CY₂₀₁ to ring CY₂₀₄ may each independently be a benzene group, a naphthalene group, a phenanthrene group, or an anthracene group.

In one or more embodiments, each of Formulae 201 and 202 may include at least one selected from among the groups represented by Formulae CY201 to CY203.

In one or more embodiments, Formula 201 may include at least one selected from among the groups represented by Formulae CY201 to CY203 and at least one selected from among the groups represented by Formulae CY204 to CY217.

In one or more embodiments, in Formula 201, xa1 may be 1, R₂₀₁ may be a group represented by one selected from among Formulae CY201 to CY203, xa2 may be 0, and R₂₀₂ may be a group represented by one selected from among Formulae CY204 to CY207.

In one or more embodiments, each of Formulae 201 and 202 may not include (e.g., may exclude any of) the groups represented by Formulae CY201 to CY203.

In one or more embodiments, each of Formulae 201 and 202 may not include (e.g., may exclude any of) the groups represented by Formulae CY201 to CY203 and may include at least one selected from among the groups represented by Formulae CY204 to CY217.

In one or more embodiments, each of Formulae 201 and 202 may not include (e.g., may exclude any of) the groups represented by Formulae CY201 to CY217.

For example, the hole transport region may include one of (e.g., at least one selected from among) Compounds HT1 to HT46, m-MTDATA, TDATA, 2-TNATA, NPB (NPD), β-NPB, TPD, Spiro-TPD, Spiro-NPB, methylated-NPB, TAPC, HMTPD, 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), poly[(9,9-dioctylfluorenyl-2,7-diyl)-co-(4,4′-(N-(4-sec-butylphenyl)diphenylamine)] (TFB), or a (e.g., any suitable) combination thereof:

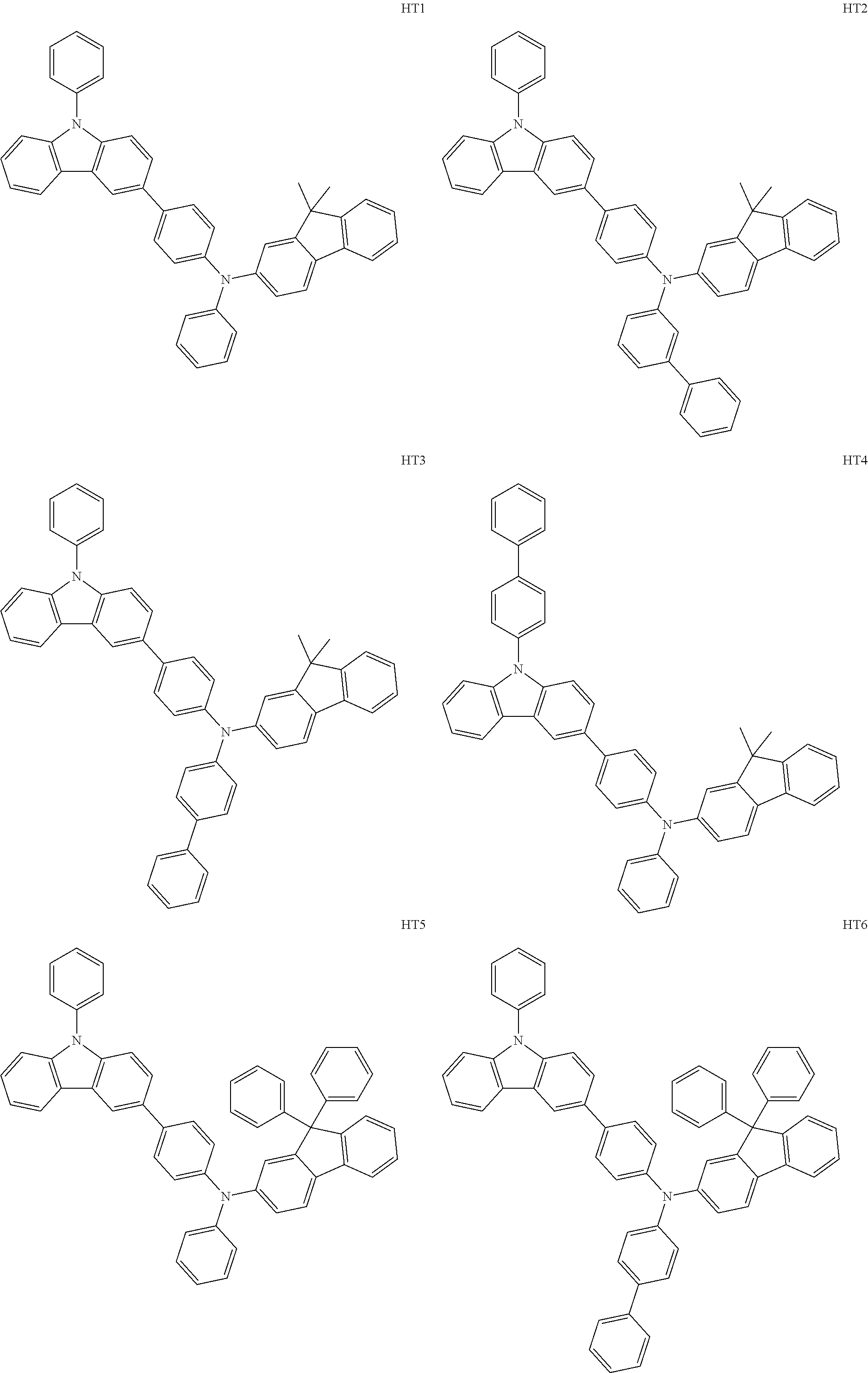

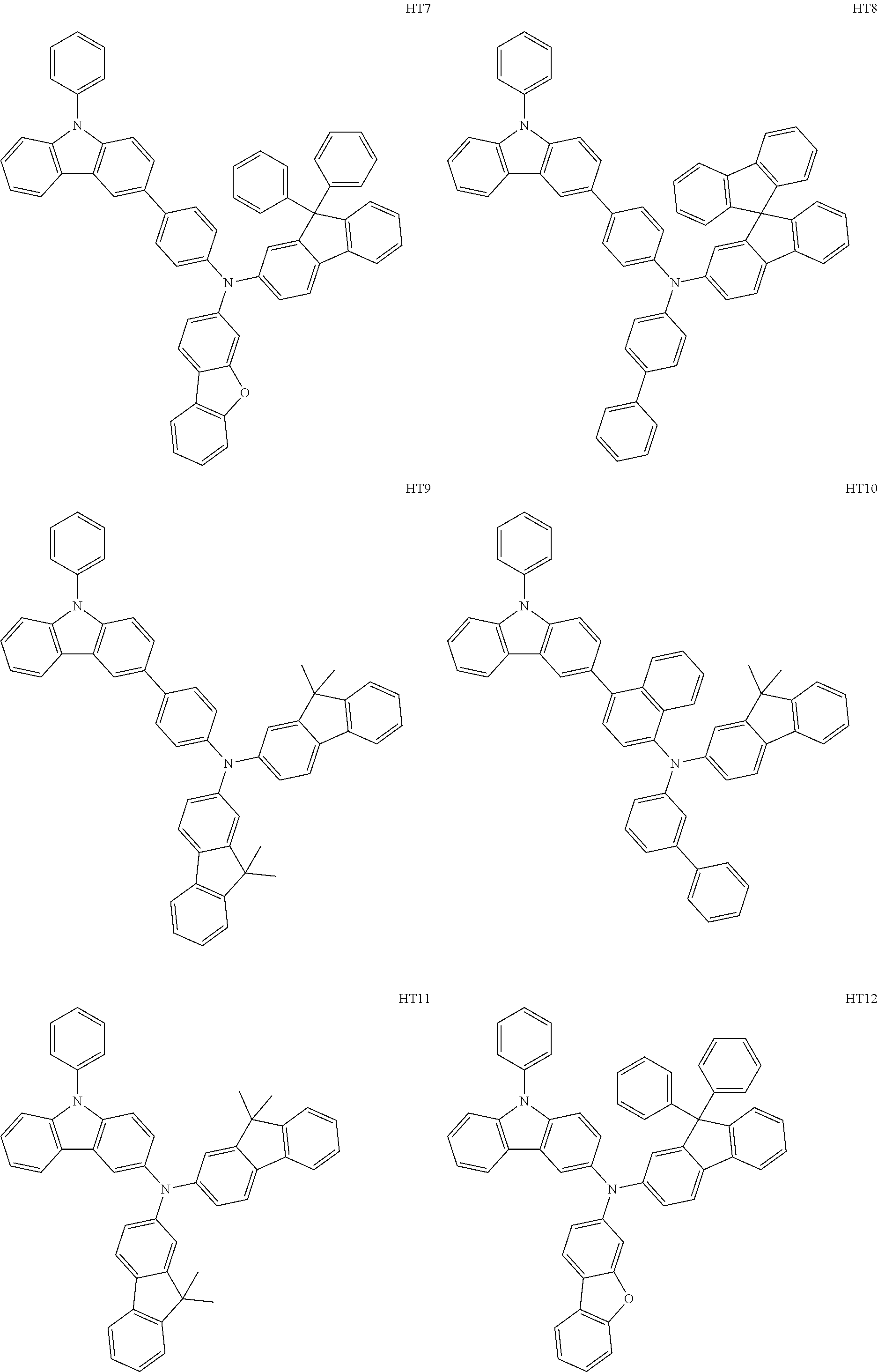

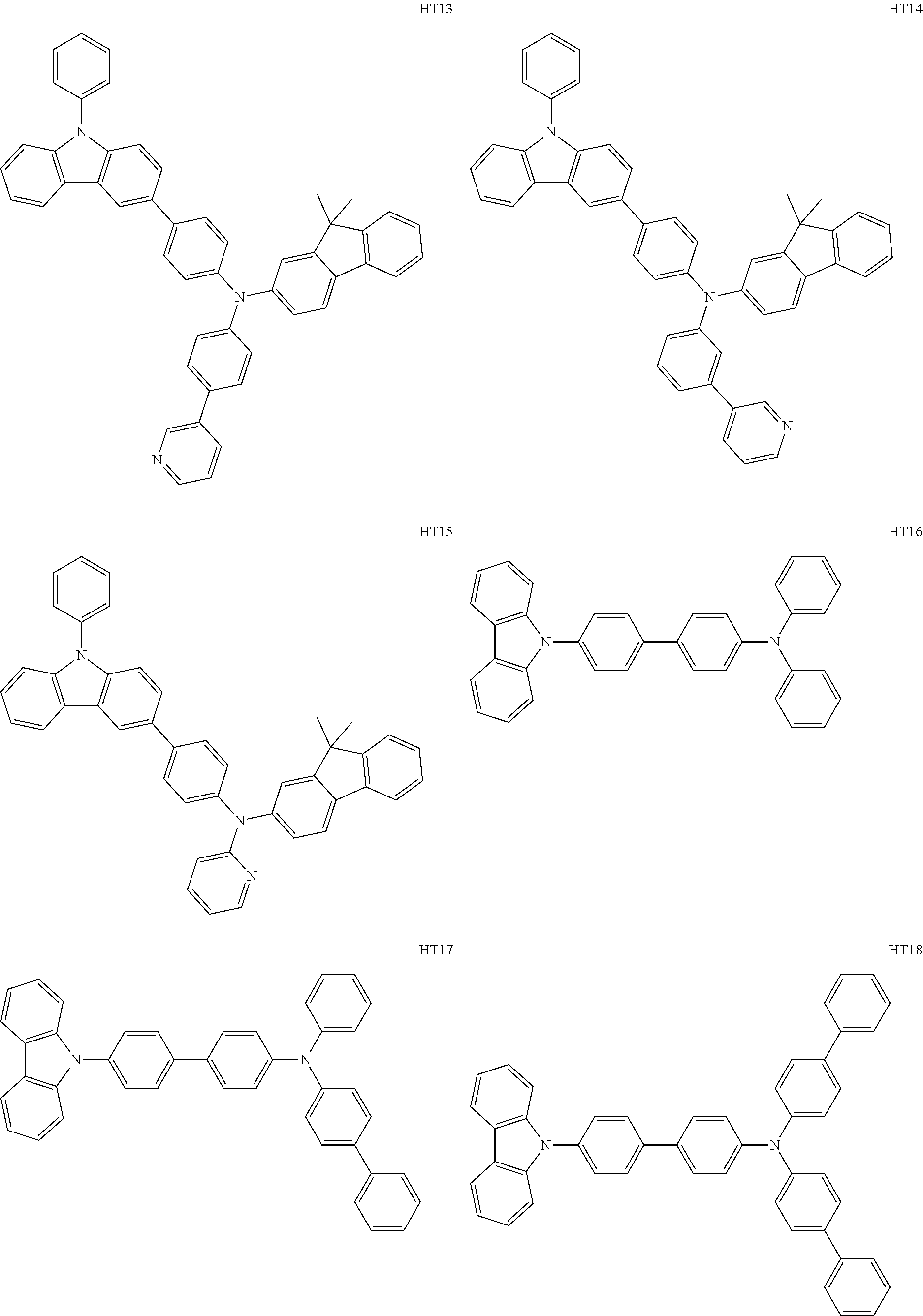 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

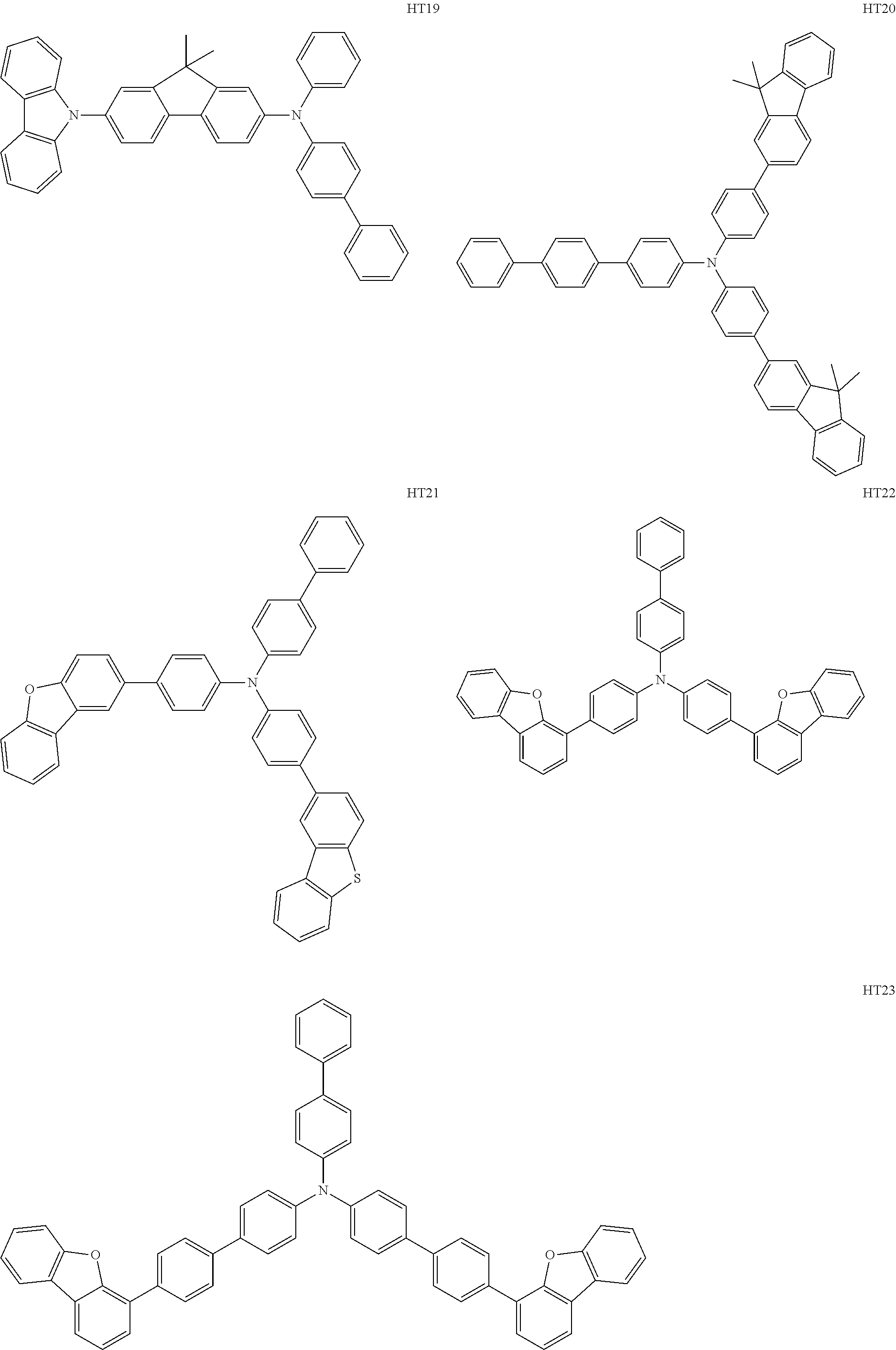 [SMILES: CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21 ; c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1]

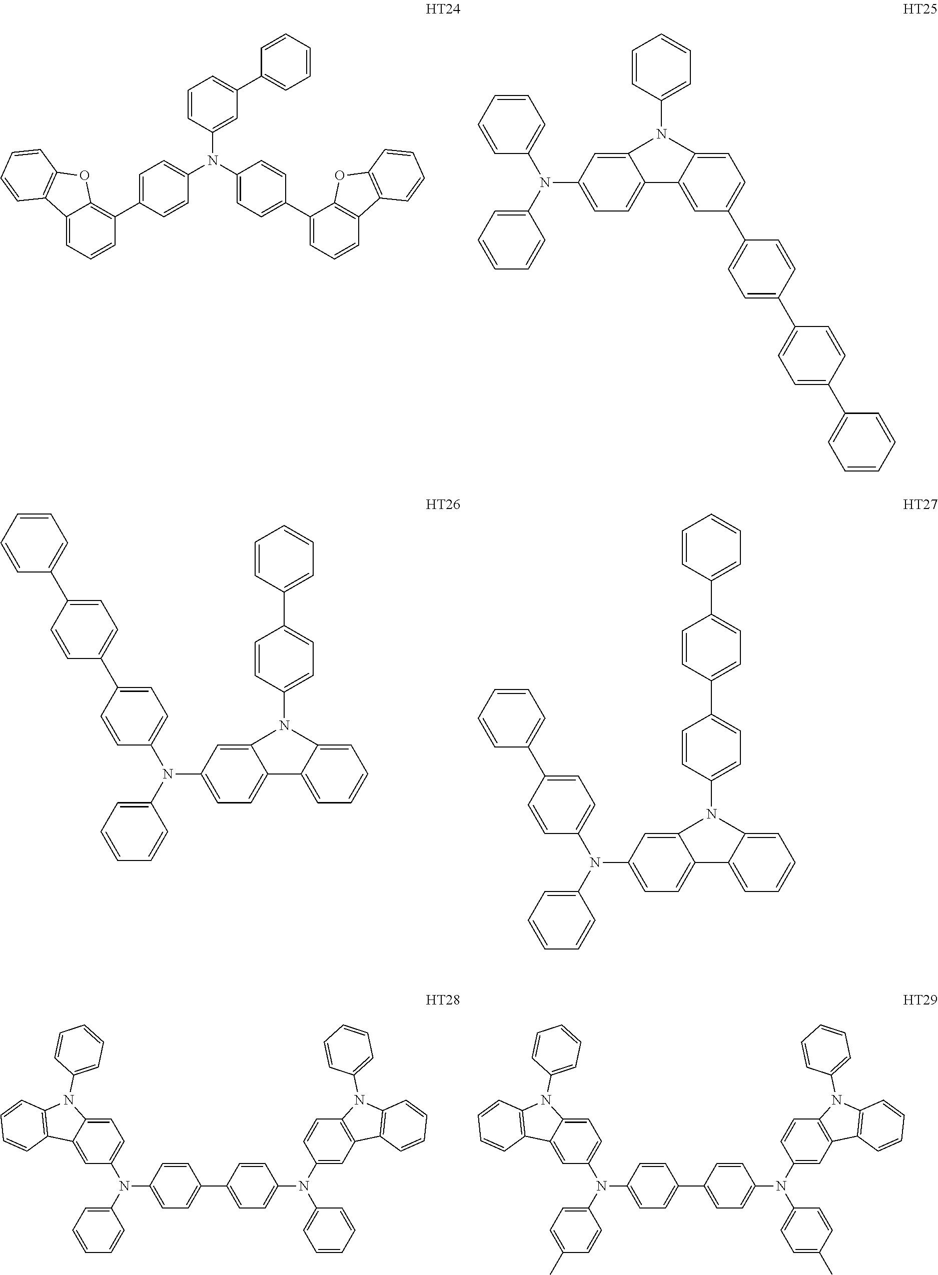

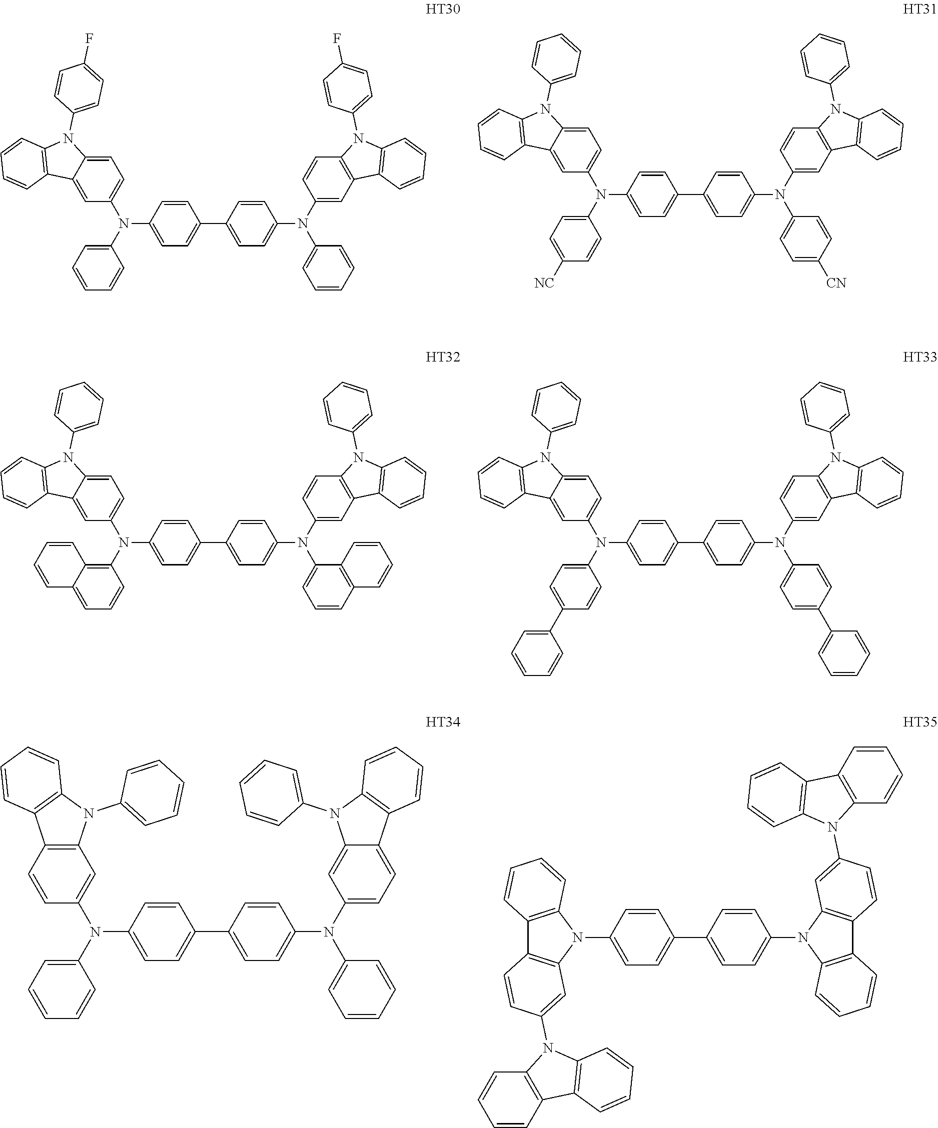

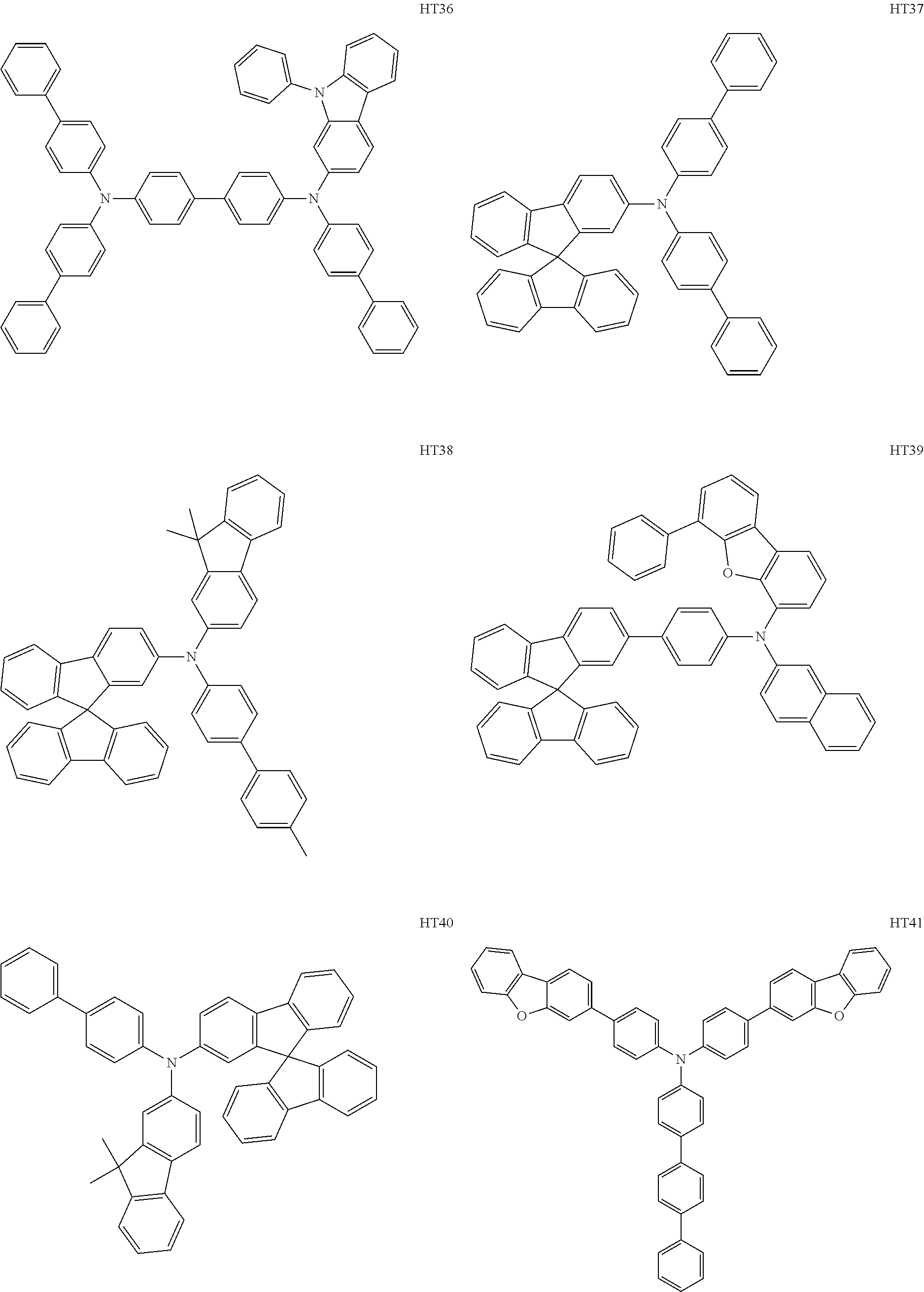

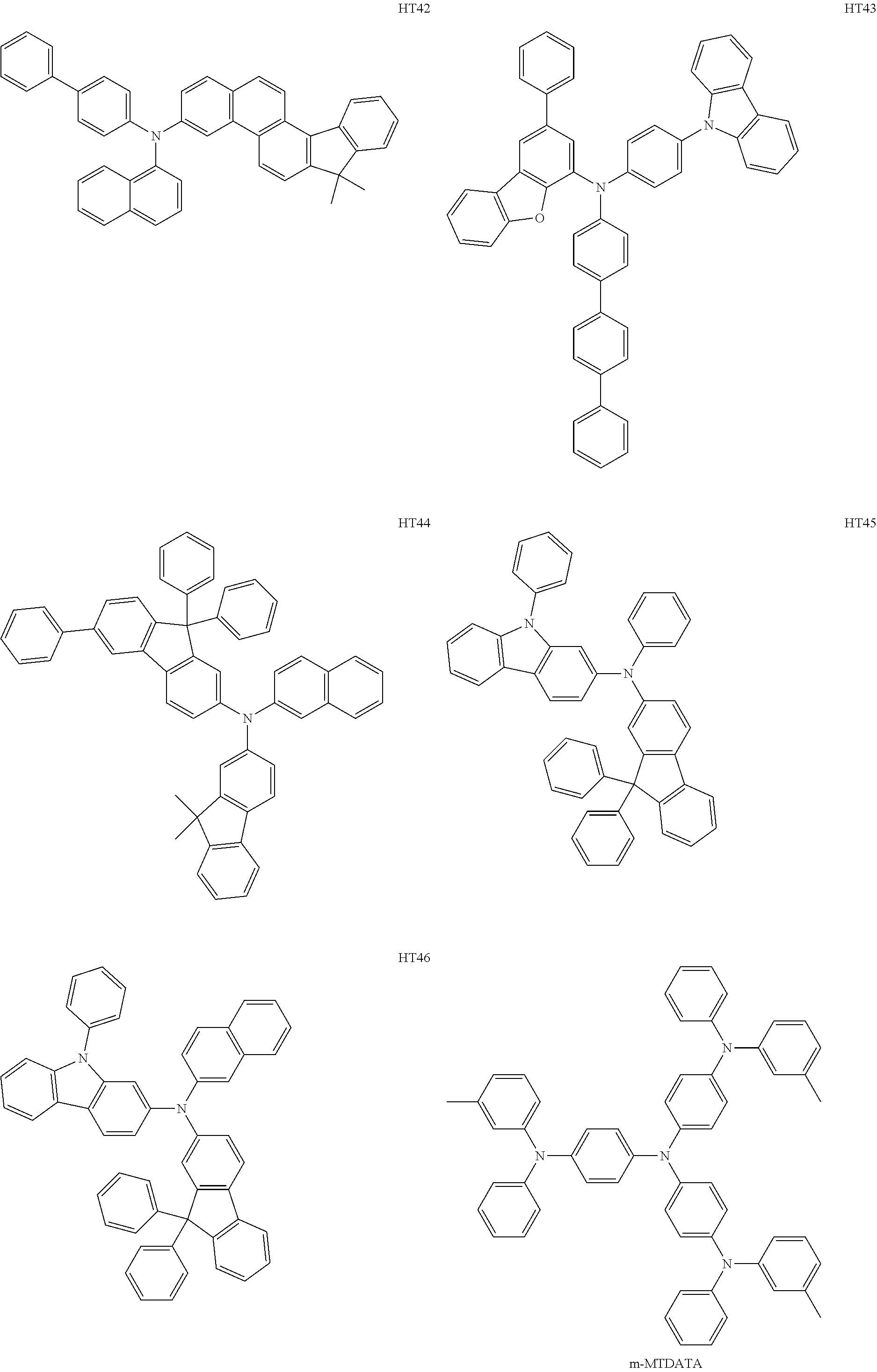

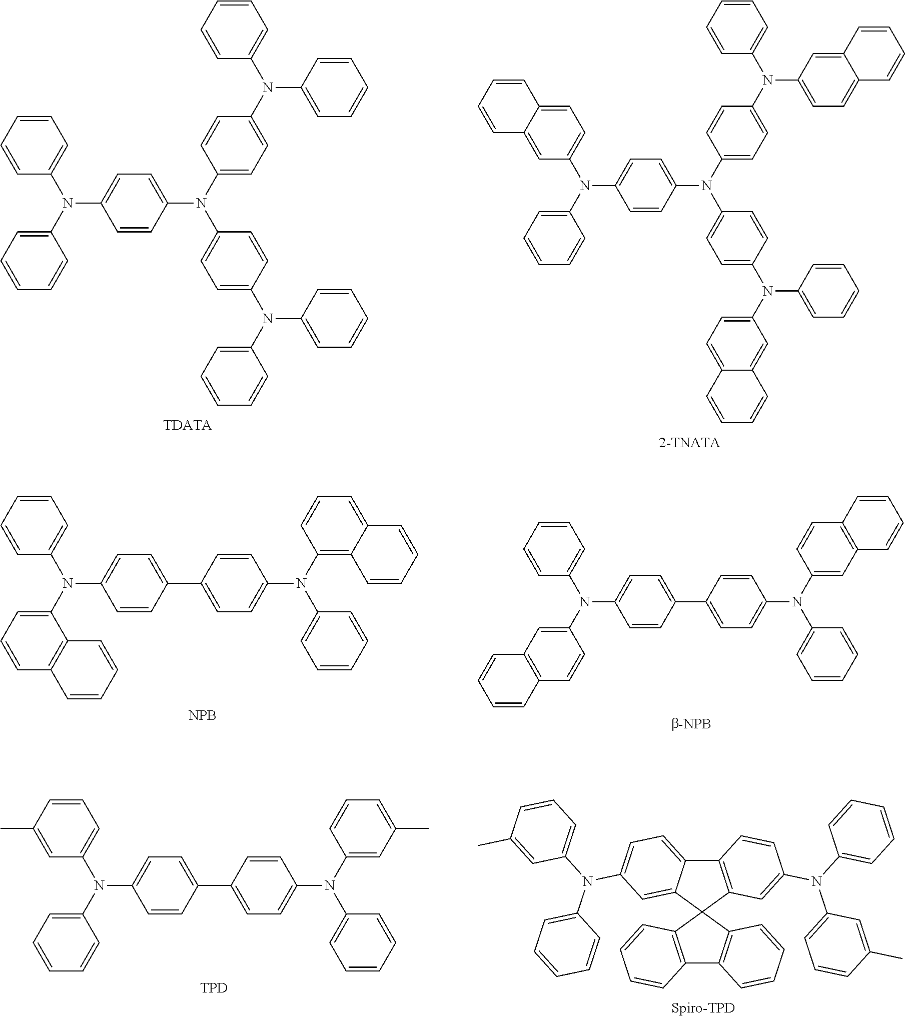

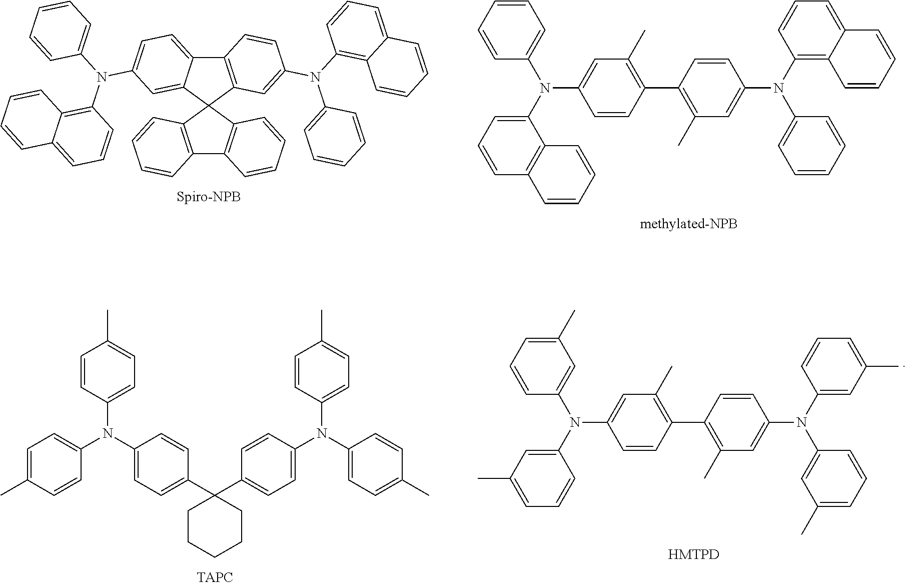

The thickness of the hole transport region may be about 50 Å to about 10,000 Å, for example, about 100 Å to about 4,000 Å. If (e.g., when) the hole transport region includes a hole injection layer, a hole transport layer, or a (e.g., any suitable) combination thereof, the thickness of the hole injection layer may be about 100 Å to about 9,000 Å, for example, about 100 Å to about 1,000 Å, and the thickness of the hole transport layer may be about 50 Å to about 2,000 Å, for example, about 100 Å to about 1,500 Å. If (e.g., when) the thicknesses of the hole transport region, the hole injection layer, and the hole transport layer are within the foregoing ranges, satisfactory or suitable hole transporting characteristics may be obtained without a substantial increase in driving voltage.

The emission auxiliary layer may be to increase or enhance light emission efficiency by compensating for an optical resonance distance according to the wavelength of light emitted by the emission layer, and the electron-blocking layer may be to block the leakage of electrons from the emission layer to the hole transport region. Materials that may be included in the hole transport region may be included in the emission auxiliary layer and the electron-blocking layer.

p-Dopant

The hole transport region may further include, in addition to the materials as described in one or more embodiments, a charge-generation material for the improvement or enhancement of conductive (e.g., electrically conductive) properties. The charge-generation material may be uniformly (e.g., substantially uniformly) or non-uniformly dispersed in the hole transport region (for example, in the form of a single layer consisting of (e.g., including) a charge-generation material).

The charge-generation material may be, for example, a p-dopant.

For example, the lowest unoccupied molecular orbital (LUMO) energy of the p-dopant may be less than or equal to −3.5 eV.

In one or more embodiments, the p-dopant may include a quinone derivative, a cyano group-containing compound, a compound including an element EL1 and an element EL2, or a (e.g., any suitable) combination thereof.

Examples of the quinone derivative may include TCNQ and/or F4-TCNQ.

Examples of the cyano group-containing compound may include HAT-CN and a compound represented by Formula 221:

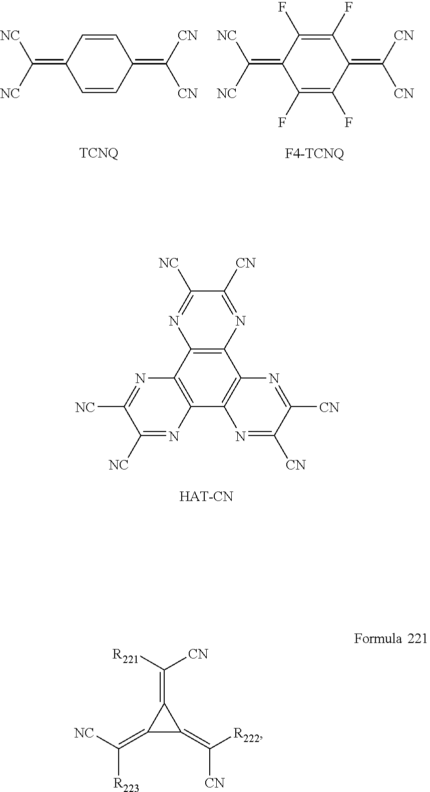

wherein, in Formula 221,
R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, and
at least one selected from among R₂₂₁ to R₂₂₃ may each independently be a C₃-C₆₀ carbocyclic group or a C₁-C₆₀ heterocyclic group, each unsubstituted or substituted with: a cyano group; —F; —Cl; —Br; —I; a C₁-C₂₀ alkyl group substituted with a cyano group, —F, —Cl, —Br, —I, or a (e.g., any suitable) combination thereof; or a (e.g., any suitable) combination thereof.

In the compound including the element EL1 and the element EL2, the element EL1 may be a metal, a metalloid, or a combination thereof, and the element EL2 may be a non-metal, a metalloid, or a combination thereof.

Examples of the metal may include an alkali metal (for example, lithium (Li), sodium (Na), potassium (K), rubidium (Rb), cesium (Cs), and/or the like); alkaline earth metal (for example, beryllium (Be), magnesium (Mg), calcium (Ca), strontium (Sr), barium (Ba), and/or the like); transition metal (for example, titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), and/or the like); post-transition metal (for example, zinc (Zn), indium (In), tin (Sn), and/or the like); and lanthanide metal (for example, lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), and/or the like).

Examples of the metalloid may include silicon (Si), antimony (Sb), and/or tellurium (Te).

Examples of the non-metal may include oxygen (O) and/or halogen (for example, F, Cl, Br, I, and/or the like).

Examples of the compound including the element EL1 and the element EL2 may include a metal oxide, a metal halide (for example, a metal fluoride, a metal chloride, a metal bromide, a metal iodide, and/or the like), a metalloid halide (for example, a metalloid fluoride, a metalloid chloride, a metalloid bromide, a metalloid iodide, and/or the like), a metal telluride, or a (e.g., any suitable) combination thereof.

Examples of the metal oxide may include a tungsten oxide (for example, WO, W₂O₃, WO₂, WO₃, W₂O₅, and/or the like), a vanadium oxide (for example, VO, V₂O₃, VO₂, V₂O₅, and/or the like), a molybdenum oxide (MoO, Mo₂O₃, MoO₂, MoO₃, Mo₂O₅, and/or the like), and/or a rhenium oxide (for example, ReO₃ and/or the like).

Examples of the metal halide may include an alkali metal halide, an alkaline earth metal halide, a transition metal halide, a post-transition metal halide, and/or a lanthanide metal halide.

Examples of the alkali metal halide may include LiF, NaF, KF, RbF, CsF, LiCl, NaCl, KCl, RbCl, CsCl, LiBr, NaBr, KBr, RbBr, CsBr, LiI, NaI, KI, RbI, and/or CsI.

Examples of the alkaline earth metal halide may include BeF₂, MgF₂, CaF₂, SrF₂, BaF₂, BeCl₂, MgCl₂, CaCl₂, SrCl₂, BaCl₂, BeBr₂, MgBr₂, CaBr₂, SrBr₂, BaBr₂, BeI₂, MgI₂, CaI₂, SrI₂, and/or BaI₂.

Examples of the transition metal halide may include a titanium halide (for example, TiF₄, TiCl₄, TiBr₄, TiI₄, and/or the like), a zirconium halide (for example, ZrF₄, ZrCl₄, ZrBr₄, ZrI₄, and/or the like), a hafnium halide (for example, HfF₄, HfCl₄, HfBr₄, HfI₄, and/or the like), a vanadium halide (for example, VF₃, VCl₃, VBr₃, VI₃, and/or the like), a niobium halide (for example, NbF₃, NbCl₃, NbBr₃, NbI₃, and/or the like), a tantalum halide (for example, TaF₃, TaCl₃, TaBr₃, TaI₃, and/or the like), a chromium halide (for example, CrF₃, CrCl₃, CrBr₃, CrI₃, and/or the like), a molybdenum halide (for example, MoF₃, MoCl₃, MoBr₃, MoI₃, and/or the like), a tungsten halide (for example, WF₃, WCl₃, WBr₃, WI₃, and/or the like), a manganese halide (for example, MnF₂, MnCl₂, MnBr₂, MnI₂, and/or the like), a technetium halide (for example, TcF₂, TcCl₂, TcBr₂, TcI₂, and/or the like), a rhenium halide (for example, ReF₂, ReCl₂, ReBr₂, ReI₂, and/or the like), an iron (II) halide (for example, FeF₂, FeCl₂, FeBr₂, FeI₂, and/or the like), a ruthenium halide (for example, RuF₂, RuCl₂, RuBr₂, RuI₂, and/or the like), an osmium halide (for example, OsF₂, OsCl₂, OsBr₂, OsI₂, and/or the like), a cobalt halide (for example, CoF₂, CoCl₂, CoBr₂, CoI₂, and/or the like), a rhodium halide (for example, RhF₂, RhCl₂, RhBr₂, RhI₂, and/or the like), an iridium halide (for example, IrF₂, IrCl₂, IrBr₂, IrI₂, and/or the like), a nickel halide (for example, NiF₂, NiCl₂, NiBr₂, NiI₂, and/or the like), a palladium halide (for example, PdF₂, PdCl₂, PdBr₂, PdI₂, and/or the like), a platinum halide (for example, PtF₂, PtCl₂, PtBr₂, PtI₂, and/or the like), a copper (I) halide (for example, CuF, CuCl, CuBr, CuI, and/or the like), a silver halide (for example, AgF, AgCl, AgBr, AgI, and/or the like), and/or a gold halide (for example, AuF, AuCl, AuBr, AuI, and/or the like).

Examples of the post-transition metal halide may include a zinc halide (for example, ZnF₂, ZnCl₂, ZnBr₂, ZnI₂, and/or the like), an indium halide (for example, InI₃ and/or the like), and/or a tin halide (for example, SnI₂ and/or the like).

Examples of the lanthanide metal halide may include YbF, YbF₂, YbF₃, SmF₃, YbCl, YbCl₂, YbCl₃SmCl₃, YbBr, YbBr₂, YbBr₃, SmBr₃, YbI, YbI₂, YbI₃, and/or SmI₃.

Examples of the metalloid halide may include an antimony halide (for example, SbCl₅ and/or the like).

Examples of the metal telluride may include an alkali metal telluride (for example, Li₂Te, Na₂Te, K₂Te, Rb₂Te, Cs₂Te, and/or the like), an alkaline earth metal telluride (for example, BeTe, MgTe, CaTe, SrTe, BaTe, and/or the like), a transition metal telluride (for example, TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, CuzTe, CuTe, Ag₂Te, AgTe, Au₂Te, and/or the like), a post-transition metal telluride (for example, ZnTe and/or the like), and/or a lanthanide metal telluride (for example, LaTe, CeTe, PrTe, NdTe, PmTe, EuTe, GdTe, TbTe, DyTe, HoTe, ErTe, Tm Te, YbTe, LuTe, and/or the like).

### Emission Layer in Interlayer 130

The emission layer may be formed or manufactured from the quantum dot composition according to one or more embodiments.

In one or more embodiments, the emission layer may include the quantum dots and ZnS as described in one or more embodiments. ZnS may be distributed between the quantum dots, and the ligand bonded to ZnS may be cross-linked. The emission layer may further include thiourea which is a degradation product of a precursor of ZnS as described in one or more embodiments.

As ZnS fills the space between the quantum dots, the penetration of the metal oxide nanoparticles of the electron transfer layer and generation of leakage current may be prevented (or a degree or occurrence of the penetration of the metal oxide nanoparticles of the electron transfer layer and generation of leakage current may be reduced), and aggregation of the quantum dots may be prevented (or a degree or occurrence of aggregation of the quantum dots may be reduced) to facilitate substantially uniform formation of the quantum dot thin film. In one or more embodiments, as the ligand bonded to ZnS is cross-linked, damage to the quantum dot thin film by the solvent of the upper layer may be prevented (or a degree or occurrence of damage to the quantum dot thin film by the solvent of the upper layer may be reduced).

In one or more embodiments, the emission layer may further include, in addition to the quantum dot and ZnS as described in one or more embodiments, a dispersion medium in which the quantum dot is naturally dispersed in a coordinated form. The dispersion medium may include an organic solvent, a polymer resin, or a (e.g., any suitable) combination thereof. The dispersion medium may be any suitable transparent medium that does not affect the optical performance of the quantum dot, is not deteriorated by light, does not reflect light, or does not absorb light. For example, the organic solvent may include toluene, chloroform, ethanol, octane, or a (e.g., any suitable) combination thereof, and the polymer resin may include an epoxy resin, a silicone resin, a polystyrene resin, an acrylate resin, or a (e.g., any suitable) combination thereof.

The emission layer may be formed or arranged by applying the quantum dot composition including the quantum dots on a hole transport region and volatilizing one or more of the solvent included in the quantum dot composition.

For example, the solvent may be as described in one or more embodiments.

The coating of the quantum dot composition may be performed by utilizing a spin coat method, a casting method, a micro gravure coating method, a gravure coating method, a bar coating method, a roll coating method, a wire bar coating method, a dip coating method, a spray coating method, a screen printing method, a flexographic method, an offset printing method, an ink jet printing method, and/or the like.

If (e.g., when) the light-emitting device 10 is a full color light-emitting device, the emission layer may include emission layers emitting different colors according to individual sub-pixels.

For example, the emission layer may be patterned into a first color emission layer, a second color emission layer, and a third color emission layer according to individual subpixels. Herein, at least one emission layer of the emission layers as described in one or more embodiments may essentially include the quantum dot. For example, the first color emission layer may be a quantum-dot emission layer including the quantum dot, and the second color emission layer and the third color emission layer may be organic emission layers including organic compounds, respectively. In this regard, the first color through the third color may be different colors, and for example, the first color through the third color may have different maximum luminescence wavelengths. The first color through the third color may be white if (e.g., when) combined with each other. For example, the emission layer may be patterned into subpixels of different colors—for example, the first color emission layer, the second color emission layer, and the third color emission layer. At least one of these layers, such as the first color emission layer, may include quantum dot(s), while the others (e.g., second and third color emission layers) may utilize organic compound(s). These layers may emit different colors with distinct peak wavelengths, and if (e.g., when) combined, they may produce white light.

In one or more embodiments, the emission layer may further include a fourth color emission layer, and at least one emission layer selected from among the first color to fourth color emission layers may be a quantum dot emission layer including the quantum dot, and the remaining emission layers may be organic emission layers including organic compounds, respectively. Other one or more suitable modifications may be feasible. In this regard, the first color through the fourth color may be different colors, and for example, the first color through the fourth color may have different maximum luminescence wavelengths. The first color through the fourth color may be white if (e.g., when) combined with each other.

In one or more embodiments, the light-emitting device 10 may have a stacked structure in which two or more emission layers that emit light of substantially identical or different colors contact each other or are separated from each other. At least one emission layer selected from among the at least two emission layers may be a quantum dot emission layer including the quantum dots, and the other emission layer may be an organic emission layer including organic compounds. Such a variation may be made. For example, the light-emitting device 10 may include a first color emission layer and a second color emission layer, and the first color and the second color may be substantially the same color or different colors. For example, both (e.g., simultaneously) the first color and the second color may be green or blue.

The emission layer may include at least one selected from among an organic compound and a semiconductor compound. In more detail, the organic compound may include a host and a dopant. The host and the dopant may include a host and a dopant that are generally available or generally used in organic light-emitting devices, respectively.

For example, the semiconductor compound may be an organic perovskite and/or an inorganic perovskite.

### Electron Transport Region in Interlayer 130

The electron transport region may have: i) a single-layered structure consisting of (e.g., including) a single layer consisting of (e.g., including) a single material, ii) a single-layered structure consisting of (e.g., including) a single layer including two or more different materials, or iii) a multilayer structure including two or more layers including two or more different materials.

The electron transport region may include at least one selected from among a buffer layer, a hole-blocking layer, an electron control layer, an electron transport layer, and an electron injection layer; however, embodiments of the present disclosure are not limited thereto.

For example, the electron transport region may have an electron transport layer/electron injection layer structure, a hole-blocking layer/electron transport layer/electron injection layer structure, an electron control layer/electron transport layer/electron injection layer structure, or an electron transport layer/electron injection layer structure, wherein for each structure, constituting layers are sequentially stacked from an emission layer. However, embodiments of the present disclosure are not limited thereto.

The electron transport region may include a conductive (e.g., electrically conductive) metal oxide and/or an organic material.

In one or more embodiments, the electron transport region (for example, the electron injection layer or the electron transport layer in the electron transport region) may include a metal oxide represented by Formula 4:

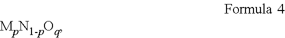

wherein, in Formula 4,
M and N may each independently be Zn, Mg, Al, Li, Fe, In, Na, Ti, Zr, Sn, W, Ta, Ni, Mo, Cu, V, or a (e.g., any suitable) combination thereof,
0≤p≤1, and 0.01≤q≤5.

In one or more embodiments, the metallic compound may be represented by Formula 4-1:

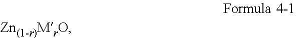

wherein, in Formula 4-1,
M′ may be Mg, Co, Ni, Zr, Mn, Sn, Y, Al, or a (e.g., any suitable) combination thereof, and
r may be a number greater than 0 and equal to or less than 0.5.

In one or more embodiments, the electron transport region may include ZnO and/or ZnMgO.

For example, the electron transport region may include, ZnO, TiO₂, WO₃, SnO₂, In₂O₃, Nb₂O₅, Fe₂O₃, CeO₂, SrTiO₃, Zn₂SnO₄, BaSnO₃, ZnSiO, Mg-doped ZnO (ZnMgO), Al-doped ZnO (AZO), Ga-doped ZnO (GZO), In-doped ZnO (IZO), Al-doped TiO₂, Ga-doped TiO₂, In-doped TiO₂, Al-doped WO₃, Ga-doped WO₃, In-doped WO₃, Al-doped SnO₂, Ga-doped SnO₂, In-doped SnO₂, Mg-doped In₂O₃, Al-doped In₂O₃, Ga-doped In₂O₃, Mg-doped Nb₂O₅, Al-doped Nb₂O₅, Ga-doped Nb₂O₅, Mg-doped Fe₂O₃, Al-doped Fe₂O₃, Ga-doped Fe₂O₃, In-doped Fe₂O₃, Mg-doped CeO₂, Al-doped CeO₂, Ga-doped CeO₂, In-doped CeO₂, Mg-doped SrTiO₃, Al-doped SrTiO₃, Ga-doped SrTiO₃, In-doped SrTiO₃, Mg-doped Zn₂SnO₄, Al-doped Zn₂SnO₄, Ga-doped Zn₂SnO₄, In-doped Zn₂SnO₄, Mg-doped BaSnO₃, Al-doped BaSnO₃, Ga-doped BaSnO₃, In-doped BaSnO₃, Mg-doped ZnSiO, Al-doped ZnSiO, Ga-doped ZnSiO, In-doped ZnSiO, or a (e.g., any suitable) combination thereof.

In one or more embodiments, the electron transport region (for example, the buffer layer, the hole-blocking layer, the electron control layer, or the electron transport layer in the electron transport region) may include a metal-free compound including at least one π electron-deficient nitrogen-containing C₁-C₆₀ heterocyclic group.

In one or more embodiments, the electron transport region may include a compound represented by Formula 601:

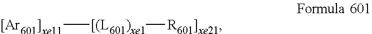

wherein, in Formula 601,
Ar₆₀₁ and L₆₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xe11 may be 1, 2, or 3,
xe1 may be 0, 1, 2, 3, 4, or 5,
R₆₀₁ may be a C₃-C₆₀ carbocyclic group that is unsubstituted or substituted with at least one R₁₀ₐ, a C₁-C₆₀ heterocyclic group that is unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ may each be the same as defined with respect to Q₁,
xe21 may be 1, 2, 3, 4, or 5, and
at least one selected from among Ar₆₀₁, L₆₀₁, and R₆₀₁ may each independently be a π electron-deficient nitrogen-containing C₁-C₆₀ heterocyclic group unsubstituted or substituted with at least one R₁₀ₐ.

In one or more embodiments, if (e.g., when) xe11 in Formula 601 is 2 or more, two or more of Ar₆₀₁ may be linked together via a single bond (e.g., a single covalent bond).

In one or more embodiments, Ar₆₀₁ in Formula 601 may be an anthracene group that is unsubstituted or substituted with at least one R₁₀ₐ.

In one or more embodiments, the electron transport region may include a compound represented by Formula 601-1:

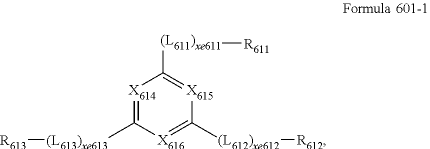

wherein, in Formula 601-1,
X₆₁₄ may be N or C(R₆₁₄), X₆₁₅ may be N or C(R₆₁₅), X₆₁₆ may be N or C(R₆₁₆), and at least one selected from among X₆₁₄ to X₆₁₆ may be N,
L₆₁₁ to L₆₁₃ may each be the same as defined with respect to L₆₀₁,
xe611 to xe613 may each be the same as defined with respect to xe1,
R₆₁₁ to R₆₁₃ may each be the same as defined with respect to R₆₀₁, and
R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group that is unsubstituted or substituted with at least one R₁₀ₐ, or a C₁-C₆₀ heterocyclic group that is unsubstituted or substituted with at least one R₁₀ₐ.

In one or more embodiments, xe1 and xe611 to xe613 in Formulae 601 and 601-1 may each independently be 0, 1, or 2.

The electron transport region may include one of (e.g., at least one selected from among among) Compounds ET1 to ET45, 2,9-dimethyl-4,7-diphenyl-1,10-phenanthroline (BCP), 4,7-diphenyl-1,10-phenanthroline (Bphen), Alq₃, BAlq, TAZ, NTAZ, or a (e.g., any suitable) combination thereof:

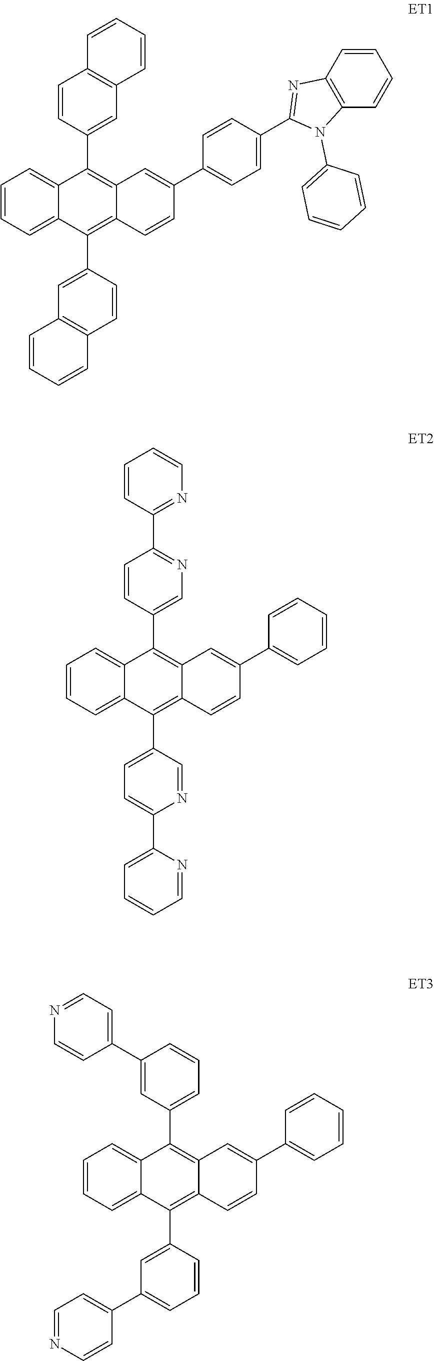 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

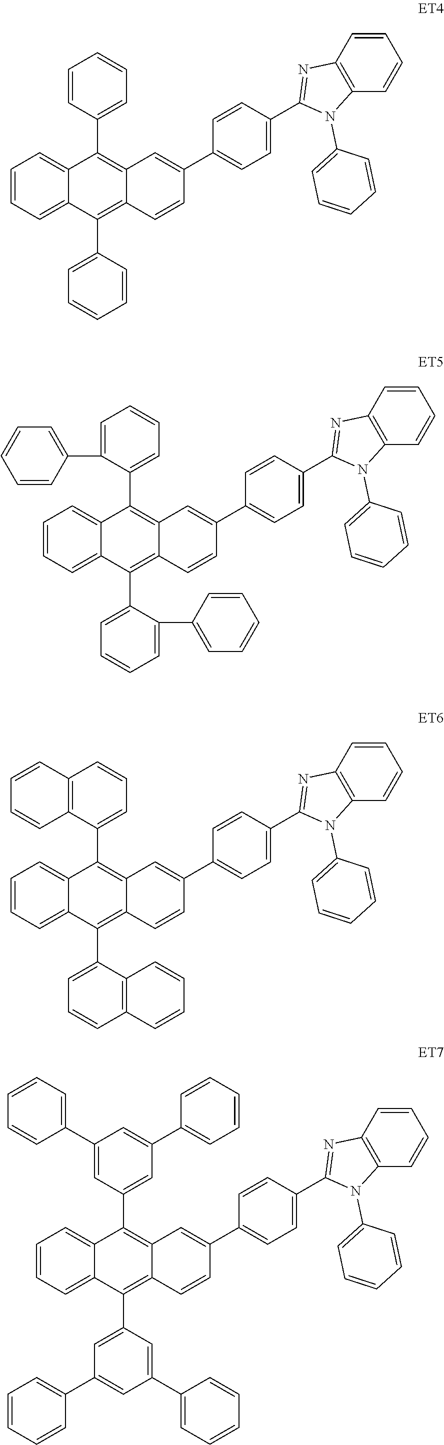 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

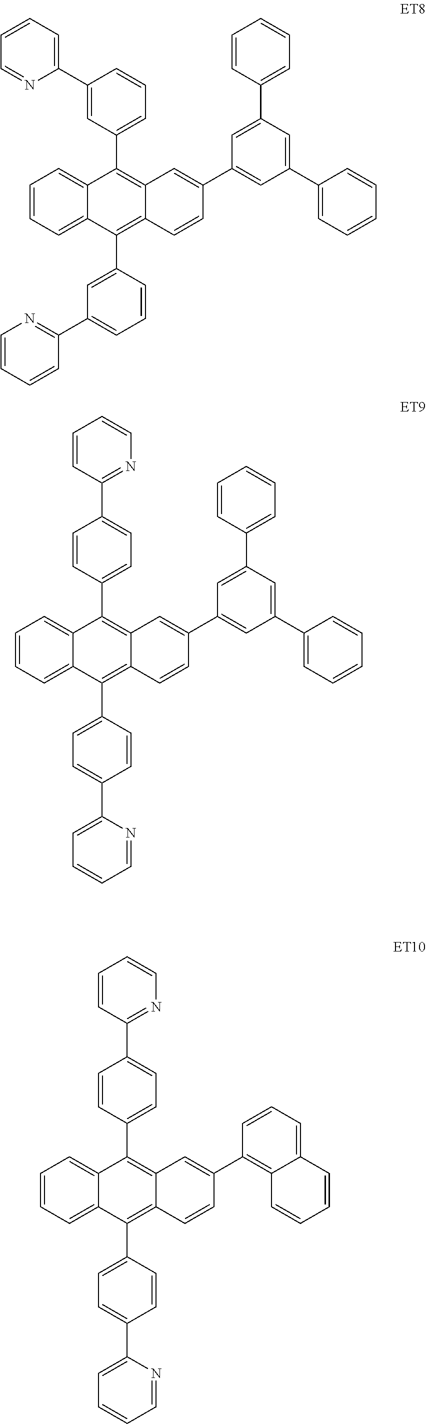 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

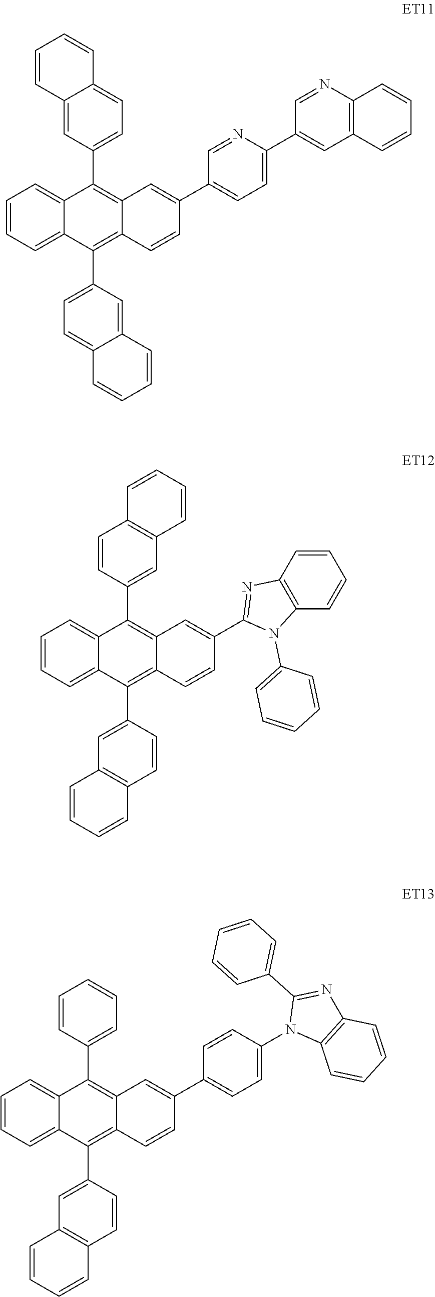 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

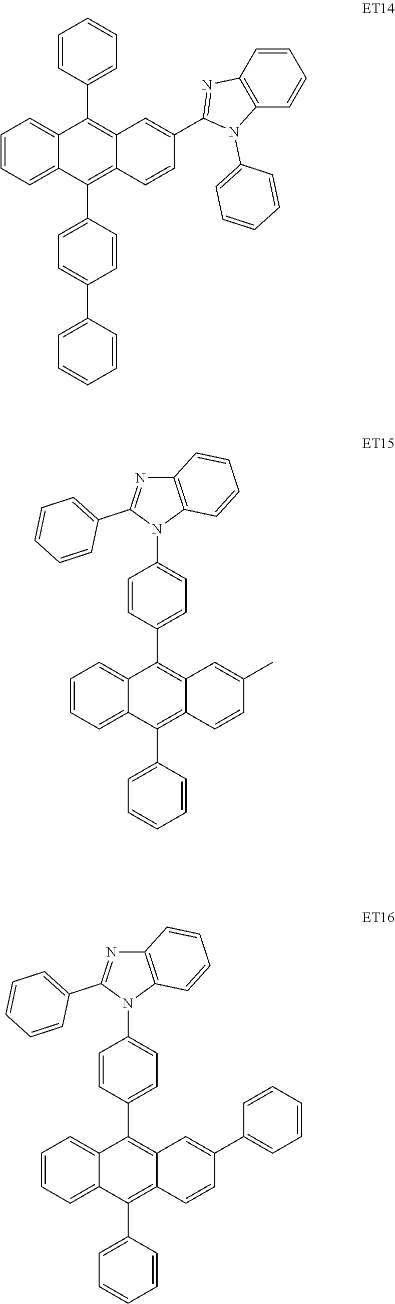 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

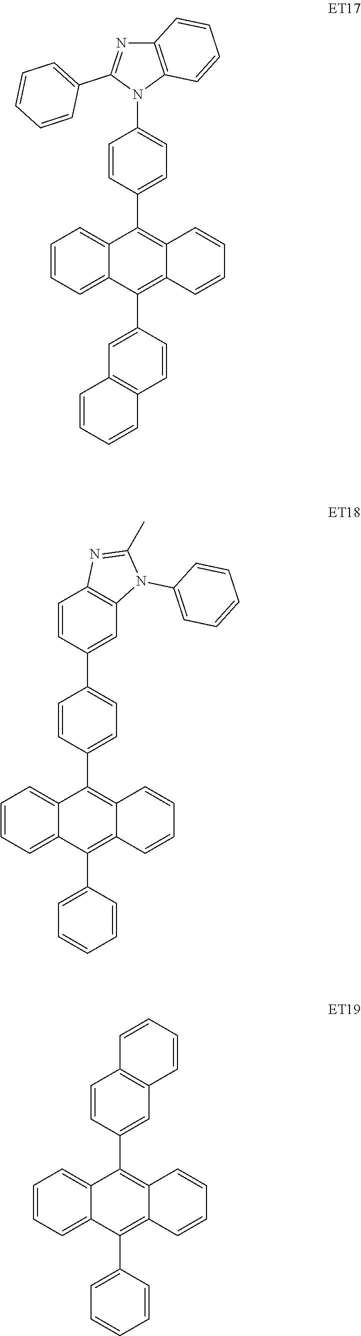

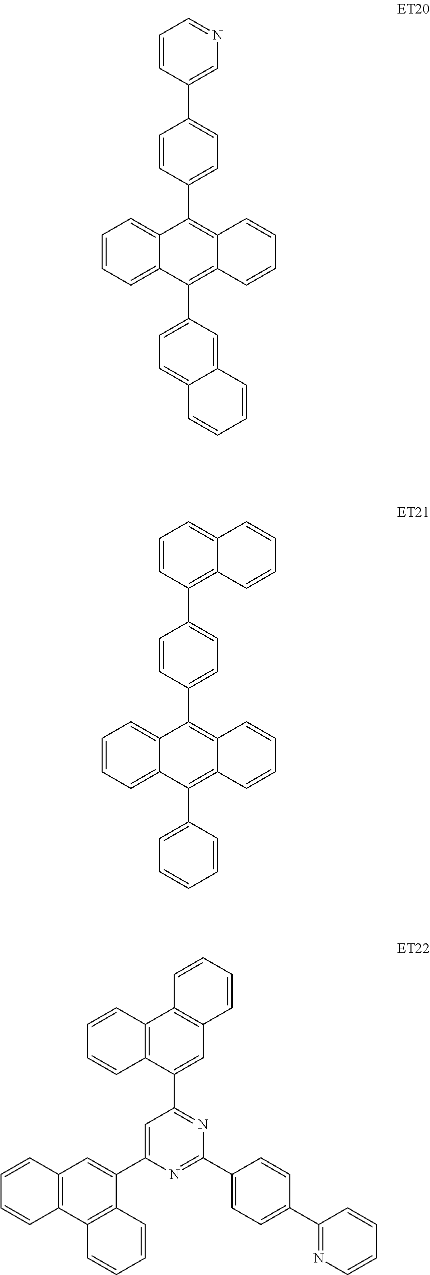

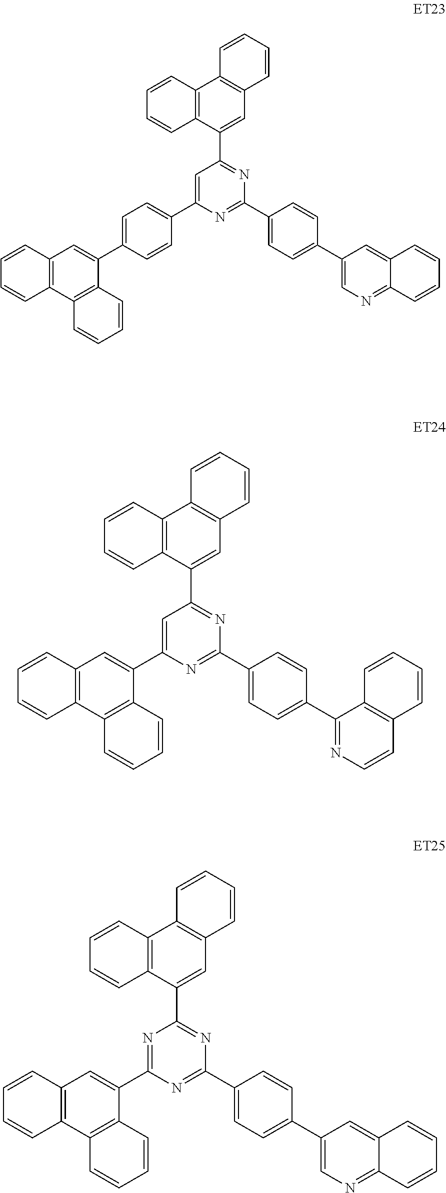 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

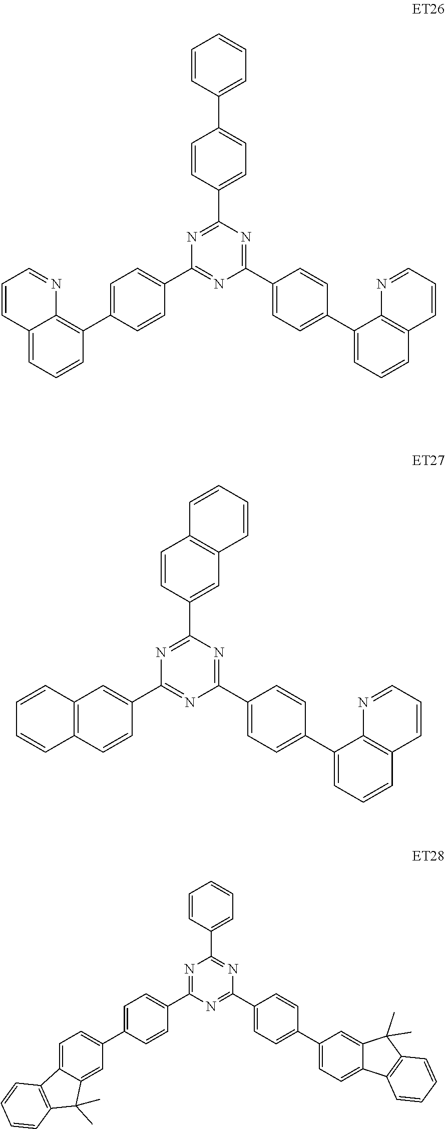 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

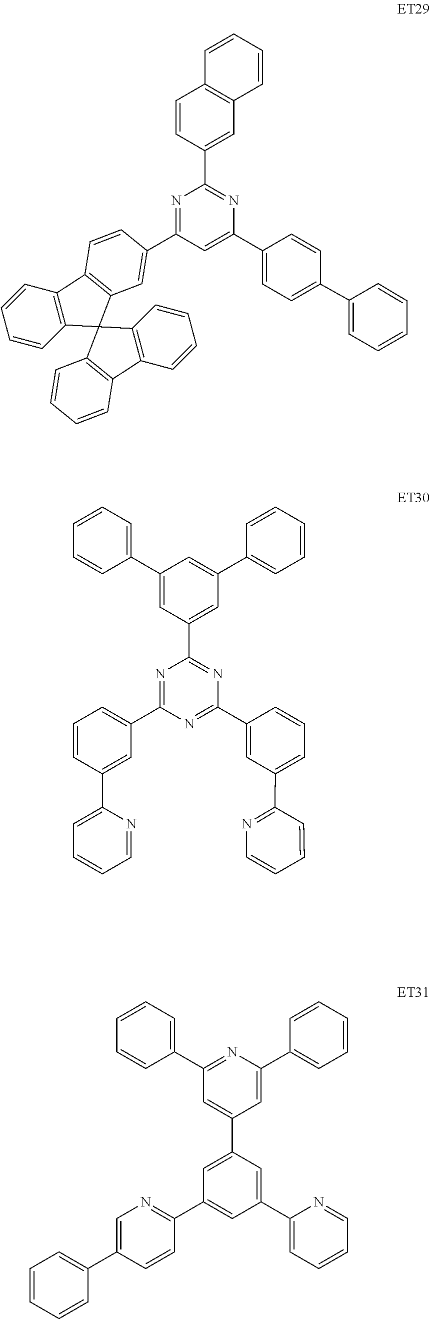 [SMILES: c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1]

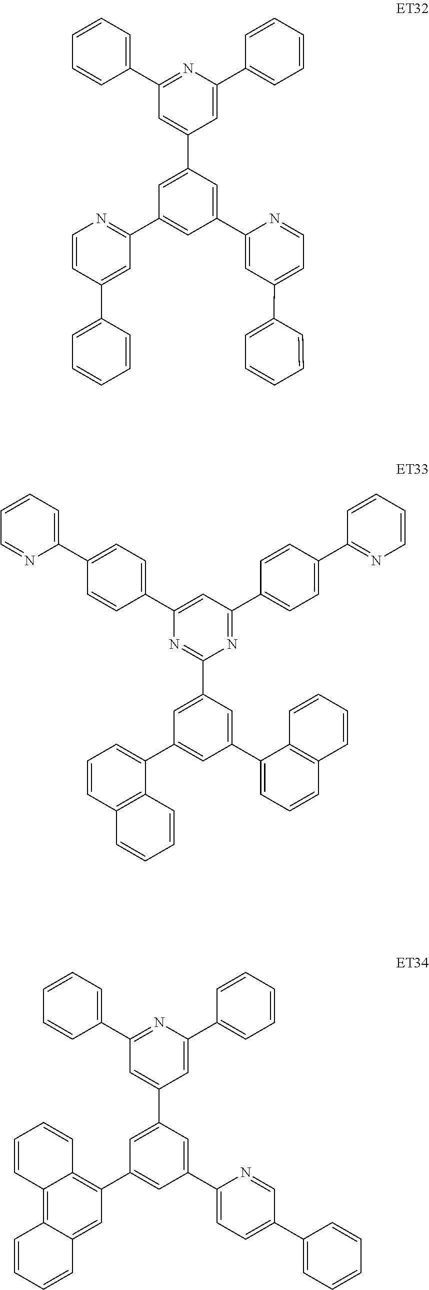 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

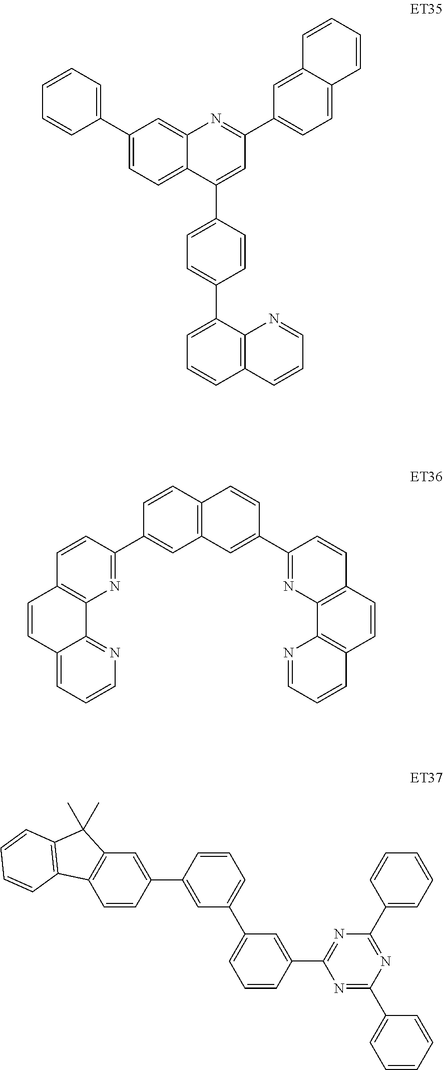 [SMILES: c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12 ; CC1(C)c2ccccc2-c2ccc(-c3cccc(-c4cccc(-c5nc(-c6ccccc6)nc(-c6ccccc6)n5)c4)c3)cc21]

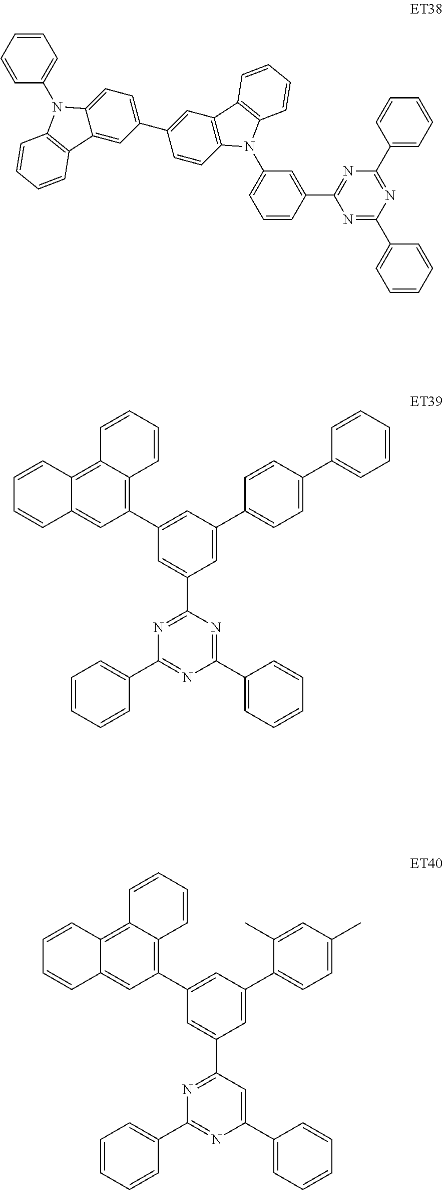 [SMILES: c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2ccc(-c3cc(-c4nc(-c5ccccc5)nc(-c5ccccc5)n4)cc(-c4cc5ccccc5c5ccccc45)c3)cc2)cc1 ; Cc1ccc(-c2cc(-c3cc(-c4ccccc4)nc(-c4ccccc4)n3)cc(-c3cc4ccccc4c4ccccc34)c2)c(C)c1]

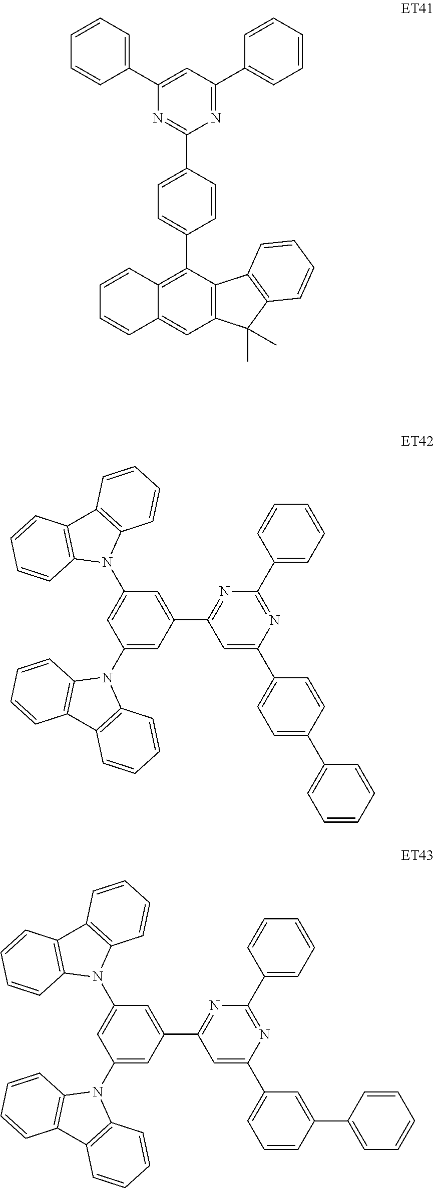 [SMILES: CC1(C)c2ccccc2-c2c1cc1ccccc1c2-c1ccc(-c2nc(-c3ccccc3)cc(-c3ccccc3)n2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1]

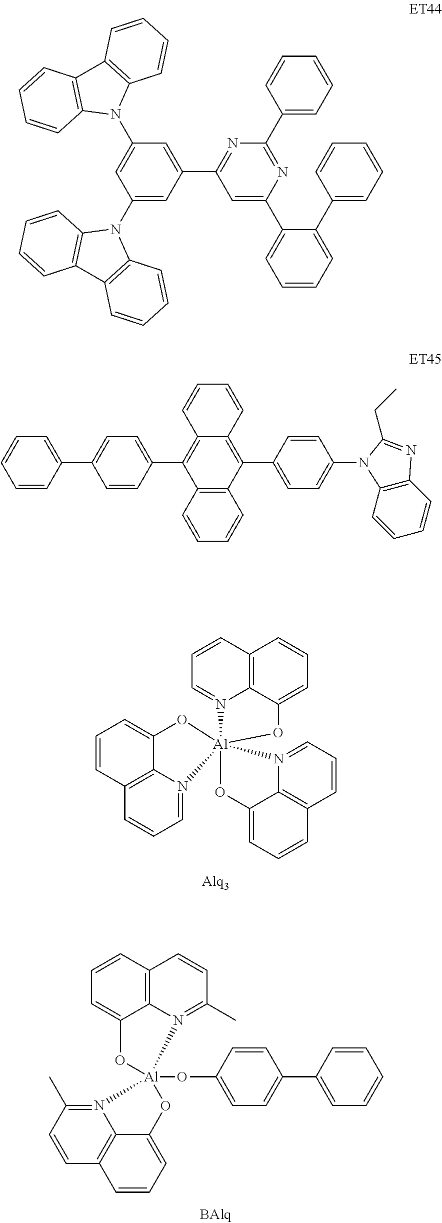

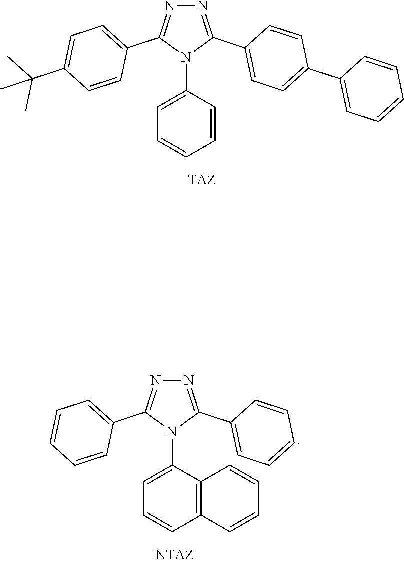 [SMILES: CC(C)(C)c1ccc(-c2nnc(-c3ccc(-c4ccccc4)cc3)n2-c2ccccc2)cc1 ; c1ccc(-c2nnc(-c3ccccc3)n2-c2cccc3ccccc23)cc1]

The thickness of the electron transport region may be about 100 Å to about 5,000 Å, for example, about 160 Å to about 4,000 Å. If (e.g., when) the electron transport region includes a buffer layer, a hole-blocking layer, an electron control layer, an electron transport layer, or a (e.g., any suitable) combination thereof, a thickness of the buffer layer, the hole-blocking layer, or the electron control layer may each independently be in a range of about 20 Å to about 1,000 Å, for example, about 30 Å to about 300 Å, and a thickness of the electron transport layer may be in a range of about 100 Å to about 1,000 Å, for example, about 150 Å to about 500 Å. If (e.g., when) the thickness of the buffer layer, the hole-blocking layer, the electron control layer, and/or the electron transport layer are within the foregoing ranges, satisfactory or suitable electron transporting characteristics may be obtained without a substantial increase in driving voltage.

The electron transport region (for example, the electron transport layer in the electron transport region) may further include, in addition to the materials as described in one or more embodiments, a metal-containing material.

The metal-containing material may include an alkali metal complex, an alkaline earth metal complex, or a (e.g., any suitable) combination thereof. A metal ion of the alkali metal complex may be a Li ion, a Na ion, a K ion, a Rb ion, or a Cs ion, and a metal ion of the alkaline earth metal complex may be a Be ion, a Mg ion, a Ca ion, a Sr ion, or a Ba ion. A ligand coordinated with the metal ion of the alkali metal complex or the alkaline earth-metal complex may include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or a (e.g., any suitable) combination thereof.

In one or more embodiments, the metal-containing material may include a Li complex. The Li complex may include, for example, Compound ET-D1 (LiQ) and/or ET-D2:

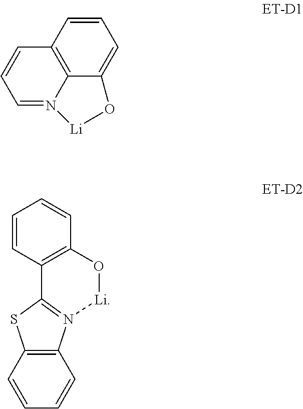

The electron transport region may include an electron injection layer that facilitates the injection of electrons from the second electrode 150. The electron injection layer may directly contact the second electrode 150.

The electron injection layer may have: i) a single-layered structure consisting of (e.g., including) a single layer consisting of (e.g., including) a single material, ii) a single-layered structure consisting of (e.g., including) a single layer including two or more different materials, or iii) a multilayer structure including two or more layers including two or more different materials.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or a (e.g., any suitable) combination thereof.

The alkali metal may include Li, Na, K, Rb, Cs, or a (e.g., any suitable) combination thereof. The alkaline earth metal may include Mg, Ca, Sr, Ba, or a (e.g., any suitable) combination thereof. The rare earth metal may include Sc, Y, Ce, Tb, Yb, Gd, or a (e.g., any suitable) combination thereof.

The alkali metal-containing compound, the alkaline earth metal-containing compound, and the rare earth metal-containing compound may include oxides, halides (for example, fluorides, chlorides, bromides, iodides, and/or the like), or tellurides of the alkali metal, the alkaline earth metal, and the rare earth metal, or a (e.g., any suitable) combination thereof.

The alkali metal-containing compound may include: alkali metal oxides, such as Li₂O, Cs₂O, and/or K₂O; alkali metal halides, such as LiF, NaF, CsF, KF, LiI, NaI, CsI, and/or KI; or a (e.g., any suitable) combination thereof. The alkaline earth metal-containing compound may include an alkaline earth metal compound, such as BaO, SrO, CaO, BaₓSr₁₋ₓO (x is a real number satisfying 0<x<1), and/or BaₓCa₁₋ₓO (x is a real number satisfying 0<x<1). The rare earth metal-containing compound may include YbF₃, ScF₃, SC₂O₃, Y₂O₃, Ce₂O₃, GdF₃, TbF₃, YbI₃, ScI₃, TbI₃, or a (e.g., any suitable) combination thereof. In one or more embodiments, the rare earth metal-containing compound may include lanthanide metal telluride. Examples of the lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, and/or Lu₂Te₃.

The alkali metal complex, the alkaline earth-metal complex, and the rare earth metal complex may include i) one selected from among ions of the alkali metal, the alkaline earth metal, and the rare earth metal and ii) a ligand bonded to the metal ion, for example, hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenyl benzimidazole, hydroxyphenylbenzothiazole, bipyridine, phenanthroline, cyclopentadiene, or a (e.g., any suitable) combination thereof.

The electron injection layer may include (e.g., consist of) an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or a (e.g., any suitable) combination thereof, as described in one or more embodiments. In one or more embodiments, the electron injection layer may further include an organic material (for example, a compound represented by Formula 601).

In one or more embodiments, the electron injection layer may include (e.g., consist of) i) an alkali metal-containing compound (for example, alkali metal halide), ii) a) an alkali metal-containing compound (for example, alkali metal halide); and b) an alkali metal, an alkaline earth metal, a rare earth metal, or a (e.g., any suitable) combination thereof. For example, the electron injection layer may be a KI:Yb co-deposited layer, an RbI:Yb co-deposited layer, a LiF: Yb co-deposited layer, and/or the like.

If (e.g., when) the electron injection layer further includes the organic material, the alkali metal, the alkaline earth metal, the rare earth metal, the alkali metal-containing compound, the alkaline earth metal-containing compound, the rare earth metal-containing compound, the alkali metal complex, the alkaline earth-metal complex, the rare earth metal complex, or a (e.g., any suitable) combination thereof may be uniformly (e.g., substantially uniformly) or non-uniformly dispersed in a matrix including the organic material.

The thickness of the electron injection layer may be about 1 Å to about 100 Å, and, for example, about 3 Å to about 90 Å. If (e.g., when) the thickness of the electron injection layer is within the foregoing ranges, satisfactory or suitable electron injection characteristics may be obtained without a substantial increase in driving voltage.

### Second Electrode 150

The second electrode 150 may be arranged on the interlayer 130. The second electrode 150 may be a cathode, which is an electron injection electrode, and as a material to form or arrange the second electrode 150, a metal, an alloy, an electrically conductive compound, or a (e.g., any suitable) combination thereof, each having a low-work function, may be utilized.

The second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or a (e.g., any suitable) combination thereof. The second electrode 150 may be a transmissive electrode, a transflective electrode, or a reflective electrode.

The second electrode 150 may have a single-layer structure or a multilayer structure including a plurality of layers.

### Capping Layer

A first capping layer may be arranged outside the first electrode 110, and/or a second capping layer may be arranged outside the second electrode 150. For example, the light-emitting device 10 may have a structure in which the first capping layer, the first electrode 110, the interlayer 130, and the second electrode 150 are sequentially stacked in the stated order, a structure in which the first electrode 110, the interlayer 130, the second electrode 150, and the second capping layer are sequentially stacked in the stated order, or a structure in which the first capping layer, the first electrode 110, the interlayer 130, the second electrode 150, and the second capping layer are sequentially stacked in the stated order.

Light generated in the emission layer of the interlayer 130 of the light-emitting device 10 may be extracted toward the outside through the first electrode 110 which is a transflective electrode or a transmissive electrode, and the first capping layer. Light generated in the emission layer of the interlayer 130 of the light-emitting device 10 may be extracted toward the outside through the second electrode 150 which is a transflective electrode or a transmissive electrode, and the second capping layer.

The first capping layer and the second capping layer may be to increase or enhance external quantum efficiency according to the principle of constructive interference. Accordingly, the light extraction efficiency of the light-emitting device 10 may be increased or enhanced, such that the luminescence efficiency of the light-emitting device 10 may be increased or enhanced.

Each of the first capping layer and the second capping layer may include a material having a refractive index of 1.6 or more (at 589 nm).

The first capping layer and the second capping layer may each independently be an organic capping layer including an organic material, an inorganic capping layer including an inorganic material, or an organic-inorganic composite capping layer including an organic material and an inorganic material.

At least one of the first capping layer and the second capping layer may each independently include a carbocyclic compound, a heterocyclic compound, an amine group-containing compound, a porphine derivative, a phthalocyanine derivative, a naphthalocyanine derivative, an alkali metal complex, an alkaline earth metal complex, or a (e.g., any suitable) combination thereof. The carbocyclic compound, the heterocyclic compound, and the amine group-containing compound may optionally be substituted with a substituent including O, N, S, Se, Si, F, Cl, Br, I, or a (e.g., any suitable) combination thereof. In one or more embodiments, at least one of the first capping layer and the second capping layer may each independently include an amine group-containing compound.

In one or more embodiments, at least one of the first capping layer and the second capping layer may each independently include a compound represented by Formula 201, a compound represented by Formula 202, or a (e.g., any suitable) combination thereof.

In one or more embodiments, at least one of the first capping layer and the second capping layer may each independently include one of (e.g., at least one selected from among) Compounds HT28 to HT33, one of (e.g., at least one selected from among) Compounds CP1 to CP6, β-NPB, or a (e.g., any suitable) combination thereof:

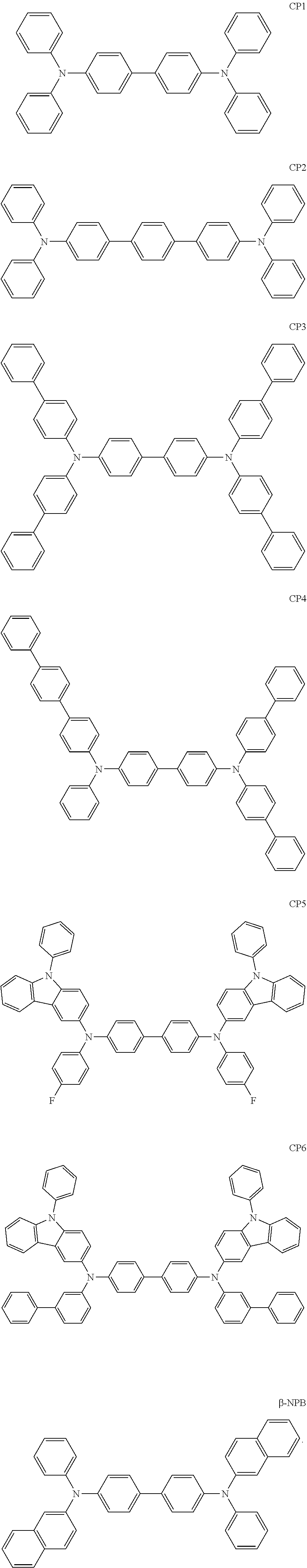

### Electronic Apparatus

According to one or more embodiments, an electronic apparatus may include a thin film manufactured from the quantum dot composition.

The thin film manufactured from the quantum dot composition may include the quantum dots, ZnS, which is a degradation product of the Zn complex compound, and thiourea.

The thin film may be included in one or more suitable electronic apparatuses. For example, the electronic apparatus including the thin film may be a light-emitting apparatus, an authentication apparatus, and/or the like.

The electronic apparatus (for example, a light-emitting apparatus or a display apparatus) may further include, in addition to the light-emitting device, i) a color filter, ii) a color conversion layer, or iii) a color filter and a color conversion layer. The color filter and/or the color conversion layer may be arranged in at least one traveling direction of light emitted from the light-emitting device. For example, the light emitted from the light-emitting device may be blue light or white light. In one or more embodiments, the electronic apparatus may include the light-emitting device including the quantum dot emission layer as described in one or more embodiments. In one or more embodiments, the electronic apparatus may include a color conversion layer including the thin film manufactured from quantum dot composition.

The electronic apparatus may include a first substrate. The first substrate may include a plurality of subpixel areas, the color filter may include a plurality of color filter areas respectively corresponding to the subpixel areas, and the color conversion layer may include a plurality of color conversion areas respectively corresponding to the subpixel areas.

A pixel-defining film may be arranged among the subpixel areas to define each of the subpixel areas.

The color filter may further include a plurality of color filter areas and light-shielding patterns arranged among the color filter areas, and the color conversion layer may further include a plurality of color conversion areas and light-shielding patterns arranged among the color conversion areas.

The plurality of color filter areas (or the plurality of color conversion areas) may include a first area emitting first color light, a second area emitting second color light, and/or a third area emitting third color light, wherein the first color light, the second color light, and/or the third color light may have different maximum emission wavelengths. In one or more embodiments, the first color light may be red light, the second color light may be green light, and the third color light may be blue light. In one or more embodiments, the plurality of color filter areas (or the plurality of color conversion areas) may include quantum dots. In more detail, the first area may include red quantum dots, the second area may include green quantum dots, and the third area may not include (e.g., may exclude any) quantum dots. A detailed description of the quantum dots is provided herein. The first area, the second area, and/or the third area may each further include a scatterer (e.g., a light scatterer).

In one or more embodiments, the light-emitting device may be to emit first light, the first area may be to absorb the first light to emit first-1 color light, the second area may be to absorb the first light to emit second-1 color light, and the third area may be to absorb the first light to emit third-1 color light. In this case, the first-1 color light, the second-1 color light, and the third-1 color light may have different maximum emission wavelengths. In more detail, the first light may be blue light, the first-1 color light may be red light, the second-1 color light may be green light, and the third-1 color light may be blue light.

The electronic apparatus may further include a thin-film transistor, in addition to the light-emitting device as described in one or more embodiments. The thin-film transistor may include a source electrode, a drain electrode, and an active layer, wherein any one selected from the source electrode and the drain electrode may be electrically connected to any one selected from the first electrode and the second electrode of the light-emitting device.

The thin-film transistor may further include a gate electrode, a gate insulating (e.g., electrically insulating) film, and/or the like.

The active layer may include crystalline silicon, amorphous (e.g., non-crystalline) silicon, an organic semiconductor, an oxide semiconductor, and/or the like.

The electronic apparatus may further include a sealing portion to seal the light-emitting device. The sealing portion may be arranged between the color filter and/or the color conversion layer and the light-emitting device. The sealing portion allows light from the light-emitting device to be extracted to the outside and concurrently (e.g., simultaneously) prevents ambient air and/or moisture from penetrating into the light-emitting device (or reduces a degree to or occurrence of which ambient air and/or moisture penetrate into the light-emitting device). The sealing portion may be a sealing substrate including a transparent (e.g., substantially transparent) glass substrate and/or a plastic substrate. The sealing portion may be a thin-film encapsulation layer including at least one layer of an organic layer and an inorganic layer. If (e.g., when) the sealing portion is a thin film encapsulation layer, the electronic apparatus may be flexible.

One or more suitable functional layers may be additionally arranged on the sealing portion, in addition to the color filter and/or the color conversion layer, according to the use of the electronic apparatus. Examples of the functional layers may include a touch screen layer and a polarizing layer. The touch screen layer may be a pressure-sensitive touch screen layer, a capacitive touch screen layer, or an infrared touch screen layer. The authentication apparatus may be, for example, a biometric authentication apparatus that authenticates an individual by using biometric information of a living body (for example, fingertips, pupils, and/or the like).

The authentication apparatus may further include, in addition to the light-emitting device as described in one or more embodiments, a biometric information collector.

The electronic apparatus may be applied to one or more suitable displays, light sources, lighting, personal computers (for example, a mobile personal computer), mobile phones, digital cameras, electronic organizers, electronic dictionaries, electronic game machines, medical instruments (for example, electronic thermometers, sphygmomanometers, blood glucose meters, pulse measurement devices, pulse wave measurement devices, electrocardiogram displays, ultrasonic diagnostic devices, or endoscope displays), fish finders, one or more suitable measuring instruments, meters (for example, meters for a vehicle, an aircraft, and a vessel), projectors, and/or the like.

### Description of FIG. 2

In one or more embodiments, an electronic apparatus may include: a light source; and a color conversion member arranged on a path of light emitted from the light source, and the color conversion member may include a thin film manufactured from the quantum dot composition.

FIG. 2 is a schematic view of a structure of an electronic apparatus according to one or more embodiments. The electronic apparatus of FIG. 2 may include a substrate 10, a light source 20 arranged on the substrate 10, and a color conversion member 30 arranged on the light source 20.

For example, the light source 20 may be a light-emitting device, an organic light-emitting device, a quantum dot light-emitting device (QLED), or a (e.g., any suitable) combination thereof. The color conversion member 30 may be arranged in at least one traveling direction of light emitted from the light source 20.

In the electronic apparatus, at least one area of the color conversion member 30 may include the thin film formed or manufactured from the quantum dot composition, and the area may be to absorb the light emitted from the light source and emit color-converted light.

That the color conversion member 30 may be arranged in at least one traveling direction of light emitted from the light source 20 and may not exclude other elements from being further included between the color conversion member 30 and the light source 20.

In one or more embodiments, the color conversion member 30 may further include a color filter.

The electronic apparatus as illustrated in FIG. 2 may have one or more suitable shapes that are generally available or generally used, and accordingly, may further include one or more suitable structures that are generally available or generally used. The color filter may include a pigment and/or a dye.

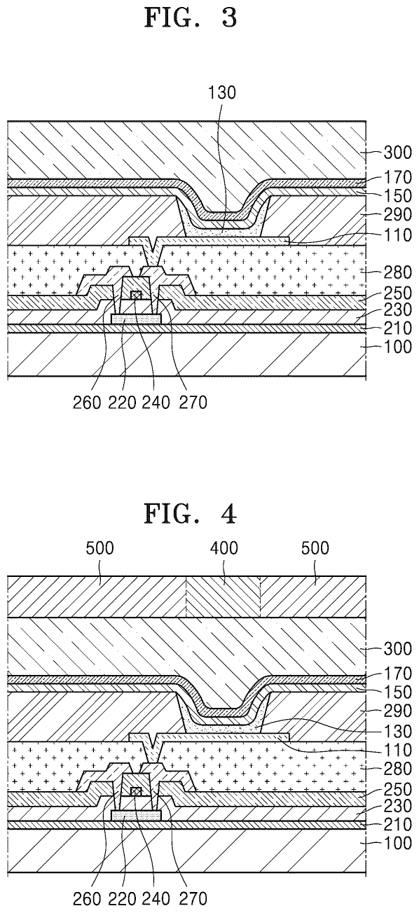

### Description of FIGS. 3 and 4

FIG. 3 is a cross-sectional view illustrating a light-emitting apparatus according to one or more embodiments.

The light-emitting apparatus of FIG. 3 includes a substrate 100, a thin-film transistor (TFT), a light-emitting device, and an encapsulation portion 300 that seals the light-emitting device.

The substrate 100 may be a flexible substrate, a glass substrate, and/or a metal substrate. A buffer layer 210 may be arranged on the substrate 100. The buffer layer 210 may be to prevent penetration of impurities (or reduce a degree or occurrence of penetration of impurities) through the substrate 100 and may be to provide a flat surface on the substrate 100.

A TFT may be arranged on the buffer layer 210. The TFT may include an active layer 220, a gate electrode 240, a source electrode 260, and a drain electrode 270.

The active layer 220 may include an inorganic semiconductor, such as silicon and/or polysilicon, an organic semiconductor, and/or an oxide semiconductor, and may include a source region, a drain region, and a channel region.

A gate insulating film 230 to insulate (e.g., to electrically insulate) the active layer 220 from the gate electrode 240 may be arranged on the active layer 220, and the gate electrode 240 may be arranged on the gate insulating film 230.

An interlayer insulating film 250 may be arranged on the gate electrode 240. The interlayer insulating film 250 may be arranged between the gate electrode 240 and the source electrode 260 and between the gate electrode 240 and the drain electrode 270, to insulate (e.g., to electrically insulate) these electrodes from one another.

The source electrode 260 and the drain electrode 270 may be arranged on the interlayer insulating film 250. The interlayer insulating film 250 and the gate insulating film 230 may be formed or arranged to expose the source region and the drain region of the active layer 220, and the source electrode 260 and the drain electrode 270 may be arranged in contact with the exposed portions of the source region and the drain region of the active layer 220.

The TFT may be electrically connected to a light-emitting device to drive the light-emitting device and may be covered and protected by a passivation layer 280. The passivation layer 280 may include an inorganic insulating (e.g., electrically insulating) film, an organic insulating (e.g., electrically insulating) film, or a (e.g., any suitable) combination thereof. A light-emitting device may be provided on the passivation layer 280. The light-emitting device may include the first electrode 110, the interlayer 130, and the second electrode 150.

The first electrode 110 may be arranged on the passivation layer 280. The passivation layer 280 may be arranged to expose a portion of the drain electrode 270, not fully covering the drain electrode 270, and the first electrode 110 may be arranged to be connected to the exposed portion of the drain electrode 270.

A pixel-defining film 290 including an insulating (e.g., electrically insulating) material may be arranged on the first electrode 110. The pixel-defining film 290 may expose a certain (e.g., set or predetermined) region of the first electrode 110, and the interlayer 130 may be formed or arranged in the exposed region of the first electrode 110. The pixel-defining film 290 may be a polyimide-based organic film and/or a polyacrylic organic film. In one or more embodiments, one or more layers of the interlayer 130 may extend beyond the upper portion of the pixel-defining film 290 to be arranged in the form of a common layer.

The second electrode 150 may be arranged on the interlayer 130, and a capping layer 170 may be additionally formed or arranged on the second electrode 150. The capping layer 170 may be formed or arranged to cover the second electrode 150.

The encapsulation portion 300 may be located or arranged on the capping layer 170. The encapsulation portion 300 may be arranged on a light-emitting device to protect the light-emitting device from moisture and/or oxygen. The encapsulation portion 300 may include: an inorganic film including silicon nitride (e.g., SiNₓ, wherein 0<x≤2; e.g., Si₃N₄), silicon oxide (e.g., SiOₓ, wherein 0<x≤2; e.g., SiO₂), indium tin oxide, indium zinc oxide, or a (e.g., any suitable) combination thereof; an organic film including polyethylene terephthalate, polyethylene naphthalate, polycarbonate, polyimide, polyethylene sulfonate, polyoxymethylene, polyarylate, hexamethyldisiloxane, an acrylic-based resin (for example, polymethyl methacrylate, polyacrylic acid, and/or the like), an epoxy-based resin (for example, aliphatic glycidyl ether (AGE) and/or the like), or a (e.g., any suitable) combination thereof; or a combination of the inorganic film and the organic film.

FIG. 4 is a cross-sectional view of a light-emitting apparatus according to one or more embodiments.

The light-emitting apparatus of FIG. 4 is substantially the same as the light-emitting apparatus of FIG. 3, except that a light-shielding pattern 500 and a functional region 400 are additionally arranged on the encapsulation portion 300. The functional region 400 may be i) a color filter area, ii) a color conversion area, or iii) a combination of the color filter area and the color conversion area. In one or more embodiments, a light-emitting device included in the light-emitting apparatus of FIG. 4 may be a tandem light-emitting device.

### Electronic Equipment

The quantum dots and the light-emitting device and electronic apparatus including the quantum dots may be included in one or more suitable electronic equipment.

In one or more embodiments, the electronic equipment including the light-emitting device may be one selected from among a flat panel display, a curved display, a computer monitor, a medical monitor, a television, a billboard, an indoor light, an outdoor light, a signal light, a head-up display, a fully transparent display, a partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a micro display, a 3D display, a virtual reality display, an augmented reality display, a vehicle, a video wall including two or more suitable displays tiled together, a theater screen, a stadium screen, a phototherapy device, and a signboard.

Because the light-emitting device has excellent or suitable effects in terms of luminescence efficiency and long lifespan, the electronic equipment including the light-emitting device may have characteristics with high luminance, high resolution, and low power consumption.

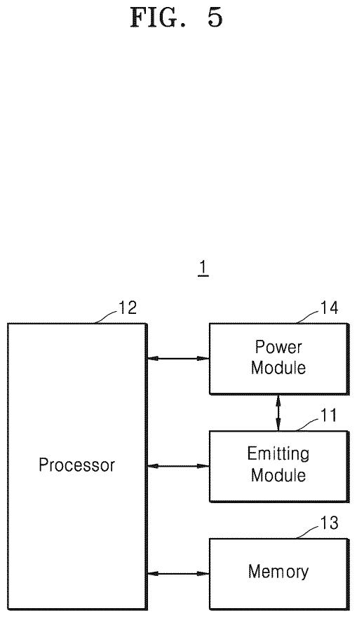

### Description of FIG. 5

FIG. 5 is a block diagram of electronic equipment 1 according to one or more embodiments. Referring to FIG. 5, the electronic equipment 1 according to one or more embodiments may include an emitting module 11, a processor 12, a memory 13, and a power module 14.

The processor 12 may include at least one selected from among a central processing unit (CPU), an application processor (AP), a graphic processing unit (GPU), a communication processor (CP), an image signal processor (ISP), and a controller.

The memory 13 may be to store data information desired or required for operations of the processor 12 or the emitting module 11. If (e.g., when) the processor 12 executes an application stored in the memory 13, an image data signal and/or an input control signal may be transmitted to the emitting module 11, and the emitting module 11 may be to process the provided signal and output image information on a display.

The power module 14 may include a power supply module, such as a power adapter, a battery device, and/or the like, and a power conversion module configured to convert power supplied by the power supply module and generate power desired or required for operations of the electronic equipment 1.

At least one selected from among the components of the electronic equipment 1 may be included in the light-emitting apparatus as described in one or more embodiments. In one or more embodiments, one or more of individual modules included in a single module on a functional basis may be included in a light-emitting apparatus, and the other may be provided separately from the light-emitting apparatus. For example, the light-emitting apparatus may include the emitting module, and the processor 12, the memory 13, and the power module 14 may be provided as an apparatus other than the light-emitting apparatus in the electronic equipment 1.

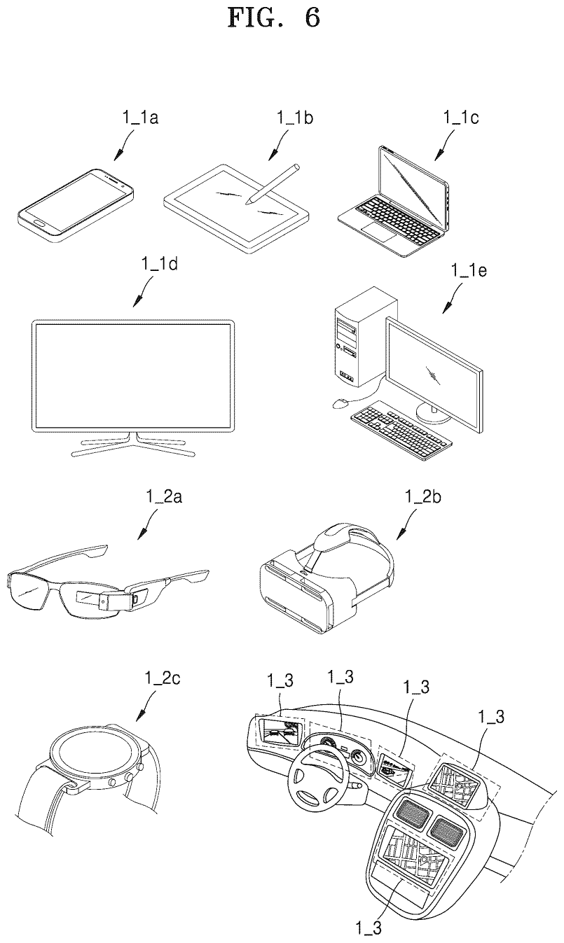

### Description of FIG. 6

FIG. 6 is a schematic view of an electronic equipment according to one or more embodiments.

Referring to FIG. 6, one or more suitable electronic equipment to which the electronic apparatus (for example, the light-emitting apparatus) is applied may include not only electronic equipment for image display, such as a smartphone 1_1a, a tablet personal computer (PC) 1_1b, a laptop 1_1c, a television (TV) 1_1d, a desk monitor 1_1e, and/or the like, but also wearable electronic equipment including an emitting module, such as smart glasses 1_2a, a head mount display 1_2b, a smart watch 1_2c, and/or the like, electronic equipment for vehicles 1_3 including an emitting module, such as a dashboard of a vehicle, a center fascia, a center information display (CID) arranged on a center fascia, a room mirror display, and/or the like.

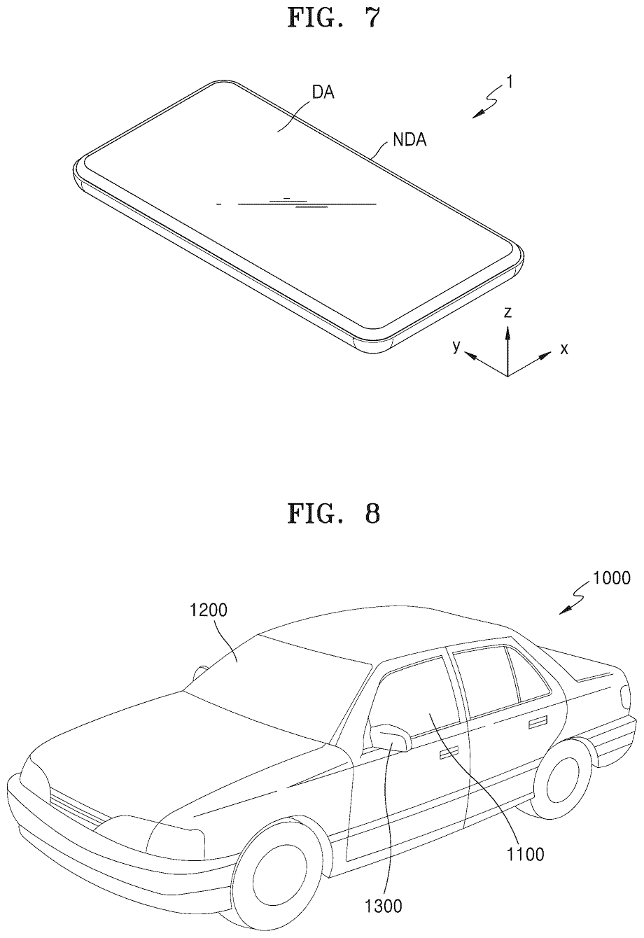

### Description of FIG. 7

FIG. 7 is a schematic perspective view of the electronic equipment 1 including the light-emitting device according to one or more embodiments. The electronic equipment 1 may be, as an apparatus that displays a moving image and/or a still image, portable electronic equipment, such as a mobile phone, a smartphone, a tablet personal computer (PC), a mobile communication terminal, an electronic notebook, an electronic book, a portable multimedia player (PMP), a navigation, or an ultra-mobile PC (UMPC), as well as one or more suitable products, such as a television, a laptop, a monitor, a billboard, or an Internet of Things (IoT) device. The electronic equipment 1 may be such a product as described in one or more embodiments or a part thereof. In one or more embodiments, the electronic equipment 1 may be a wearable device, such as a smart watch, a watch phone, a glasses-type (kind) display, or a head mounted display (HMD), or a part of the wearable device. However, embodiments of the present disclosure are not limited thereto. In one or more embodiments, the electronic equipment 1 may be a dashboard of a vehicle, a center information display (CID) arranged on a center fascia or dashboard of a vehicle, a room mirror display instead of a side-view mirror of a vehicle, an entertainment for the back seat of a vehicle, or a display arranged on the back of the front seat of a vehicle, a head up display (HUD) installed on the front of a vehicle or projected on a front window glass, or a computer generated hologram augmented reality head up display (CGH AR HUD). FIG. 7 illustrates an example in which the electronic equipment 1 is a smartphone for convenience of explanation.

The electronic equipment 1 may include a display area DA and a non-display area NDA outside the display area DA. A display apparatus may implement an image through an array of a plurality of pixels that are two-dimensionally arranged in the display area DA.

The non-display area NDA may be an area that does not display an image and may be entirely (e.g., substantially entirely) around (e.g., entirely (e.g., substantially entirely) surround) the display area DA. On the non-display area NDA, a driver to provide electrical signals or power to display devices arranged on the display area DA may be arranged. On the non-display area NDA, a pad, which is an area to which an electronic element or a printed circuit board, may be electrically connected may be arranged.

In the electronic equipment 1, the length in an x-axis direction and the length in a y-axis direction may be different from each other. In one or more embodiments, as illustrated in FIG. 7, the length in the x-axis direction may be shorter than the length in the y-axis direction. In one or more embodiments, the length in the x-axis direction may be substantially the same as the length in the y-axis direction. In one or more embodiments, the length in the x-axis direction may be greater than the length in the y-axis direction.

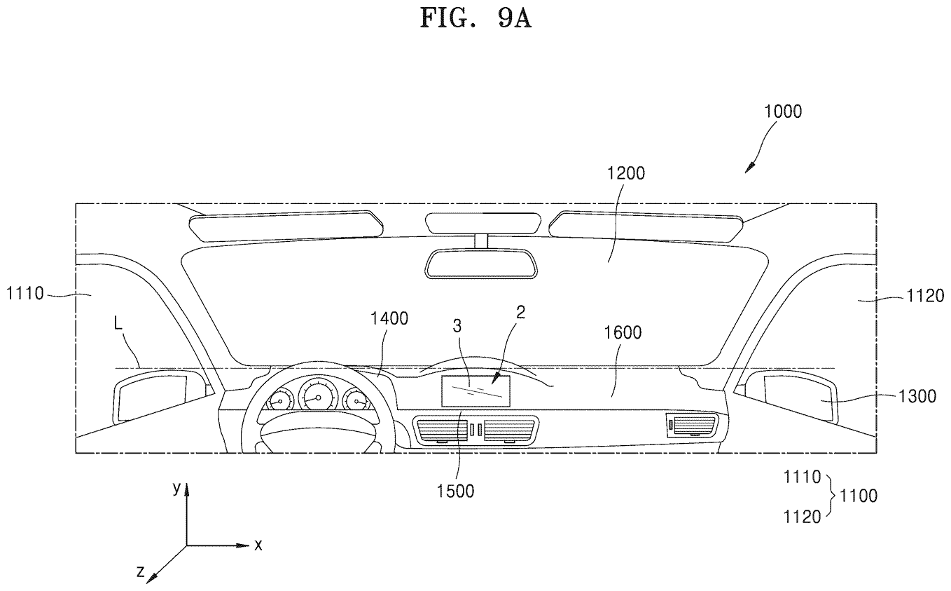

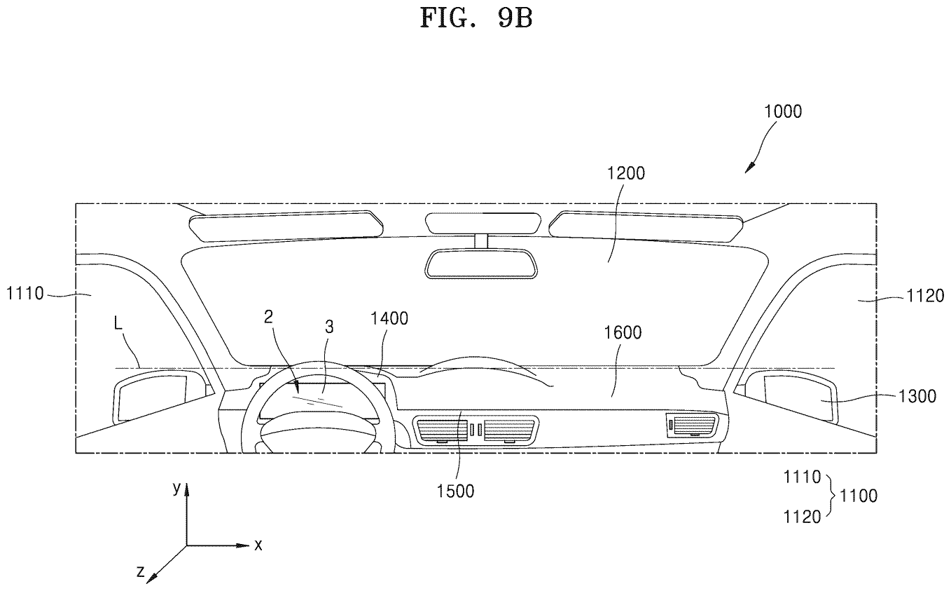

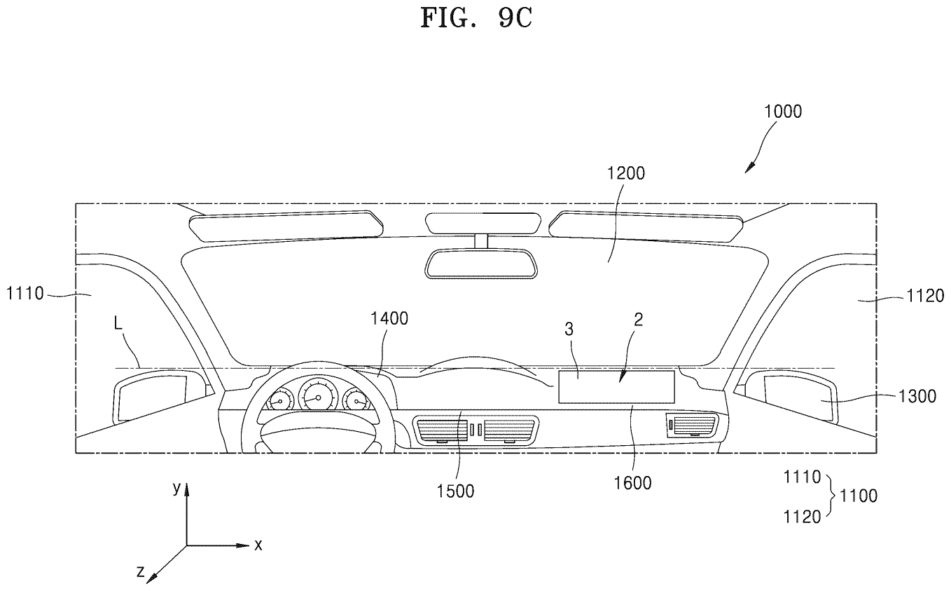

### Descriptions of FIGS. 8 and 9A to 9C

FIG. 8 is a diagram illustrating the exterior of a vehicle 1000 as electronic equipment including a light-emitting device according to one or more embodiments. FIGS. 9A to 9C are each a schematic view of the interior of the vehicle 1000 according to one or more embodiments.

Referring to FIGS. 8 and 9A to 9C, the vehicle 1000 may refer to one or more suitable apparatuses to move a subject to be transported, such as a human, an object, and/or an animal, from a departure point to a destination point. The vehicle 1000 may include a vehicle traveling on a road or track, a vessel moving over the sea or river, an airplane flying in the sky using the action of air, and/or the like.

The vehicle 1000 may be to travel on a road or a track. The vehicle 1000 may be to move in a certain (e.g., set or predetermined) direction according to rotation of at least one wheel. In one or more embodiments, the vehicle 1000 may include a three-wheeled vehicle, a four-wheeled vehicle, a construction machine, a two-wheeled vehicle, a prime mover device, a bicycle, and a train running on a track.

The vehicle 1000 may include a body having an interior and an exterior, and a chassis in which mechanical apparatuses necessary or desired for driving are installed as other parts except for the body of the vehicle 1000. The exterior of the body of the vehicle may include a front panel, a bonnet, a roof panel, a rear panel, a trunk, a pillar provided at a boundary between doors, and/or the like. The chassis of the vehicle 1000 may include a power generating device, a power transmitting device, a driving device, a steering device, a braking device, a suspension device, a transmission device, a fuel device, front and rear wheels, left and right wheels, and/or the like.

The vehicle 1000 may include a side window glass 1100, a front window glass 1200, a side-view mirror 1300, a cluster 1400, a center fascia 1500, a passenger seat dashboard 1600, and a display apparatus 2.

The side window glass 1100 and the front window glass 1200 may be partitioned by a pillar arranged between the side window glass 1100 and the front window glass 1200.

The side window glass 1100 may be installed on the side of the vehicle 1000. In one or more embodiments, the side window glass 1100 may be installed on a door of the vehicle 1000. A plurality of side window glasses 1100 may be provided and may be opposite to (e.g., face) each other. In one or more embodiments, the side window glass 1100 may include a first side window glass 1110 and a second side window glass 1120. In one or more embodiments, the first side window glass 1110 may be arranged adjacent to the cluster 1400. The second side window glass 1120 may be arranged adjacent to the passenger seat dashboard 1600.

In one or more embodiments, the side window glasses 1100 may be spaced and/or apart (e.g., spaced apart or separated) from each other in an x direction or a −x direction. In one or more embodiments, the first side window glass 1110 and the second side window glass 1120 may be spaced and/or apart (e.g., spaced apart or separated) from each other in the x direction or the −x direction. For example, an imaginary straight line L connecting the side window glasses 1100 may extend in the x direction or the −x direction. In one or more embodiments, an imaginary straight line L connecting the first side window glass 1110 and the second side window glass 1120 to each other may extend in the x direction or the −x direction.

The front window glass 1200 may be installed in front of the vehicle 1000. The front window glass 1200 may be arranged between the side window glasses 1100 opposite to (e.g., facing) each other.

The side-view mirror 1300 may be to provide a rear view of the vehicle 1000. The side-view mirror 1300 may be installed on the exterior of the body of the vehicle. In one or more embodiments, a plurality of side-view mirrors 1300 may be provided. Any one of the plurality of side-view mirrors 1300 may be arranged outside the first side window glass 1110. Another of the plurality of side-view mirrors 1300 may be arranged outside the second side window glass 1120.

The cluster 1400 may be arranged in front of a steering wheel. The cluster 1400 may include a tachometer, a speedometer, a coolant thermometer, a fuel gauge, a turn signal indicator, a high beam indicator, a warning light, a seat belt warning light, an odometer, a tachograph, an automatic shift selector indicator, a door open warning light, an engine oil warning light, and/or a low fuel warning light.

The center fascia 1500 may include a control panel on which a plurality of buttons to adjust an audio device, an air conditioning device, and a seat heater are arranged. The center fascia 1500 may be arranged on one side of the cluster 1400.

The passenger seat dashboard 1600 may be spaced and/or apart (e.g., spaced apart or separated) from the cluster 1400, and the center fascia 1500 may be arranged between the cluster 1400 and the passenger seat dashboard 1600. In one or more embodiments, the cluster 1400 may be arranged to correspond to a driver seat, and the passenger seat dashboard 1600 may be arranged to correspond to a passenger seat. In one or more embodiments, the cluster 1400 may be adjacent to the first side window glass 1110, and the passenger seat dashboard 1600 may be adjacent to the second side window glass 1120.

In one or more embodiments, the display apparatus 2 may include a display panel 3, and the display panel 3 may be to display an image. The display apparatus 2 may be arranged inside the vehicle 1000. In one or more embodiments, the display apparatus 2 may be arranged between the side window glasses 1100 opposite to (e.g., facing) each other. The display apparatus 2 may be arranged on at least one selected from among the cluster 1400, the center fascia 1500, and the passenger seat dashboard 1600.

The display apparatus 2 may include an organic light-emitting display, an inorganic electroluminescent display, a quantum dot display, and/or the like. Hereinafter, as the display apparatus 2 according to one or more embodiments, an organic light-emitting display apparatus including the light-emitting device will be described in more detail as an example, but one or more suitable types (kinds) of display apparatuses as described in one or more embodiments may be used in one or more embodiments.

Referring to FIG. 9A, the display apparatus 2 may be arranged on the center fascia 1500. In one or more embodiments, the display apparatus 2 may be to display navigation information. In one or more embodiments, the display apparatus 2 may be to display information regarding audio settings, video setting, and/or vehicle settings.

Referring to FIG. 9B, the display apparatus 2 may be arranged on the cluster 1400. In this case, the cluster 1400 may be to display driving information and/or the like through the display apparatus 2. For example, the cluster 1400 may be implemented digitally. The digital cluster 1400 may be to display vehicle information and driving information. In one or more embodiments, a needle and a gauge of a tachometer and one or more suitable warning light icons may be displayed by a digital signal.

Referring to FIG. 9C, the display apparatus 2 may be arranged on the passenger seat dashboard 1600. The display apparatus 2 may be embedded in the passenger seat dashboard 1600 or arranged on the passenger seat dashboard 1600. In one or more embodiments, the display apparatus 2 arranged on the passenger seat dashboard 1600 may be to display an image related to information displayed on the cluster 1400 and/or information displayed on the center fascia 1500. In one or more embodiments, the display apparatus 2 arranged on the passenger seat dashboard 1600 may be to display information different from information displayed on the cluster 1400 and/or information displayed on the center fascia 1500.

### Manufacturing Method

Layers constituting the hole transport region, the emission layer, and the layers constituting the electron transport region may be formed or arranged in a certain (e.g., set or predetermined) region by utilizing one or more suitable methods, such as vacuum deposition, spin coating, casting, Langmuir-Blodgett (LB) deposition, ink-jet printing, laser-printing, laser-induced thermal imaging, and/or the like. For example, the emission layer may be formed or arranged by ink-jet printing.

If (e.g., when) the layers constituting the hole transport region, the emission layer, and the layers constituting the electron transport region are formed or arranged by vacuum deposition, the deposition may be performed at a deposition temperature in a range of about 100° C. to about 500° C., at a vacuum degree in a range of about 10⁻⁸ torr to about 10⁻³ torr, and at a deposition speed in a range of about 0.01 Å/sec to about 100 Å/sec, depending on a material to be included in a layer to be formed or arranged and the structure of a layer to be formed or arranged.

### Definition of Terms

The term “C₃-C₆₀ carbocyclic group” as used herein refers to a cyclic group consisting of carbon atoms as the only ring-forming atoms and having three to sixty carbon atoms, and the term “C₁-C₆₀ heterocyclic group” as used herein refers to a cyclic group that has one to sixty carbon atoms and further includes, in addition to a carbon atom, a heteroatom as a ring-forming atom. The C₃-C₆₀ carbocyclic group and the C₁-C₆₀ heterocyclic group may each be a monocyclic group consisting of one ring or a polycyclic group in which two or more rings are condensed with each other. In one or more embodiments, the number of ring-forming atoms of the C₁-C₆₀ heterocyclic group may be 3 to 61.

The “cyclic group” as used herein may include both (e.g., simultaneously) the C₃-C₆₀ carbocyclic group and the C₁-C₆₀ heterocyclic group.

The term “π electron-rich C₃-C₆₀ cyclic group” as used herein refers to a cyclic group that has 3 to 60 carbon atoms and does not include *—N═*′ as a ring-forming moiety, and the term “π electron-deficient nitrogen-containing C₁-C₆₀ heterocyclic group” as used herein refers to a heterocyclic group that has 1 to 60 carbon atoms and includes *—N═*′ as a ring-forming moiety.

In one or more embodiments, the C₃-C₆₀ carbocyclic group may be i) Group T1 or ii) a condensed cyclic group in which two or more of Group T1 are condensed with each other (for example, a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),
the C₁-C₆₀ heterocyclic group may be i) Group T2, ii) a condensed cyclic group in which two or more of Group T2 are condensed with each other, or iii) a condensed cyclic group in which at least one Group T2 and at least one Group T1 are condensed with each other (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and/or the like),
the π electron-rich C₃-C₆₀ cyclic group may be i) Group T1, ii) a condensed cyclic group in which two or more Groups T1 are condensed with each other, iii) Group T3, iv) a condensed cyclic group in which two or more Groups T3 are condensed with each other, or v) a condensed cyclic group in which at least one Group T3 and at least one Group T1 are condensed with each other (for example, the C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, and/or the like),
the π electron-deficient nitrogen-containing C₁-C₆₀ heterocyclic group may be i) Group T4, ii) a condensed cyclic group in which at least two Groups T4 are condensed with each other, iii) a condensed cyclic group in which at least one Group T4 and at least one Group T1 are condensed with each other, iv) a condensed cyclic group in which at least one Group T4 and at least one Group T3 are condensed with each other, or v) a condensed cyclic group in which at least one Group T4, at least one Group T1, and at least one Group T3 are condensed with one another (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and/or the like),
Group T1 may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or bicyclo[2.2.1]heptane) group, a norbornene group, a bicyclo[1.1.1]pentane group, a bicyclo[2.1.1]hexane group, a bicyclo[2.2.2]octane group, or a benzene group,
Group T2 may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,
Group T3 may be a furan group, a thiophene group, a 1H-pyrrole group, a silole group, or a borole group, and

Group T4 may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “the cyclic group”, “the C₃-C₆₀ carbocyclic group”, “the C₁-C₆₀ heterocyclic group”, “the π electron-rich C₃-C₆₀ cyclic group”, and “the π electron-deficient nitrogen-containing C₁-C₆₀ heterocyclic group” as used herein each refer to a group condensed to any cyclic group, a monovalent group, or a polyvalent group (for example, a divalent group, a trivalent group, a tetravalent group, and/or the like) according to the structure of a formula for which the corresponding term is used. In one or more embodiments, “a benzene group” may be a benzo group, a phenyl group, a phenylene group, and/or the like, which may be generally understand by one of ordinary skill in the art according to the structure of a formula including the “benzene group.”

Examples of the monovalent C₃-C₆₀ carbocyclic group and the monovalent C₁-C₆₀ heterocyclic group may include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group. Examples of the divalent C₃-C₆₀ carbocyclic group and the divalent C₁-C₆₀ heterocyclic group may include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a divalent non-aromatic condensed heteropolycyclic group.

The term “C₁-C₆₀ alkyl group” as used herein refers to a linear or branched aliphatic hydrocarbon monovalent group that has one to sixty carbon atoms, and examples thereof may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, and a tert-decyl group. The term “C₁-C₆₀ alkylene group” as used herein refers to a divalent group having the same structure as the C₁-C₆₀ alkyl group.

The term “C₂-C₆₀ alkenyl group” as used herein refers to a monovalent hydrocarbon group having at least one carbon-carbon double bond in the middle or at the terminus of the C₂-C₆₀ alkyl group, and examples thereof may include an ethenyl group, a propenyl group, and a butenyl group. The term “C₂-C₆₀ alkenylene group” as used herein refers to a divalent group having the same structure as the C₂-C₆₀ alkenyl group.

The term “C₂-C₆₀ alkynyl group” as used herein refers to a monovalent hydrocarbon group having at least one carbon-carbon triple bond in the middle or at the terminus of the C₂-C₆₀ alkyl group, and examples thereof may include an ethynyl group, a propynyl group, and/or the like. The term “C₂-C₆₀ alkynylene group” as used herein refers to a divalent group having the same structure as the C₂-C₆₀ alkynyl group.

The term “C₁-C₆₀ alkoxy group” as used herein refers to a monovalent group represented by —OA₁₀₁ (wherein A₁₀₁ is the C₁-C₆₀ alkyl group), and examples thereof may include a methoxy group, an ethoxy group, and an isopropyloxy group.

The term “C₃-C₁₀ cycloalkyl group” as used herein refers to a monovalent saturated hydrocarbon cyclic group having 3 to 10 carbon atoms, and examples thereof may include a cyclopropyl group, a cyclobutyl group, a cyclopentyl group, a cyclohexyl group, a cycloheptyl group, a cyclooctyl group, an adamantanyl group, a norbornanyl group (or bicyclo[2.2.1]heptyl group), a bicyclo[1.1.1]pentyl group, a bicyclo[2.1.1]hexyl group, a bicyclo[2.2.2]octyl group, and/or the like. The term “C₃-C₁₀ cycloalkylene group” as used herein refers to a divalent group having the same structure as the C₃-C₁₀ cycloalkyl group.

The term “C₁-C₁₀ heterocycloalkyl group” as used herein refers to a monovalent cyclic group that has one to ten carbon atoms and further includes, in addition to the carbon atoms, at least one heteroatom as a ring-forming atom, and examples thereof may include a 1,2,3,4-oxatriazolidinyl group, a tetrahydrofuranyl group, and a tetrahydrothiophenyl group. The term “C₁-C₁₀ heterocycloalkylene group” as used herein refers to a divalent group having the same structure as the C₁-C₁₀ heterocycloalkyl group.

The term “C₃-C₁₀ cycloalkenyl group” as used herein refers to a monovalent cyclic group that has three to ten carbon atoms and at least one carbon-carbon double bond in the ring thereof and no aromaticity, and examples thereof may include a cyclopentenyl group, a cyclohexenyl group, and a cycloheptenyl group. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent cyclic group that has one to ten carbon atoms, further includes, in addition to the carbon atoms, at least one heteroatom as a ring-forming atom, and has at least one double bond in the ring thereof. Examples of the C₁-C₁₀ heterocycloalkenyl group may include a 4,5-dihydro-1,2,3,4-oxatriazolyl group, a 2,3-dihydrofuranyl group, and a 2,3-dihydrothiophenyl group. The term “C₁-C₁₀ heterocycloalkenylene group” as used herein refers to a divalent group having the same structure as the C₁-C₁₀ heterocycloalkenyl group.

The term “C₆-C₆₀ aryl group” as used herein refers to a monovalent group having a carbocyclic aromatic system of six to sixty carbon atoms, and the term “C₆-C₆₀ arylene group” as used herein refers to a divalent group having a carbocyclic aromatic system of six to sixty carbon atoms. Examples of the C₆-C₆₀ aryl group may include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, and an ovalenyl group. If (e.g., when) the C₆-C₆₀ aryl group and the C₆-C₆₀ arylene group each include two or more rings, the two or more rings may be condensed with each other.

The term “C₁-C₆₀ heteroaryl group” as used herein refers to a monovalent group having a heterocyclic aromatic system that has one to sixty carbon atoms and further includes, in addition to the carbon atoms, at least one heteroatom as a ring-forming atom. The term “C₁-C₆₀ heteroarylene group” as used herein refers to a divalent group having a heterocyclic aromatic system that has one to sixty carbon atoms and further includes, in addition to the carbon atoms, at least one heteroatom as a ring-forming atom. Examples of the C₁-C₆₀ heteroaryl group may include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, and a naphthyridinyl group. If (e.g., when) the C₁-C₆₀ heteroaryl group and the C₁-C₆₀ heteroarylene group each include two or more rings, the two or more rings may be condensed with each other.

The term “monovalent non-aromatic condensed polycyclic group” as used herein refers to a monovalent group having two or more rings condensed with each other, only carbon atoms (for example, eight to sixty carbon atoms) as ring-forming atoms, and no aromaticity in its molecular structure if (e.g., when) considered as a whole. Examples of the monovalent non-aromatic condensed polycyclic group may include an indenyl group, a fluorenyl group, a spiro-bifluorenyl group, a benzofluorenyl group, an indenophenanthrenyl group, and an indeno anthracenyl group. The term “divalent non-aromatic condensed polycyclic group” as used herein refers to a divalent group having the same structure as the monovalent non-aromatic condensed polycyclic group.

The term “monovalent non-aromatic condensed heteropolycyclic group” as used herein refers to a monovalent group that has two or more rings condensed with each other, further includes, in addition to carbon atoms (for example, one to sixty carbon atoms), at least one heteroatom as a ring-forming atom, and has no aromaticity in its molecular structure if (e.g., when) considered as a whole. Examples of the monovalent non-aromatic condensed heteropolycyclic group may include a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indeno carbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, and a benzothienodibenzothiophenyl group. The term “divalent non-aromatic condensed heteropolycyclic group” as used herein refers to a divalent group having the same structure as the monovalent non-aromatic condensed heteropolycyclic group.

The term “C₆-C₆₀ aryloxy group” as used herein refers to —OA₁₀₂ (wherein A₁₀₂ is the C₆-C₆₀ aryl group), and the term “C₆-C₆₀ arylthio group” as used herein refers to —SA₁₀₃ (wherein A₁₀₃ is the C₆-C₆₀ aryl group).

The term “C₇-C₆₀ arylalkyl group” as used herein refers to -A₁₀₄A₁₀₅ (wherein A₁₀₄ is a C₁-C₅₄ alkylene group, and A₁₀₅ is a C₆-C₅₉ aryl group), and the term “C₂-C₆₀ heteroarylalkyl group” as used herein refers to -A₁₀₆A₁₀₇ (wherein A₁₀₆ is a C₁-C₅₉ alkylene group, and A₁₀₇ is a C₁-C₅₉ heteroaryl group).

The term “R₁₀ₐ” as used herein refers to:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a (e.g., any suitable) combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a (e.g., any suitable) combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).
Q₁ to Q₃, Q₁₁ to Q₁₃, Q₂₁ to Q₂₃, and Q₃₁ to Q₃₃ as used herein may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or a (e.g., any suitable) combination thereof; a C₇-C₆₀ arylalkyl group; or a C₂-C₆₀ heteroarylalkyl group.

The term “heteroatom” as used herein refers to an atom other than a carbon atom or a hydrogen atom. Examples of the heteroatom may include O, S, N, P, Si, B, Ge, Se, or a (e.g., any suitable) combination thereof.

The term “third-row transition metal” used herein may include hafnium (Hf), tantalum (Ta), tungsten (W), rhenium (Re), osmium (Os), iridium (Ir), platinum (Pt), gold (Au), and/or the like.

The term “Ph” as used herein refers to a phenyl group, the term “Me” as used herein refers to a methyl group, the term “Et” as used herein refers to an ethyl group, the term “ter-Bu” or “But” as used herein refers to a tert-butyl group, and the term “OMe” as used herein refers to a methoxy group.

The term “biphenyl group” as used herein refers to “a phenyl group substituted with a phenyl group.” For example, the “biphenyl group” is a substituted phenyl group having a C₆-C₆₀ aryl group as a substituent.

The term “terphenyl group” as used herein refers to “a phenyl group substituted with a biphenyl group”. For example, the “terphenyl group” is a substituted phenyl group having, as a substituent, a C₆-C₆₀ aryl group substituted with a C₆-C₆₀ aryl group.

* and *′ as used herein, unless defined otherwise, each refer to a binding site to a neighboring atom in a corresponding formula or moiety.

Hereinafter, the quantum dot composition and the light-emitting device formed therefrom according to one or more embodiments are further described in more detail.

Also, the quantum dots and a manufacturing method thereof according to one or more embodiments are described in more detail as well.

### EXAMPLES

### Test Example 1: Manufacture of ZnS Thin Film

A dispersion solution in which the Zn complex compound of Compound 1 was dispersed in an octane solvent at 5 wt % was spin-coated on a glass substrate and then baked at 140° C. for 10 minutes to form a ZnS thin film having a thickness of 40 nm.

### Absorption Spectrum of ZnS Thin Film

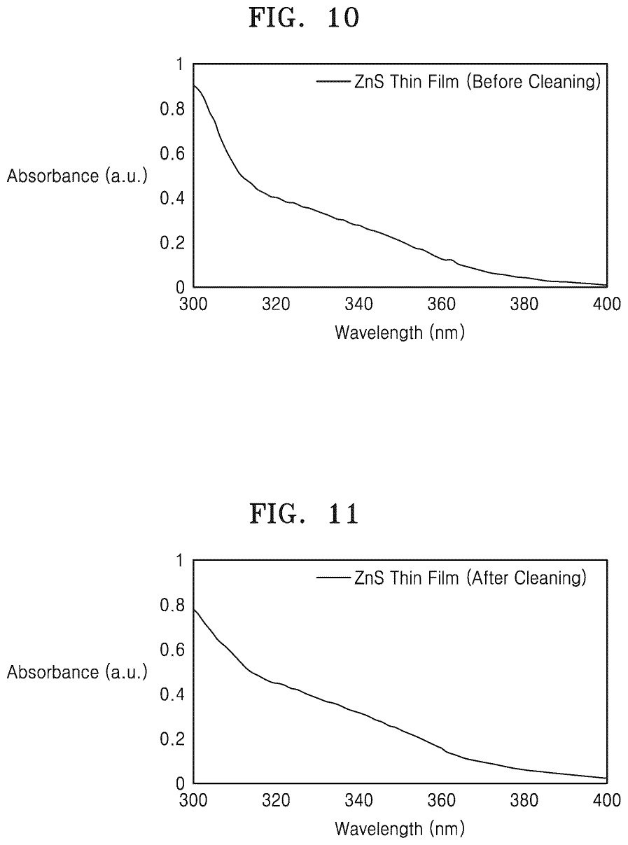

The UV-VIS absorption spectrum of the thin film was measured by using a spectrometer (Cary5000, Agilent), and the result thereof is shown in FIG. 10. Referring to FIG. 10, the absorption band was shown between 300 nm and 400 nm, and this may be due to absorption from ZnS. The absorption band from Compound 1 appears between 250 nm and 280 nm, which is distinguished from the absorption band of ZnS. Accordingly, the absorption band between 300 nm and 400 nm in FIG. 10 indicates that the thin film formed or manufactured from the dispersion solution of Compound 1 includes ZnS.

### Identification of Cross-Linkage of ZnS Thin Film

The ZnS thin film manufactured in Test Example 1 was cleaned by using an octane solvent for 60 seconds, and the UV-VIS absorption spectrum was remeasured by using a spectrometer (Cary5000, Agilent). The result thereof is shown in FIG. 11. Referring to FIG. 11, the ZnS absorption band identified in FIG. 10 is illustrated in FIG. 11 as well. This may be because a ligand of NH—(C₂H₄)—CH═CH₂ bonded to ZnS and generated from the Zn complex compound of Compound 1 was cross-linked to hold ZnS in the thin film, and ZnS was not washed away even after the cleaning using the solvent.

### Comparative Test Example 1

zinc diethyldithiocarbamate (Zn(DETC)₂) was mixed with oleylamine at a molar ratio of 1:2, and a dispersion solution obtained by dispersing the mixed solution in an octane solvent at 5 wt % was spin-coated on a glass substrate and then baked at 140° C. for 10 minutes to form a ZnS thin film having a thickness of 40 nm.

### Manufacture of ZnSeTe/ZnSe/ZnS Quantum Dot

Zinc acetate (2 mmol), oleic acid (OA, 2 mL), and 1-octadecene (ODE, 15 mL) were placed into a 3-neck flask and mixed, and the vacuum atmosphere was maintained at 120° C. for 30 minutes. Subsequently, after the atmosphere was switched to N₂ atmosphere, diphenylphosphine (Se-DPP) (1 mmol of Se in 0.5 mL of DPP) and trioctylphosphine (Te-TOP) (0.349 mmol of Te in 0.8 mL of TOP), which were prepared in advance, were sequentially injected at 220° C., the reaction was maintained for 30 minutes, and an additional reaction was performed for 1 hour at 300° C. to synthesize a ZnSeTe core. Afterwards, the temperature of the reaction solution was lowered to room temperatures, and an excess amount of ethanol was added thereto to purify the ZnSeTe core and to disperse the same in hexane.

Zinc acetate (3 mmol), OA (2 mL), and trioctylamine (TOA, 10 mL) were placed into a 3-neck flask and mixed, and the vacuum atmosphere was maintained at 120° C. for 30 minutes. Then, the atmosphere was switched to a N₂ atmosphere, and the ZnSeTe core dispersed in hexane was injected, and then HF was injected to remove an oxide film. The temperature of solution was raised to 240° C., and after 0.5 M Zn-oleate (4 mL) and 2 M Se-TOP (0.6 mL) were injected, the temperature was raised to 340° C., and the reaction was continued for 30 minutes to grow a ZnSe shell.

0.5 M Zn-oleate (3 ml) and 2 M S-TOP (1.2 mL) were injected into the manufactured ZnSeTe/ZnSe to grow a ZnS shell after reaction at 340° C. for 30 minutes. After the reaction, the solution was cooled to room temperature, and ethanol was injected thereinto for purification. Then, ZnSeTe/ZnSe/ZnS quantum dots were dispersed in hexane.

### Preparation of Quantum Dot Composition

### Test Example 2

The ZnSeTe/ZnSe/ZnS quantum dot and Zn complex compound of Compound 1 prepared as described herein were dispersed in an octane solvent to prepare a quantum dot composition. In the quantum dot composition, the amount of the ZnSeTe/ZnSe/ZnS quantum dot was 4 wt % based on the weight of the solvent, and the amount of the Zn complex compound of Compound 1 was 1 wt % based on the weight of the quantum dot.

### Test Examples 3 and 4

The quantum dot compositions were prepared in substantially the same manner as in Test Example 2, except that the compounds as shown in Table 1 were each used instead of the Zn complex compound of Compound 1.

### Comparative Test Example 2

The quantum dot composition was prepared in substantially the same manner as in Test Example 2, except that the Zn complex compound was not used.

TABLE 1

| Quantum dot | | Zn complex |
|---|---|---|
| composition | Quantum dot | compound |
| Test Example 2 | ZnSeTe/ZnSe/ZnS | Compound 1 |
| Test Example 3 | ZnSeTe/ZnSe/ZnS | Compound 2 |
| Test Example 4 | ZnSeTe/ZnSe/ZnS | Compound 3 |
| Comparative Test | ZnSeTe/ZnSe/ZnS | — |
| Example 2 | | |

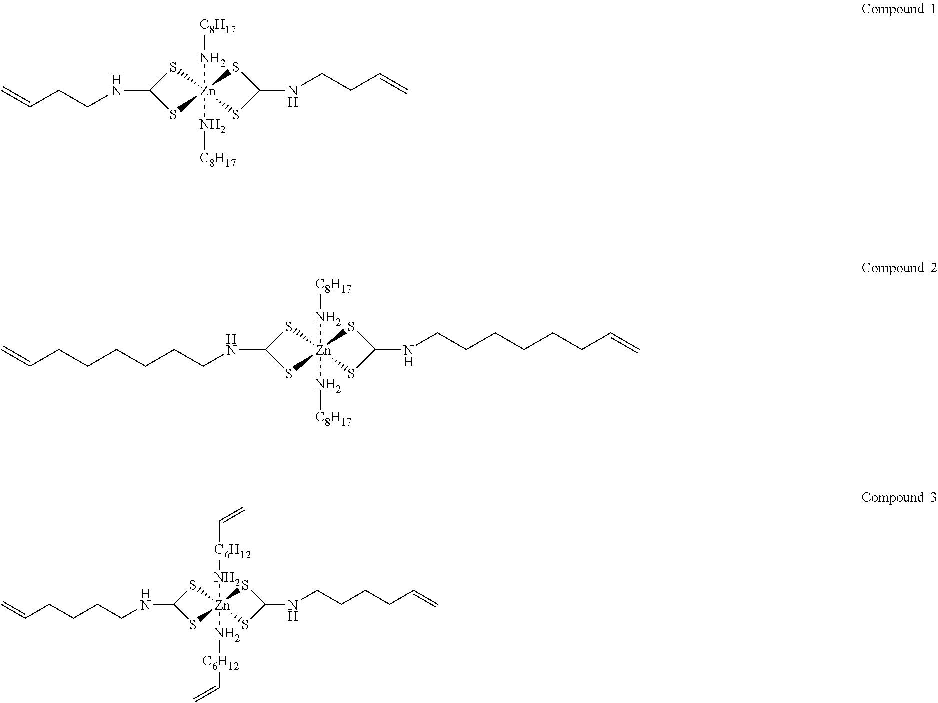

### Manufacture of Quantum Dot Thin Film

### Test Example 5

The quantum dot composition of Test Example 2 was spin-coated on a glass substrate and baked at 140° C. for 10 minutes to form a quantum dot thin film having a thickness of 40 nm.

### Comparative Test Example 3

The quantum dot composition of Comparative Test Example 2 was spin-coated on a glass substrate and baked at 140° C. for 10 minutes to form a quantum dot thin film having a thickness of 40 nm.

### Examination of Cohesion of Quantum Dot Surface

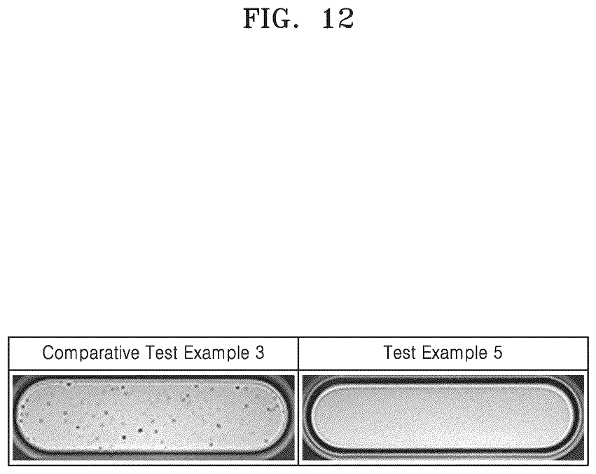

Photomicrographs of an upper surface of each of the quantum dot thin film of Test Example 5 and Comparative Test Example 3 were obtained (pixel size of 25×84 micrometers) and provided in FIG. 12. Referring to FIG. 12, the quantum dot thin film of Comparative Test Example 3 looked rough, whereas the quantum dot thin film of Test Example 5 looked smooth. This may be because the quantum dot thin film of Comparative Test Example 3 was formed in a non-uniform manner due to aggregation of the quantum dots, whereas the quantum dot thin film of Test Example 5 was formed in a substantially uniform manner without aggregation of the quantum dots.

### Manufacture of Light-Emitting Device

### Examples 1 to 3 and Comparative Example 1

As an anode, an ITO-deposited substrate was cut to a size of 50 mm×50 mm×0.5 mm, sonicated with isopropyl alcohol and pure water, each for 5 minutes, and then cleaned by irradiation with UV and exposure to ozone for 30 minutes.

PEDOT/PSS was spin-coated on the ITO substrate to form a hole injection layer having a thickness of 600 Å, and then, TFB was spin-coated on the hole injection layer to form a hole transport layer having a thickness of 400 Å.

The quantum dot composition as shown in Table 2 was spin-coated on the hole transport layer and then baked at 140° C. for 10 minutes to form a blue emission layer having a thickness of 300 Å. ZnMgO was spin-coated on the emission layer to form an electron transport layer having a thickness of 280 Å. Al was deposited on the electron transport layer to form a cathode having a thickness of a 1,000 Å, thereby completing the manufacture of a light-emitting device.

### Evaluation of Light-Emitting Device

The current efficiency and lifespan of the light-emitting devices of Examples 1 to 3 and Comparative Example 1 were measured at 10 mA/cm² by using Keithley MU 236 and PR650 (luminance meter), and the results thereof are shown in Table 2. The lifespan (T₉₀) of the light-emitting devices is time taken for the initial luminance of 1,000 nit to decline to 90%.

TABLE 2

| | | | Current | Lifespan |
|---|---|---|---|---|
| | Quantum dot | Zn complex | efficiency | (T90) |
| | composition | compound | (cd/A) | (hour) |
| Example 1 | Test Example 2 | Compound 1 | 12.1 | 180 |
| Example 2 | Test Example 3 | Compound 2 | 11.8 | 170 |
| Example 3 | Test Example 4 | Compound 3 | 12.0 | 180 |
| Comparative | Comparative Test | — | 10.5 | 100 |
| Example 1 | Example 2 | | | |

From Table 2, it is found that the current efficiency and lifespan of the light-emitting devices of Examples 1 to 3 in which the quantum dot emission layer was formed or manufactured from the quantum dot composition to which the Zn complex compound of Compounds 1 to 3 is added were higher than those of the light-emitting device of Comparative Example 1 in which the Zn complex compound was not used.

As the quantum dot composition according to the present disclosure includes a Zn complex compound, and thus a ZnS matrix is formed between quantum dots if (e.g., when) a quantum dot thin film is formed, the quantum dot thin film may have improved or reduced leakage current characteristics and morphology. The efficiency and lifespan of a light-emitting device including the quantum dot thin film may be improved or enhanced. For example, the ZnS matrix is formed in situ between the quantum dots during the formation of the quantum dot thin film. This ZnS matrix acts as a passivation layer and a physical barrier, reducing non-radiative recombination and suppressing charge leakage pathways. As a result, the quantum dot thin film exhibits improved or enhanced morphological uniformity and reduced leakage current characteristics. These enhancements contribute directly to the improved or enhanced current efficiency and operational lifespan of light-emitting devices incorporating the film.

Furthermore, the integration of the Zn complex compound into the quantum dot composition facilitates better interfacial compatibility between the emission layer and adjacent charge transport layers. This compatibility enhances charge injection and balance within the device architecture. The resulting light-emitting devices, as demonstrated in Examples 1 to 3, exhibit significantly higher current efficiency and longer operational lifespans compared to devices fabricated without the Zn complex compound (Comparative Example 1). These findings underscore the critical role of the Zn complex compound in achieving high-performance quantum dot-based optoelectronic devices.

The light-emitting device, the display apparatus/device, the electronic apparatus/device, the electronic equipment, the manufacturing apparatuses thereof, or any other relevant apparatuses/devices or components according to one or more embodiments of the present disclosure may be implemented utilizing any suitable hardware, firmware (e.g., an application-specific integrated circuit), software, or a combination of software, firmware, and hardware. For example, the one or more components of the device may be formed or provided on one integrated circuit (IC) chip or on separate IC chips. Further, the one or more components of the device may be implemented on a flexible printed circuit film, a tape carrier package (TCP), a printed circuit board (PCB), or formed or provided on one substrate. Further, the one or more components of the device may be a process or thread, running on one or more processors, in one or more computing devices, executing computer program instructions and interacting with other system components for performing the one or more suitable functionalities as described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, and/or the like. Also, a person of skill in the art should recognize that the functionality of one or more suitable computing devices may be combined or integrated into a single computing device, or the functionality of a particular computing device may be distributed across one or more other computing devices without departing from the scope of the embodiments of the present disclosure.

It should be understood that embodiments described herein should be considered in a descriptive sense only and not for purposes of limitation. Descriptions of features or aspects within each embodiment should typically be considered as available for other similar features or aspects in other embodiments. While the subject matter of the present disclosure has been described with reference to the drawings, it will be understood by those of ordinary skill in the art that one or more suitable changes in form and more details may be made therein without departing from the spirit and scope as defined by the following claims and equivalents thereof.

What is claimed is:

1. A quantum dot composition comprising:
a quantum dot;
a Zn complex compound represented by Formula 1; and
a solvent: 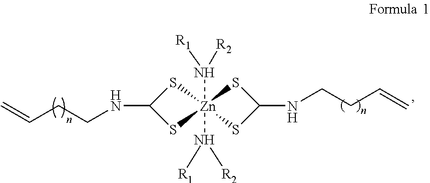
wherein, in Formula 1,
R₁ and R₂ are each independently hydrogen, a C₈-C₂₀ alkyl group, a C₈-C₂₀ alkenyl group, or a C₈-C₂₀ alkyloxiranyl group, and at least one selected from R₁ and R₂ is a C₈-C₂₀ alkyl group, a C₈-C₂₀ alkenyl group, or a C₈-C₂₀ alkyloxiranyl group,
n is an integer of 1 to 10, and
a dotted line is a coordinate bond.

2. The quantum dot composition as claimed in claim 1, wherein one selected from R₁ and R₂ is hydrogen, and the other one selected from R₁ and R₂ is a C₈-C₂₀ alkyl group, a C₈-C₂₀ alkenyl group, or a C₈-C₂₀ alkyloxiranyl group.

3. The quantum dot composition as claimed in claim 1, wherein:
one selected from R₁ and R₂ is hydrogen, and
the other one selected from R₁ and R₂ is:
an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, an n-nonadecyl group, or an n-eicosyl group;
an n-octenyl group, an n-nonenyl group, an n-decenyl group, an n-undecenyl group, an n-dodecenyl group, an n-tridecenyl group, an n-tetradecenyl group, an n-pentadecenyl group, an n-hexadecenyl group, an n-heptadecenyl group, an n-octadecenyl group, an n-nonadecenyl group, or an n-eicocenyl group; or
an n-hexyloxiranyl group, an n-heptyloxiranyl group, an n-octyloxiranyl group, an n-nonyloxiranyl group, an n-decyloxiranyl group, an n-undecyloxiranyl group, an n-dodecyloxiranyl group, an n-tridecyloxiranyl group, an n-tetradecyloxiranyl group, an n-pentadecyloxiranyl group, an n-hexadecyloxiranyl group, an n-heptadecyloxiranyl group, or an n-octadecyloxiranyl group.

4. The quantum dot composition as claimed in claim 1, wherein the Zn complex compound comprises at least one compound selected from compounds in Group I:

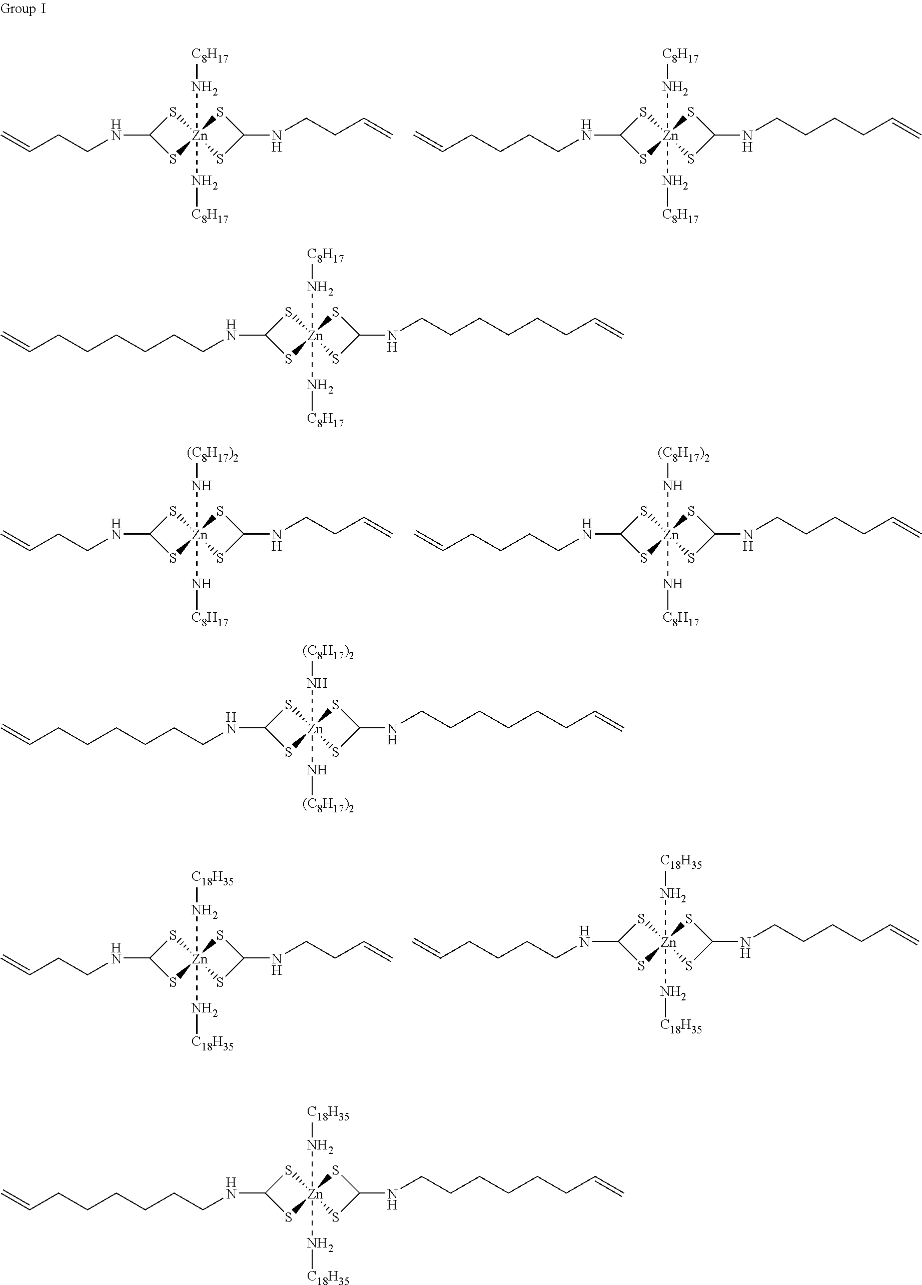

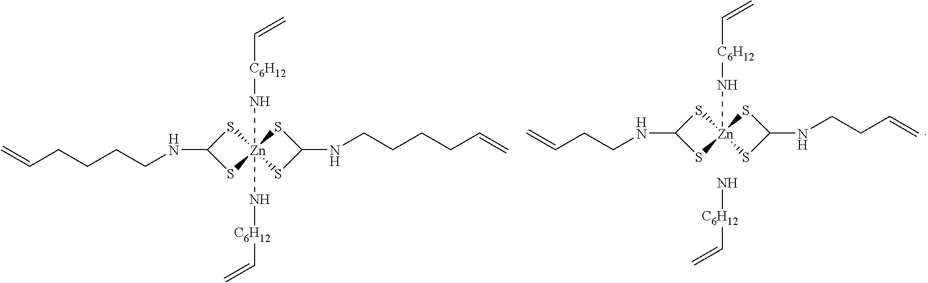

5. The quantum dot composition as claimed in claim 1, wherein an amount of the quantum dot based on 100 wt % of the quantum dot composition is 1 wt % to 10 wt %.

6. The quantum dot composition as claimed in claim 1, wherein an amount of the Zn complex compound based on 100 wt % of the quantum dot is 1 wt % to 10 wt %.

7. The quantum dot composition as claimed in claim 1, wherein the quantum dot comprises: a Group II-VI semiconductor compound; a Group III-V semiconductor compound; a Group III-VI semiconductor compound; a Group I-III-VI semiconductor compound; a Group IV-VI semiconductor compound; or a combination thereof.

8. The quantum dot composition as claimed in claim 1, wherein the quantum dot comprises CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, CdZnSeS, CdZnSeTe, CdZnSTe, CdHgSeS, CdHgSeTe, CdHgSTe, HgZnSeS, HgZnSeTe, HgZnSTe, InGaS₃, InGaSe₃, AgInS, AgInS₂, CuInS, CuInS₂, CuInGaS₂, CuGaO₂, AgGaO₂, AgAlO₂, SnSeS, SnSeTe, SnSTe, PbSeS, PbSeTe, PbSTe, SnPbS, SnPbSe, SnPbTe, SnPbSSe, SnPbSeTe, SnPbSTe, or any combination thereof.

9. The quantum dot composition as claimed in claim 1, wherein the quantum dot comprises a core and a shell covering at least a part of the core.

10. A light-emitting device comprising:
a first electrode;
a second electrode opposite to the first electrode; and
an interlayer arranged between the first electrode and the second electrode and comprising an emission layer,
wherein the emission layer is manufactured from the quantum dot composition as claimed in claim 1 and comprises the quantum dot, ZnS generated from decomposition of the Zn complex compound represented by Formula 1, ZnS to which a ligand is bonded, and a thiourea derivative.

11. The light-emitting device as claimed in claim 10, wherein the ZnS to which a ligand is bonded and which is generated from decomposition of the Zn complex compound represented by Formula 1 is represented by Formula 1A:

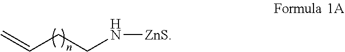

12. The light-emitting device as claimed in claim 10, wherein the thiourea derivative is represented by Formula 3:

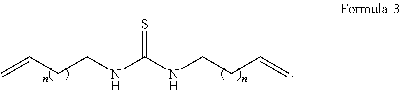

13. The light-emitting device as claimed in claim 10, wherein:
the first electrode is an anode,
the second electrode is a cathode, and
the interlayer further comprises a hole transport region between the first electrode and the emission layer and an electron transport region between the emission layer and the second electrode.

14. The light-emitting device as claimed in claim 13, wherein:
the hole transport region comprises a hole injection layer, a hole transport layer, an emission auxiliary layer, an electron-blocking layer, or any combination thereof, and
the electron transport region comprises a hole-blocking layer, an electron transport layer, an electron injection layer, or any combination thereof.

15. The light-emitting device as claimed in claim 13, wherein:
the electron transport region comprises an electron transport layer, and
the electron transport layer comprises a metal oxide represented by Formula 4: 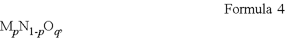
and
wherein, in Formula 4,
M and N are each independently Zn, Mg, Al, Li, Fe, In, Na, Ti, Zr, Sn, W, Ta, Ni, Mo, Cu, V, or any combination thereof,
$$0 \leq p \leq 1 ,$$
$$and$$
$$0.01 \leq q \leq 5 .$$

16. An electronic apparatus comprising the light-emitting device as claimed in claim 10.

17. The electronic apparatus as claimed in claim 16, further comprising a thin-film transistor,
wherein the thin-film transistor comprises a source electrode and a drain electrode, and
the first electrode of the light-emitting device is electrically connected to one selected from the source electrode and the drain electrode of the thin-film transistor.

18. The electronic apparatus as claimed in claim 16, further comprising a color filter, a conversion layer, a touch screen layer, a polarizing layer, or any combination thereof.

19. An electronic equipment comprising the light-emitting device as claimed in claim 10.

20. The electronic equipment as claimed in claim 19, wherein the electronic equipment is at least one selected from among a flat panel display, a curved display, a computer monitor, a medical monitor, a television, a billboard, an indoor light, an outdoor light, a signal light, a head-up display, a fully transparent display, a partially transparent display, a flexible display, a rollable display, a foldable display, a stretchable display, a laser printer, a telephone, a portable phone, a tablet personal computer, a phablet, a personal digital assistant (PDA), a wearable device, a laptop computer, a digital camera, a camcorder, a viewfinder, a micro display, a three-dimensional (3D) display, a virtual reality display, an augmented reality display, a vehicle, a video wall having two or more displays tiled together, a theater screen, a stadium screen, a phototherapy device, and a signboard.
